(19) United States
(12) Patent Application Publication
(10) Pub. No.: US 2007/0171716 A1
(43) Pub. Date: Jul. 26, 2007

(54) System and method for visualizing configurable analytical spaces in time for diagrammatic context representations

(76) Inventors: William Wright, Toronto (CA); Thomas Kapler, Toronto (CA); Robert Harper, Toronto (CA)

Correspondence Address: Gowling Lafleur Henderson LLP;1 First Canadian Place, Suite 1600, 100 King Street West, Toronto, ON, M5X 1G5, CA

(21) Appl. No.: 11/606,211

(22) Filed: Nov. 30, 2006

Related U.S. Application Data
(60) Provisional application No. 60/740,636, filed on Nov. 30, 2005.
(60) Provisional application No. 60/812,954, filed on Jun. 13, 2006.

(51) Int. Cl. G11C 16/04

(52) U.S. Cl. 365/185.12

(57) ABSTRACT

A system and method are provided for generating a plurality of environments for a diagrammatic domain coupled to a temporal domain, such that each of the environments has a plurality of nodes and links between the nodes to form a respective information structure. The system and method include storage for storing a plurality of data objects of the diagrammatic domain for use in generating the plurality of nodes and links, and rules data stored in the storage and configured for assigning each of the plurality of data objects to a one or more environments of the plurality of environments. A layout logic module is used for providing a first layout pattern for a first environment of the plurality of environments and a second layout pattern for a second environment of the plurality of environments, such that each of the layout patterns includes distinct predefined layout rules for coordinating the visual appearance and spatial distribution of the respective nodes and links with respect to a reference surface for each of the first and second environments to provide the corresponding information structures. A layout module is used for applying the first layout pattern to a first data object set assigned by the rules data from the plurality of data objects to the first environment for laying out the corresponding nodes and links and configured for applying the second layout pattern to a second data object set assigned by the rules data from the plurality of data objects to the second environment for laying out the corresponding nodes and links, such that some of the data objects from the first data object set are also included in the data objects of the second data object set. An environment generation module is used for coordinating presentation of the generated first and second environments on a display, for subsequent analysis by a user. Further, a reconfiguration module is used to reconfigure the position and/or visual properties of the nodes and links.

(This application claims the benefit of U.S. Provisional Application No. 60/740,636 Filed Nov. 30, 2005 and U.S. Provisional Application No. 60/812,954. lo Filed Jun. 14, 2006.)

### BACKGROUND OF THE INVENTION

The present invention relates to an interactive visual presentation of multidimensional data on a user interface.

Representing processes is of particular interest because it is broadly applicable to intelligence analysis (Bodnar, 2003), (Wright, 2004). People are habitual and many things can be expressed as processes with sequential events and generic temporal considerations. In analysis, a process description or model provides a context and a logical framework for reasoning about the subject. A process model helps review what is happening, why is it happening, and what can be done about it. A process model can also help describe a pattern against which to compare actual behavior, or act as a template for searches. Creating and modifying multidimensional diagrammatic contexts presents several challenges from both a usability and visualization point of view. For example, as diagrams grow in complexity and information density, the ability of user to make fine adjustments in high-dimensional displays can become difficult.

Tracking and analyzing entities and streams of events, has traditionally been the domain of investigators, whether that be national intelligence analysts, police services or military intelligence. Business users also analyze events in time and location to better understand phenomenon such as customer behavior or transportation patterns. As data about events and objects become more commonly available, analyzing and understanding of interrelated temporal and spatial information is increasingly a concern for military commanders, intelligence analysts and business analysts. Localized cultures, characters, organizations and their behaviors play an important part in planning and mission execution. For business applications, tracking of production process characteristics can be a means for improving plant operations. A generalized method to capture and visualize this information over time for use by business applications, among others, is needed.

Many visualization techniques and products for analyzing complex event interactions only display information along a single dimension, typically one of time, geography or a network connectivity diagram. Each of these types of visualizations is common and well understood. For example a Time-focused scheduling chart such as Microsoft (MS) Project displays various project events over the single dimension of time, and a Geographic Information System (GIS) product, such as MS MapPoint, or ESRI ArcView, is good for showing events in the single dimension of locations on a map. There are also link analysis tools, such as Netmap (www.netmapanalytics.com) or Visual Analytics (www.visualanalytics.com) that display events as a network diagram, or graph, of objects and connections between objects. Some of these systems are capable of using animation to display another dimension, typically time. Time is played back, or scrolled, and the related spatial image display changes to reflect the state of information at a moment in time. However this technique relies on limited human short term memory to track and then retain temporal changes and patterns in the diagrammatic spatial domain. Another visualization technique called “small multiples” uses repeated frames of a condition or chart, each capturing an increment moment in time, much like looking at sequence of frames from a film laid side by side. Each image must be interpreted separately, and side-by-side comparisons made, to detect differences. This technique is expensive in terms of visual space since an image must be generated for each moment of interest, which can be problematic when trying to simultaneously display multiple images of adequate size that contain complex data content.

It is also recognized that current methodology for modeling diagrammatic based domains is problematic for retaining continuity of analysis in the event of changes to selected nodes in process diagrams. Further, there is a current need for systematic abilities to analyze a diagrammatic domain from a variety of different perspectives.

### SUMMARY OF THE INVENTION

It is an object of the present invention to provide a system and method for the integrated, interactive visual representation of a diagrammatic domain with spatial and temporal properties to obviate or mitigate at least some of the above-mentioned disadvantages.

It is recognized that current methodology for modeling diagrammatic based domains is problematic for retaining continuity of analysis in the event of changes to selected nodes in process diagrams. Further, there is a current need for systematic abilities to analyze a diagrammatic domain from a variety of different perspectives. Contrary to present systems there is provided a system and method for generating a plurality of environments for a diagrammatic domain coupled to a temporal domain, each of the environments having a plurality of nodes and links between the nodes to form a respective information structure. The system comprises storage for storing a plurality of data objects of the diagrammatic domain for use in generating the plurality of nodes and links and rules data stored in the storage and configured for assigning each of the plurality of data objects to a one or more environments of the plurality of environments. A layout logic module is used for providing a first layout pattern for a first environment of the plurality of environments and a second layout pattern for a second environment of the plurality of environments, each of the layout patterns including distinct predefined layout rules for coordinating the visual appearance and spatial distribution of the respective nodes and links with respect to a reference surface for each of the first and second environments to provide the corresponding information structures. A layout module is configured for applying the first layout pattern to a first data object set assigned by the rules data from the plurality of data objects to the first environment for laying out the corresponding nodes and links and configured for applying the second layout pattern to a second data object set assigned by the rules data from the plurality of data objects to the second environment for laying out the corresponding nodes and links, such that some of the data objects from the first data object set are also included in the data objects of the second data object set. An environment generation module is configured for coordinating presentation of the generated first and second environments on a display for subsequent analysis by a user.

One aspect provided is a system for generating a plurality of environments for a diagrammatic domain coupled to a temporal domain, each of the environments having a plurality of nodes and links between the nodes to form a respective information structure, the system comprising; storage for storing a plurality of data objects of the diagrammatic domain for use in generating the plurality of nodes and links; rules data stored in the storage and configured for assigning each of the plurality of data objects to a one or more environments of the plurality of environments; a layout logic module for providing a first layout pattern for a first environment of the plurality of environments and a second layout pattern for a second environment of the plurality of environments, each of the layout patterns including distinct predefined layout rules for coordinating the visual appearance and spatial distribution of the respective nodes and links with respect to a reference surface for each of the first and second environments to provide the corresponding information structures; a layout module configured for applying the first layout pattern to a first data object set assigned by the rules data from the plurality of data objects to the first environment for laying out the corresponding nodes and links and configured for applying the second layout pattern to a second data object set assigned by the rules data from the plurality of data objects to the second environment for laying out the corresponding nodes and links, such that some of the data objects from the first data object set are also included in the data objects of the second data object set; and an environment generation module configured for coordinating presentation of the generated first and second environments on a display for subsequent analysis by a user.

A further aspect provided is a method for generating a plurality of environments for a diagrammatic domain coupled to a temporal domain, each of the environments having a plurality of nodes and links between the nodes to form a respective information structure, the method comprising the acts of; accessing a plurality of data objects of the diagrammatic domain for use in generating the plurality of nodes and links; assigning each of the plurality of data objects to a one or more environments of the plurality of environments; providing a first layout pattern for a first environment of the plurality of environments and a second layout pattern for a second environment of the plurality of environments, each of the layout patterns including distinct predefined layout rules for coordinating the visual appearance and spatial distribution of the respective nodes and links with respect to a reference surface for each of the first and second environments to provide the corresponding information structures; applying the first layout pattern to a first data object set assigned by the rules data from the plurality of data objects to the first environment for laying out the corresponding nodes and links and applying the second layout pattern to a second data object set assigned by the rules data from the plurality of data objects to the second environment for laying out the corresponding nodes and links, such that some of the data objects from the first data object set are also included in the data objects of the second data object set; and displaying the generated first and second environments for subsequent analysis by a user.

### BRIEF DESCRIPTION OF THE DRAWINGS

A better understanding of these and other embodiments of the present invention can be obtained with reference to the following drawings and detailed description of the preferred embodiments, in which:

FIG. 1 is a block diagram of a data processing system for a visualization tool;

FIG. 2 shows further details of the data processing system of FIG. 1;

FIG. 3 shows further details of the visualization tool of FIG. 1;

FIG. 4 shows further details of a visualization representation for display on a visualization interface of the system of FIG. 1;

FIG. 5 is an example visualization representation of FIG. 1 showing Events in Concurrent Time and Space;

FIG. 6 shows example data objects and associations of FIG. 1;

FIG. 7 shows further example data objects and associations of FIG. 1;

FIG. 8 shows changes in orientation of a reference surface of the visualization representation of FIG. 1;

FIG. 9 is an example timeline of FIG. 8;

FIG. 10 is a further example timeline of FIG. 8;

FIG. 11 is a further example timeline of FIG. 8 showing a time chart;

FIG. 12 is a further example of the time chart of FIG. 11;

FIG. 13 shows example user controls for the visualization representation of FIG. 5;

FIG. 14 shows an example operation of the tool of FIG. 3;

FIG. 15 shows a further example operation of the tool of FIG. 3;

FIG. 16 shows a further example operation of the tool of FIG. 3;

FIG. 17 shows an example visualization representation of FIG. 4 containing events and target tracking over space and time showing connections between events;

FIG. 18 shows an example visualization representation containing events and target tracking over space and time showing connections between events on a time chart of FIG. 11, and

FIG. 19 is an example operation of the visualization tool of FIG. 3;

FIG. 20 is a further embodiment of FIG. 18 showing imagery;

FIG. 21 is a further embodiment of FIG. 18 showing imagery in a time chart view;

FIG. 22 shows further detail of the aggregation module of FIG. 3;

FIG. 23 shows an example aggregation result of the module of FIG. 22;

FIG. 24 is a further embodiment of the result of FIG. 23;

FIG. 25 shows a summary chart view of a further embodiment of the representation of FIG. 20;

FIG. 26 shows an event comparison for the aggregation module of FIG. 23;

FIG. 27 shows a further embodiment of the tool of FIG. 3;

FIG. 28 shows an example operation of the tool of FIG. 27;

FIG. 29 shows a further example of the visualization representation of FIG. 4;

FIG. 30 is a further example of the charts of FIG. 25;

FIGS. 31a,b,c,d show example control sliders of analysis functions of the tool of FIG. 3;

FIG. 32 shows an example of multiple environments of a diagrammatic domain;

FIG. 33 shows a further example diagrammatic context domain;

FIG. 34 shows a visualization tool for generating the domain of FIG. 32;

FIG. 35 is a further embodiment of the domain of FIG. 32;

FIG. 36 shows an example environments involving operation of a reconfiguration module of the tool of FIG. 34; and

FIG. 37 is a further embodiment of the domain of FIG. 32;

FIG. 38 shows the operation of the tool 12 of FIG. 34 for various environment generation methods;

FIG. 39 is an example of a user driven generation method of FIG. 38;

FIG. 40 is a further example of the user driven generation method of FIG. 38;

FIG. 41 shows an embodiment of rules of FIG. 34;

FIG. 42 is a further example of the user driven generation method of FIG. 38;

FIG. 43 is an example of an event driven generation method of FIG. 38;

FIG. 44 a further example of the event driven generation method of FIG. 38;

FIG. 45 is an example of a knowledge driven generation method of FIG. 38;

FIG. 46 a further example of the knowledge driven generation method of FIG. 38;

FIG. 47 a further 2D example of the knowledge driven generation method of FIG. 38;

FIG. 48 a further 3D example of the knowledge driven generation method of FIG. 38; and

FIG. 49 is a further example of multiple environments of FIG. 32.

### DETAILED DESCRIPTION OF THE PREFERRED EMBODIMENT

The following detailed description of the embodiments of the present invention does not limit the implementation of the invention to any particular computer programming language. The present invention may be implemented in any computer programming language provided that the OS (Operating System) provides the facilities that may support the requirements of the present invention. A preferred embodiment is implemented in the Java computer programming language (or other computer programming languages in conjunction with C/C++). Any limitations presented would be a result of a particular type of operating system, computer programming language, or data processing system and would not be a limitation of the present invention.

Visualization Environment

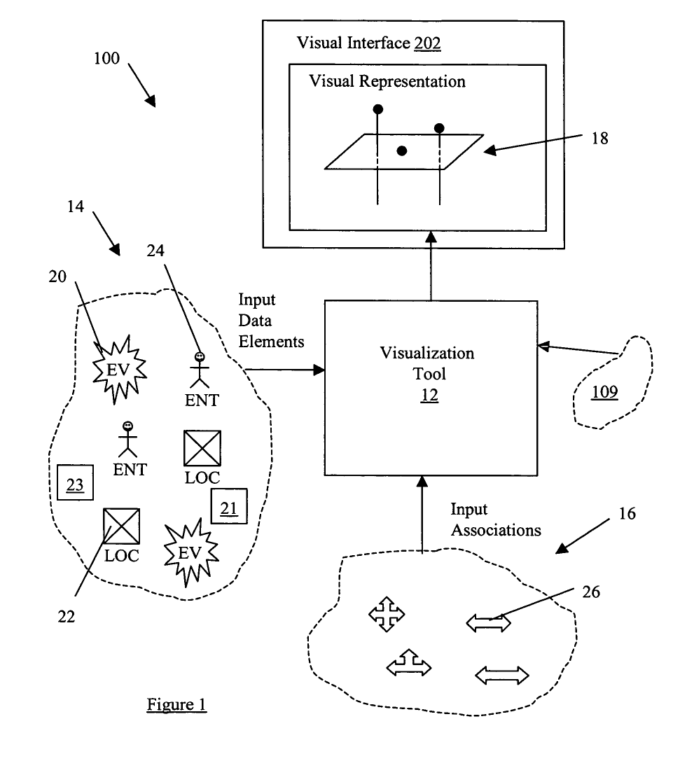

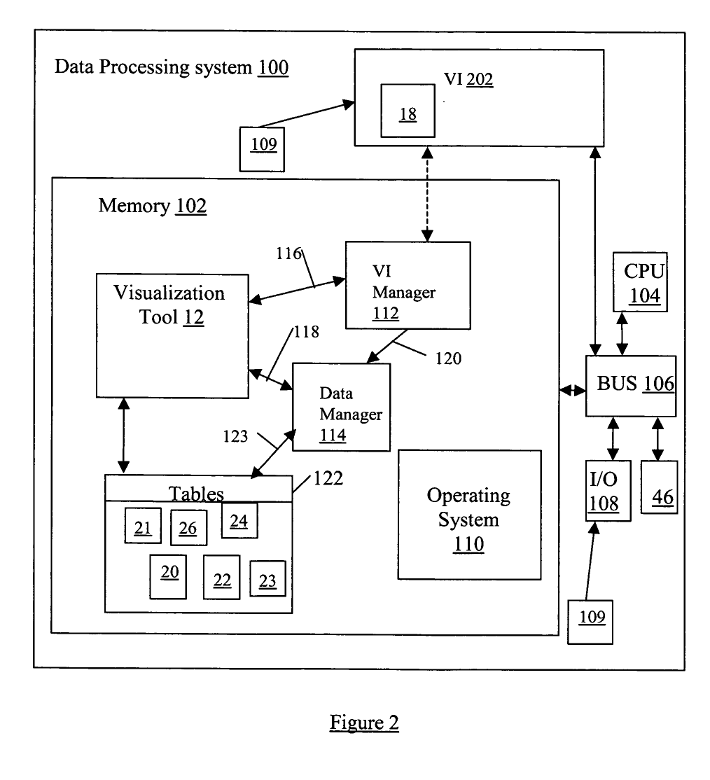

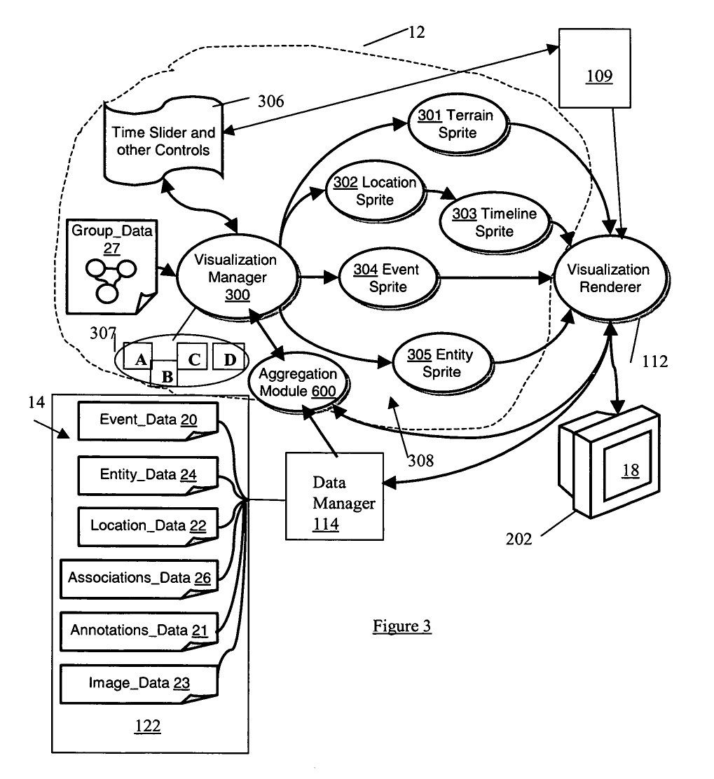

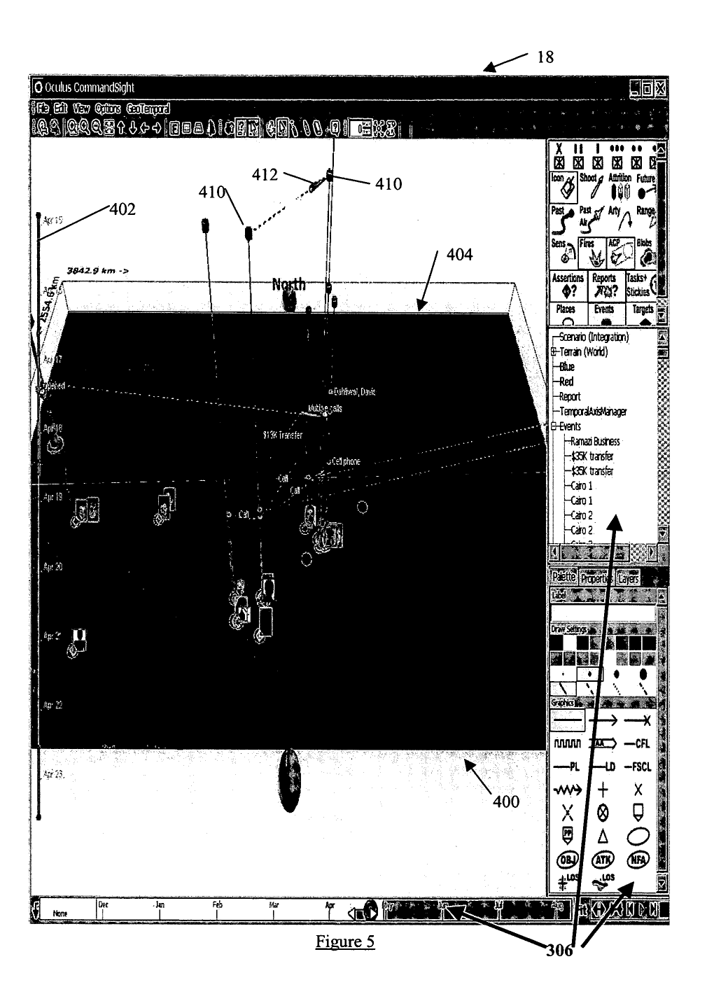

Referring to FIG. 1, a visualization data processing system 100 includes a visualization tool 12 for processing a collection of data objects 14 as input data elements to a user interface 202. The data objects 14 are combined with a respective set of associations 16 by the tool 12 to generate an interactive visual representation 18 on the visual interface (VI) 202. The data objects 14 include event objects 20, location objects 22, images 23 and entity objects 24, as further described below. The set of associations 16 include individual associations 26 that associate together various subsets of the objects 20, 22, 23, 24, as further described below. Management of the data objects 14 and set of associations 16 are driven by user events 109 of a user (not shown) via the user interface 108 (see FIG. 2) during interaction with the visual representation 18. The representation 18 shows connectivity between temporal and spatial information of data objects 14 at multi-locations within the spatial domain 400 (see FIG. 4).

Data Processing System 100

Referring to FIG. 2, the data processing system 100 has a user interface 108 for interacting with the tool 12, the user interface 108 being connected to a memory 102 via a BUS 106. The interface 108 is coupled to a processor 104 via the BUS 106, to interact with user events 109 to monitor or otherwise instruct the operation of the tool 12 via an operating system 110. The user interface 108 can include one or more user input devices such as but not limited to a QWERTY keyboard, a keypad, a trackwheel, a stylus, a mouse, and a microphone. The visual interface 202 is considered the user output device, such as but not limited to a computer screen display. If the screen is touch sensitive, then the display can also be used as the user input device as controlled by the processor 104. Further, it is recognized that the data processing system 100 can include a computer readable storage medium 46 coupled to the processor 104 for providing instructions to the processor 104 and/or the tool 12. The operation of the data processing system 100 is facilitated by the device infrastructure including one or more computer processors 104 and can include the memory 102 (e.g. a random access memory). The computer processor(s) 104 facilitates performance of the data processing system 100 configured for the intended task(s) through operation of a network interface, the user interface 202 and other application programs/hardware of the data processing system 100 by executing task related instructions. These task related instructions can be provided by an operating system, and/or software applications located in the memory 102, and/or by operability that is configured into the electronic/digital circuitry of the processor(s) 104 designed to perform the specific task(s).

Further, it is recognized that the device infrastructure can include a computer readable storage medium 46 coupled to the processor 104 for providing instructions to the processor 104 and/or to load/update operating configurations for the tool 12 as well as the application of the tool 12 itself. The computer readable medium 46 can include hardware and/or software such as, by way of example only, magnetic disks, magnetic tape, optically readable medium such as CD/DVD ROMS, and memory cards. In each case, the computer readable medium 46 may take the form of a small disk, floppy diskette, cassette, hard disk drive, solid-state memory card, or RAM provided in the memory 102. It should be noted that the above listed example computer readable mediums 46 can be used either alone or in combination.

Referring again to FIG. 2, the tool 12 interacts via link 116 with a VI manager 112 (also known as a visualization renderer) of the system 100 for presenting the visual representation 18 on the visual interface 202. The tool 12 also interacts via link 118 with a data manager 114 of the system 100 to coordinate management of the data objects 14 and association set 16 from data files or tables 122 of the memory 102. It is recognized that the objects 14 and association set 16 could be stored in the same or separate tables 122, as desired. The data manager 114 can receive requests for storing, retrieving, amending, or creating the objects 14 and association set 16 via the tool 12 and/or directly via link 120 from the VI manager 112, as driven by the user events 109 and/or independent operation of the tool 12. The data manager 114 manages the objects 14 and association set 16 via link 123 with the tables 122. Accordingly, the tool 12 and managers 112, 114 coordinate the processing of data objects 14, association set 16 and user events 109 with respect to the content of the screen representation 18 displayed in the visual interface 202.

The task related instructions can comprise code and/or machine readable instructions for implementing predetermined functions/operations including those of an operating system, tool 12, or other information processing system, for example, in response to command or input provided by a user of the system 100. The processor 104 (also referred to as module(s) for specific components of the tool 12) as used herein is a configured device and/or set of machine-readable instructions for performing operations as described by example above.

As used herein, the processor/modules in general may comprise any one or combination of, hardware, firmware, and/or software. The processor/modules acts upon information by manipulating, analyzing, modifying, converting or transmitting information for use by an executable procedure or an information device, and/or by routing the information with respect to an output device. The processor/modules may use or comprise the capabilities of a controller or microprocessor, for example. Accordingly, any of the functionality provided by the systems and process of FIGS. 1-49 may be implemented in hardware, software or a combination of both. Accordingly, the use of a processor/modules as a device and/or as a set of machine readable instructions is hereafter referred to generically as a processor/module for sake of simplicity.

It will be understood by a person skilled in the art that the memory 102 storage described herein is the place where data is held in an electromagnetic or optical form for access by a computer processor. In one embodiment, storage means the devices and data connected to the computer through input/output operations such as hard disk and tape systems and other forms of storage not including computer memory and other in-computer storage. In a second embodiment, in a more formal usage, storage is divided into: (1) primary storage, which holds data in memory (sometimes called random access memory or RAM) and other “built-in” devices such as the processor's L1 cache, and (2) secondary storage, which holds data on hard disks, tapes, and other devices requiring input/output operations. Primary storage can be much faster to access than secondary storage because of the proximity of the storage to the processor or because of the nature of the storage devices. On the other hand, secondary storage can hold much more data than primary storage. In addition to RAM, primary storage includes read-only memory (ROM) and L1 and L2 cache memory. In addition to hard disks, secondary storage includes a range of device types and technologies, including diskettes, Zip drives, redundant array of independent disks (RAID) systems, and holographic storage. Devices that hold storage are collectively known as storage media.

A database is a further embodiment of memory 102 as a collection of information that is organized so that it can easily be accessed, managed, and updated. In one view, databases can be classified according to types of content: bibliographic, full-text, numeric, and images. In computing, databases are sometimes classified according to their organizational approach. As well, a relational database is a tabular database in which data is defined so that it can be reorganized and accessed in a number of different ways. A distributed database is one that can be dispersed or replicated among different points in a network. An object-oriented programming database is one that is congruent with the data defined in object classes and subclasses.

Computer databases typically contain aggregations of data records or files, such as sales transactions, product catalogs and inventories, and customer profiles. Typically, a database manager provides users the capabilities of controlling read/write access, specifying report generation, and analyzing usage. Databases and database managers are prevalent in large mainframe systems, but are also present in smaller distributed workstation and mid-range systems such as the AS/400 and on personal computers. SQL (Structured Query Language) is a standard language for malting interactive queries from and updating a database such as IBM's DB2, Microsoft's Access, and database products from Oracle, Sybase, and Computer Associates.

Memory is a further embodiment of memory 210 storage as the electronic holding place for instructions and data that the computer's microprocessor can reach quickly. When the computer is in normal operation, its memory usually contains the main parts of the operating system and some or all of the application programs and related data that are being used. Memory is often used as a shorter synonym for random access memory (RAM). This kind of memory is located on one or more microchips that are physically close to the microprocessor in the computer.

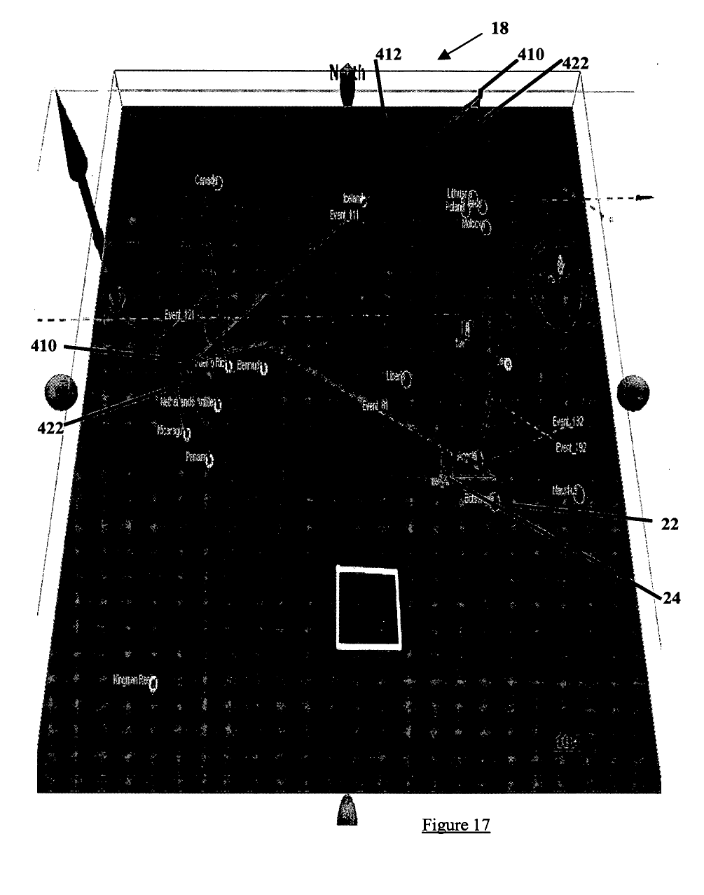

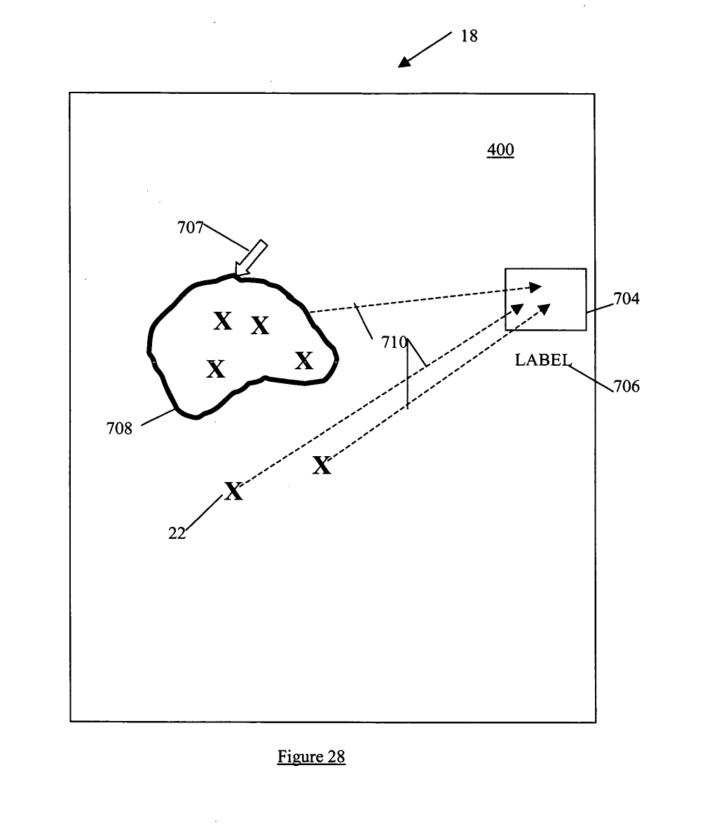

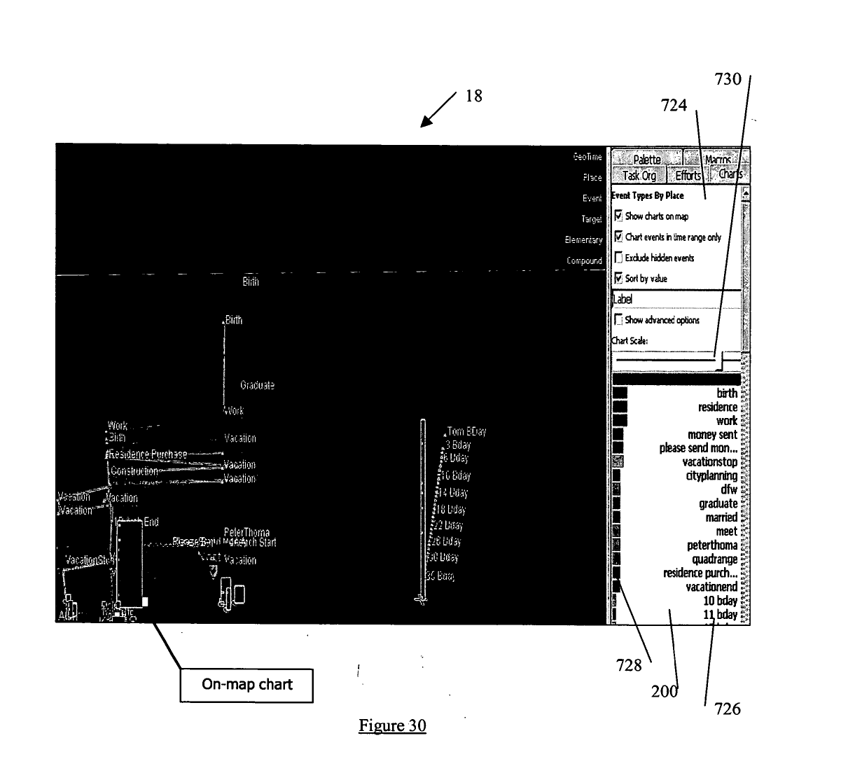

Referring to FIGS. 27 and 29, the tool 12 can have an information module 712 for generating information 714a,b,c,d for display by the visualization manager 300, in response to user manipulations via the I/O interface 108. For example, when a mouse pointer 713 is held over the visual element 410,412 of the representation 18, some predefined information 714a,b,c,d is displayed about that selected visual element 410,412. The information module 712 is configured to display the type of information dependent upon whether the object is a place 22, target 24, elementary or compound event 20, for example. For example, when the place 22 type is selected, the displayed information 714a is formatted by the information module 712 to include such as but not limited to; Label (e.g. Rome), Attributes attached to the object (if any); and events associated with that place 22. For example, when the target 24/target trail 412 (see FIG. 17) type is selected, the displayed information 714b is formatted by the information module 712 to include such as but not limited to; Label, Attributes (if any), events associated with that target 24, as well as the target's icon (if one is associated with the target 24) is shown. For example, when an elementary event 20a type is selected, the displayed information 714c is formatted by the information module 712 to include such as but not limited to; Label, Class, Date, Type, Comment (including Attributes, if any), associated Targets 24 and Place 22. For example, when a compound event 20b type is selected, the displayed information 714d is formatted by the information module 712 to include such as but not limited to; Label, Class, Date, Type, Comment (including Attributes, if any) and all elementary event popup data for each child event. Accordingly, it is recognized that the information module 712 is configured to select data for display from the database 122 (see FIG. 2) appropriate to the type of visual element 410,412 selected by the user from the visual representation 18.

Tool Information Model

Referring to FIG. 1, a tool information model is composed of the four basic data elements (objects 20, 22, 23, 24 and associations 26) that can have corresponding display elements in the visual representation 18. The four elements are used by the tool 12 to describe interconnected activities and information in time and space as the integrated visual representation 18, as further described below.

Event Data Objects 20

Events are data objects 20 that represent any action that can be described. The following are examples of events;

Bill was at Toms house at 3 pm,

Tom phoned Bill on Thursday,

A tree fell in the forest at 4:13 am, Jun. 3, 1993 and

Tom will move to Spain in the summer of 2004.

The Event is related to a location and a time at which the action took place, as well as several data properties and display properties including such as but not limited to; a short text label, description, location, start-time, end-time, general event type, icon reference, visual layer settings, priority, status, user comment, certainty value, source of information, and default+user-set color. The event data object 20 can also reference files such as images or word documents.

Locations and times may be described with varying precision. For example, event times can be described as “during the week of January 5^{th}” or “in the month of September”. Locations can be described as “Spain” or as “New York” or as a specific latitude and longitude.

Entity Data Objects 24

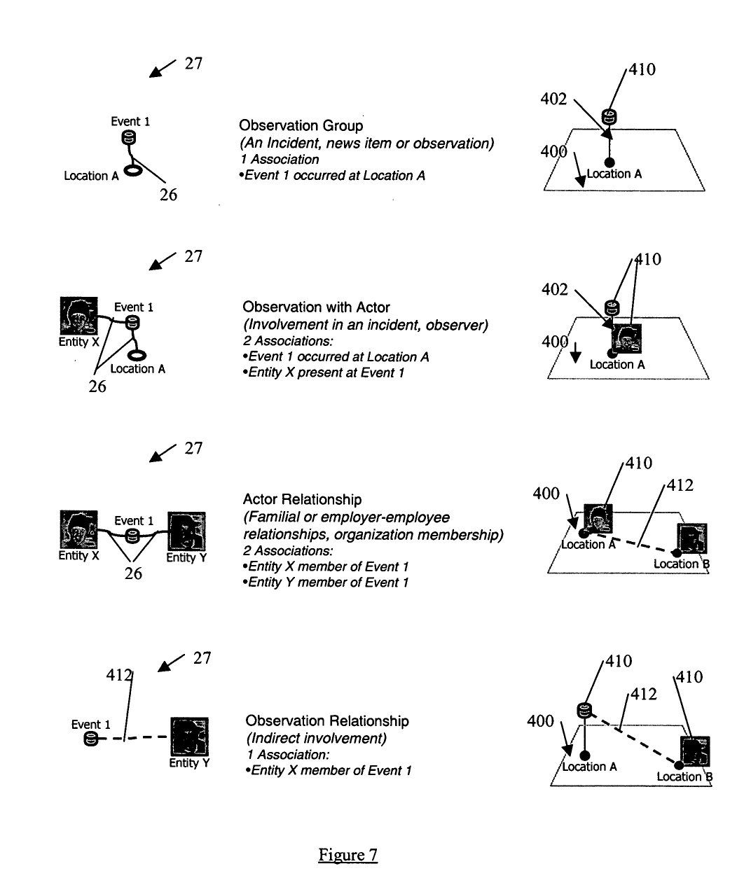

Entities are data objects 24 that represent any thing related to or involved in an event, including such as but not limited to; people, objects, organizations, equipment, businesses, observers, affiliations etc. Data included as part of the Entity data object 24 can be short text label, description, general entity type, icon reference, visual layer settings, priority, status, user comment, certainty value, source of information, and default+user-set color. The entity data can also reference files such as images or word documents. It is recognized in reference to FIGS. 6 and 7 that the term Entities includes “People”, as well as equipment (e.g. vehicles), an entire organization (e.g. corporate entity), currency, and any other object that can be tracked for movement in the spatial domain 400. It is also recognized that the entities 24 could be stationary objects such as but not limited to buildings. Further, entities can be phone numbers and web sites. To be explicit, the entities 24 as given above by example only can be regarded as Actors

Location Data Objects 22

Locations are data objects 22 that represent a place within a spatial context/domain, such as a geospatial map, a node in a diagram such as a flowchart, or even a conceptual place such as “Shang-ri-la” or other “locations” that cannot be placed at a specific physical location on a map or other spatial domain. Each Location data object 22 can store such as but not limited to; position coordinates, a label, description, color information, precision information, location type, non-geospatial flag and user comments.

Associations

Event 20, Location 22 and Entity 24 are combined into groups or subsets of the data objects 14 in the memory 102 (see FIG. 2) using associations 26 to describe real-world occurrences. The association is defined as an information object that describes a pairing between 2 data objects 14. For example, in order to show that a particular entity was present when an event occurred, the corresponding association 26 is created to represent that Entity X “was present at” Event A. For example, associations 26 can include such as but not limited to; describing a communication connection between two entities 24, describing a physical movement connection between two locations of an entity 24, and a relationship connection between a pair of entities 24 (e.g. family related and/or organizational related). It is recognised that the associations 26 can describe direct and indirect connections. Other examples can include phone numbers and web sites.

A variation of the association type 26 can be used to define a subclass of the groups 27 to represent user hypotheses. In other words, groups 27 can be created to represent a guess or hypothesis that an event occurred, that it occurred at a certain location or involved certain entities. Currently, the degree of belief/accuracy/evidence reliability can be modeled on a simple 1-2-3 scale and represented graphically with line quality on the visual representation 18.

Image Data Objects 23

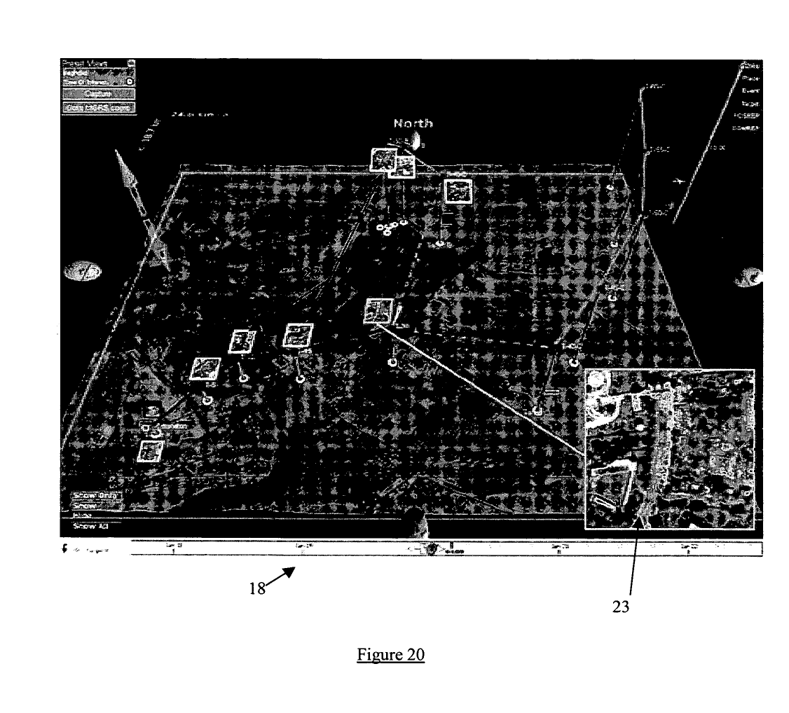

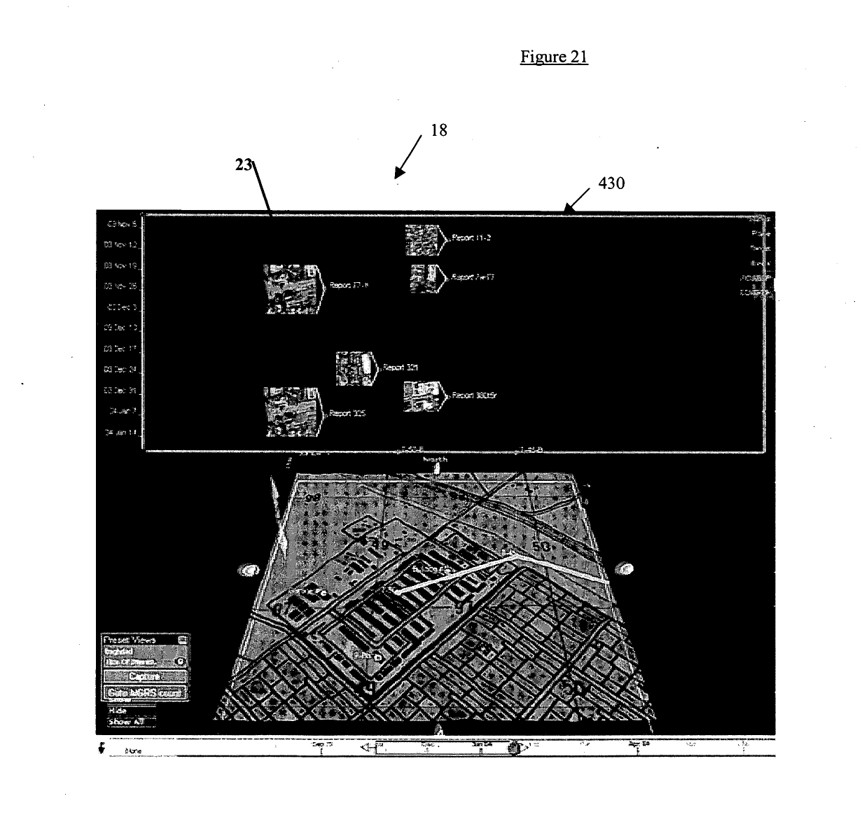

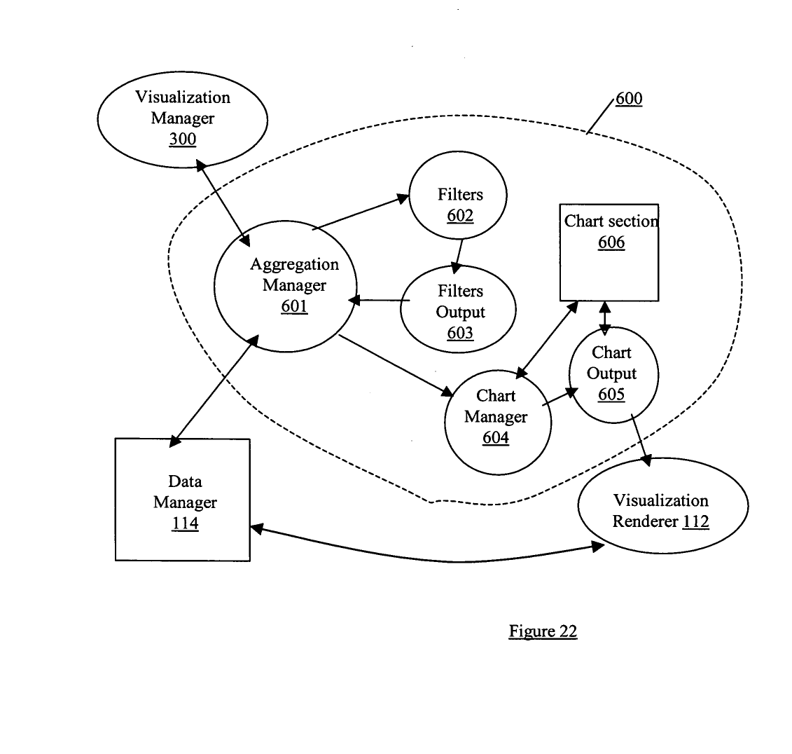

Standard icons for data objects 14 as well as small images 23 for such as but not limited to objects 20,22,24 can be used to describe entities such as people, organizations and objects. Icons are also used to describe activities. These can be standard or tailored icons, or actual images of people, places, and/or actual objects (e.g. buildings). Imagery can be used as part of the event description. Images 23 can be viewed in all of the visual representation 18 contexts, as for example shown in FIGS. 20 and 21 which show the use of images 23 in the time lines 422 and the time chart 430 views. Sequences of images 23 can be animated to help the user detect changes in the image over time and space.

Annotations 21

Annotations 21 in Geography and Time (see FIG. 22) can be represented as manually placed lines or other shapes (e.g. pen/pencil strokes) can be placed on the visual representation 18 by an operator of the tool 12 and used to annotate elements of interest with such as but not limited to arrows, circles and freeform markings. Some examples are shown in FIG. 21. These annotations 21 are located in geography (e.g. spatial domain 400) and time (e.g. temporal domain 422) and so can appear and disappear on the visual representation 18 as geographic and time contexts are navigated through the user input events 109.

Visualization Tool 12

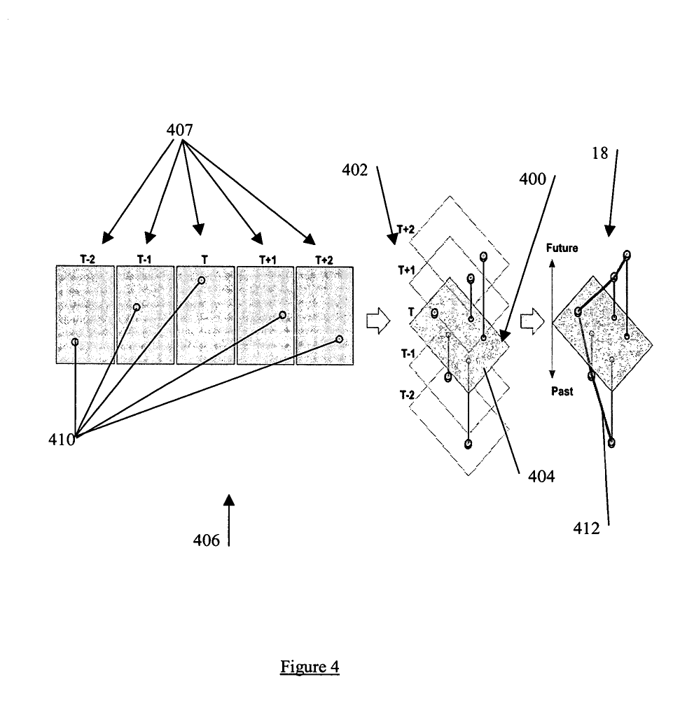

Referring to FIG. 3, the visualization tool 12 has a visualization manager 300 for interacting with the data objects 14 for presentation to the interface 202 via the VI manager 112. The Data Objects 14 are formed into groups 27 through the associations 26 and processed by the Visualization Manager 300. The groups 27 comprise selected subsets of the objects 20, 21, 22, 23, 24 combined via selected associations 26. This combination of data objects 14 and association sets 16 can be accomplished through predefined groups 27 added to the tables 122 and/or through the user events 109 during interaction of the user directly with selected data objects 14 and association sets 16 via the controls 306. It is recognized that the predefined groups 27 could be loaded into the memory 102 (and tables 122) via the computer readable medium 46 (see FIG. 2). The Visualization manager 300 also processes user event 109 input through interaction with a time slider and other controls 306, including several interactive controls for supporting navigation and analysis of information within the visual representation 18 (see FIG. 1) such as but not limited to data interactions of selection, filtering, hide/show and grouping as further described below. Use of the groups 27 is such that subsets of the objects 14 can be selected and grouped through associations 26. In this way, the user of the tool 12 can organize observations into related stories or story fragments. These groupings 27 can be named with a label and visibility controls, which provide for selected display of the groups 27 on the representation 18, e.g. the groups 27 can be turned on and off with respect to display to the user of the tool 12.

The Visualization Manager 300 processes the translation from raw data objects 14 to the visual representation 18. First, Data Objects 14 and associations 16 can be formed by the Visualization Manager 300 into the groups 27, as noted in the tables 122, and then processed. The Visualization Manager 300 matches the raw data objects 14 and associations 16 with sprites 308 (i.e. visual processing objects/components that know how to draw and render visual elements for specified data objects 14 and associations 16) and sets a drawing sequence for implementation by the VI manager 112. The sprites 308 are visualization components that take predetermined information schema as input and output graphical elements such as lines, text, images and icons to the computers graphics system. Entity 24, event 20 and location 22 data objects each can have a specialized sprite 308 type designed to represent them. A new sprite instance is created for each entity, event and location instance to manage their representation in the visual representation 18 on the display.

The sprites 308 are processed in order by the visualization manager 300, starting with the spatial domain (terrain) context and locations, followed by Events and Timelines, and finally Entities. Timelines are generated and Events positioned along them. Entities are rendered last by the sprites 308 since the entities depend on Event positions. It is recognised that processing order of the sprites 308 can be other than as described above.

The Visualization manager 112 renders the sprites 308 to create the final image including visual elements representing the data objects 14 and associates 16 of the groups 27, for display as the visual representation 18 on the interface 202. After the visual representation 18 is on the interface 202, the user event 109 inputs flow into the Visualization Manager, through the VI manager 112 and cause the visual representation 18 to be updated. The Visualization Manager 300 can be optimized to update only those sprites 308 that have changed in order to maximize interactive performance between the user and the interface 202.

Layout of the Visualization Representation 18

The visualization technique of the visualization tool 12 is designed to improve perception of entity activities, movements and relationships as they change over time in a concurrent time-geographic or time-diagrammatical context. The visual representation 18 of the data objects 14 and associations 16 consists of a combined temporal-spatial display to show interconnecting streams of events over a range of time on a map or other schematic diagram space, both hereafter referred to in common as a spatial domain 400 (see FIG. 4). Events can be represented within an X,Y,T coordinate space, in which the X,Y plane shows the spatial domain 400 (e.g. geographic space) and the Z-axis represents a time series into the future and past, referred to as a temporal domain 402. In addition to providing the spatial context, a reference surface (or reference spatial domain) 404 marks an instant of focus between before and after, such that events “occur” when they meet the surface of the ground reference surface 404. FIG. 4 shows how the visualization manager 300 (see FIG. 3) combines individual frames 406 (spatial domains 400 taken at different times Ti 407) of event/entity/location visual elements 410, which are translated into a continuous integrated spatial and temporal visual representation 18. It should be noted connection visual elements 412 can represent presumed location (interpolated) of Entity between the discrete event/entity/location represented by the visual elements 410. Another interpretation for connections elements 412 could be signifying communications between different Entities at different locations, which are related to the same event as further described below.

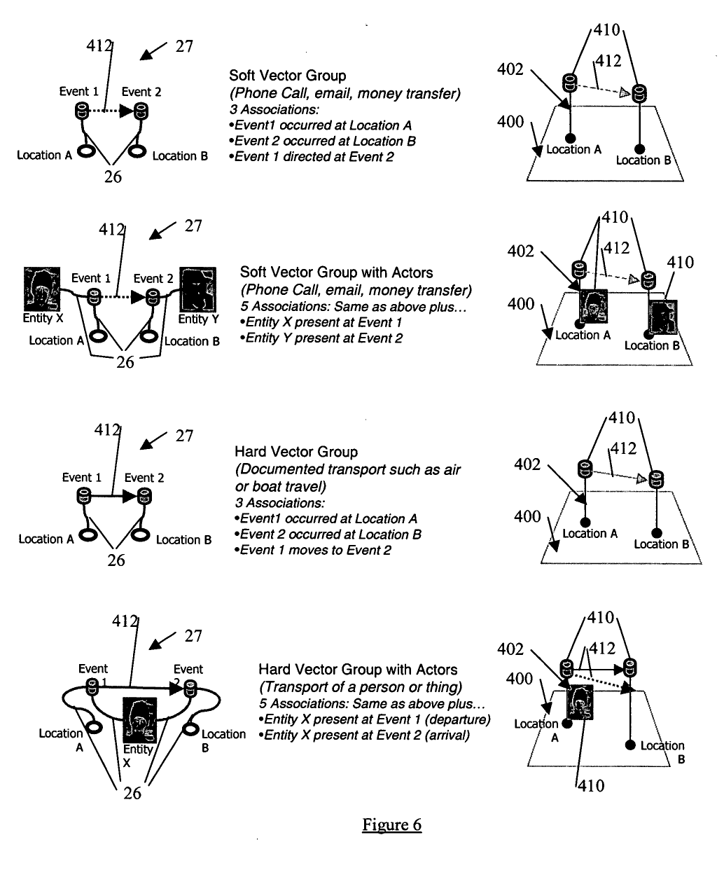

Referring to FIG. 5, an example visual representation 18 visually depicts events over time and space in an x, y, t space (or x, y, z, t space with elevation data). The example visual representation 18 generated by the tool 12 (see FIG. 2) is shown having the time domain 402 as days in April, and the spatial domain 400 as a geographical map providing the instant of focus (of the reference surface 404) as sometime around noon on April 23—the intersection point between the timelines 422 and the reference surface 404 represents the instant of focus. The visualization representation 18 represents the temporal 402, spatial 400 and connectivity elements 412 (between two visual elements 410) of information within a single integrated picture on the interface 202 (see FIG. 1). Further, the tool 12 provides an interactive analysis tool for the user with interface controls 306 to navigate the temporal, spatial and connectivity dimensions. The tool 12 is suited to the interpretation of any information in which time, location and connectivity are key dimensions that are interpreted together. The visual representation 18 is used as a visualization technique for displaying and tracking events, people, and equipment within the combined temporal and spatial domains 402, 400 display. Tracking and analyzing entities 24 and streams has traditionally been the domain of investigators, whether that be police services or military intelligence. In addition, business users also analyze events 20 in time and spatial domains 400, 402 to better understand phenomenon such as customer behavior or transportation patterns. The visualization tool 12 can be applied for both reporting and analysis.

The visual representation 18 can be applied as an analyst workspace for exploration, deep analysis and presentation for such as but not limited to:
Situations involving people and organizations that interact over time and in which geography or territory plays a role;
Storing and reviewing activity reports over a given period. Used in this way the representation 18 could provide a means to determine a living history, context and lessons learned from past events; and
As an analysis and presentation tool for long term tracking and surveillance of persons and equipment activities.

The visualization tool 12 provides the visualization representation 18 as an interactive display, such that the users (e.g. intelligence analysts, business marketing analysts) can view, and work with, large numbers of events. Further, perceived patterns, anomalies and connections can be explored and subsets of events can be grouped into “story” or hypothesis fragments. The visualization tool 12 includes a variety of capabilities such as but not limited to:
An event-based information architecture with places, events, entities (e.g. people) and relationships;
Past and future time visibility and animation controls;
Data input wizards for describing single events and for loading many events from a table;
Entity and event connectivity analysis in time and geography;
Path displays in time and geography;
Configurable workspaces allowing ad hoc, drag and drop arrangements of events;
Search, filter and drill down tools;
Creation of sub-groups and overlays by selecting events and dragging them into sets (along with associated spatial/time scope properties); and
Adaptable display functions including dynamic show/hide controls.
   Example Objects 14 with Associations 16

In the visualization tool 12, specific combinations of associated data elements (objects 20, 22, 24 and associations 26) can be defined. These defined groups 27 are represented visually as visual elements 410 in specific ways to express various types of occurrences in the visual representation 18. The following are examples of how the groups 27 of associated data elements can be formed to express specific occurrences and relationships shown as the connection visual elements 412.

Referring to FIGS. 6 and 7, example groups 27 (denoting common real world occurrences) are shown with selected subsets of the objects 20, 22, 24 combined via selected associations 26. The corresponding visualization representation 18 is shown as well including the temporal domain 402, the spatial domain 400, connection visual elements 412 and the visual elements 410 representing the event/entity/location combinations. It is noted that example applications of the groups 27 are such as but not limited to those shown in FIGS. 6 and 7. In the FIGS. 6 and 7 it is noted that event objects 20 are labeled as “Event 1”, “Event 2”, location objects 22 are labeled as “Location A”, “Location B”, and entity objects 24 are labeled as “Entity X”, “Entity Y”. The set of associations 16 are labeled as individual associations 26 with connections labeled as either solid or dotted lines 412 between two events, or dotted in the case of an indirect connection between two locations.

Visual Elements Corresponding to Spatial and Temporal Domains

The visual elements 410 and 412, their variations and behavior facilitate interpretation of the concurrent display of events in the time 402 and space 400 domains. In general, events reference the location at which they occur and a list of Entities and their role in the event. The time at which the event occurred or the time span over which the event occurred are stored as parameters of the event.

Spatial Domain Representation

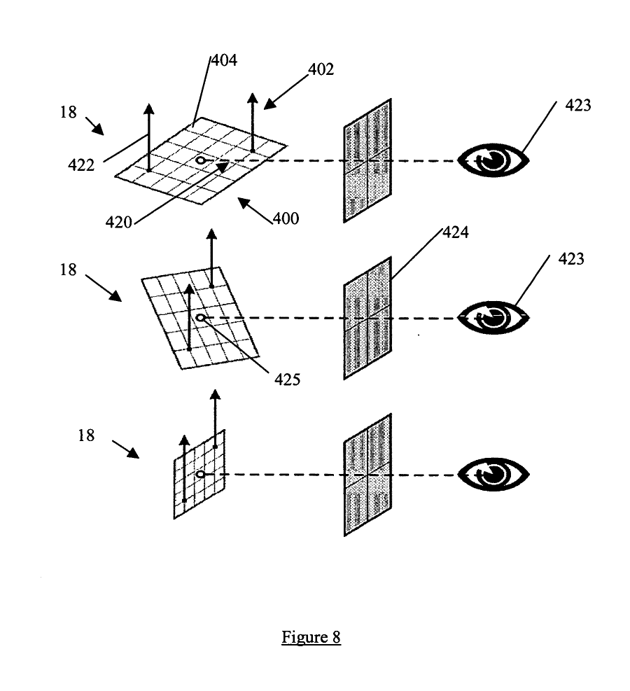

Referring to FIG. 8, the primary organizing element of the visualization representation 18 is the 2D/3D spatial reference frame (subsequently included herein with reference to the spatial domain 400). The spatial domain 400 consists of a true 2D/3D graphics reference surface 404 in which a 2D or 3 dimensional representation of an area is shown. This spatial domain 400 can be manipulated using a pointer device (not shown—part of the controls 306—see FIG. 3) by the user of the interface 108 (see FIG. 2) to rotate the reference surface 404 with respect to a viewpoint 420 or viewing ray extending from a viewer 423. The user (i.e. viewer 423) can also navigate the reference surface 404 by scrolling in any direction, zooming in or out of an area and selecting specific areas of focus. In this way the user can specify the spatial dimensions of an area of interest the reference surface 404 in which to view events in time. The spatial domain 400 represents space essentially as a plane (e.g. reference surface 404), however is capable of representing 3 dimensional relief within that plane in order to express geographical features involving elevation. The spatial domain 400 can be made transparent so that timelines 422 of the temporal domain 402 can extend behind the reference surface 404 are still visible to the user. FIG. 8 shows how the viewer 423 facing timelines 422 can rotate to face the viewpoint 420 no matter how the reference surface 404 is rotated in 3 dimensions with respect to the viewpoint 420.

The spatial domain 400 includes visual elements 410, 412 (see FIG. 4) that can represent such as but not limited to map information, digital elevation data, diagrams, and images used as the spatial context. These types of spaces can also be combined into a workspace. The user can also create diagrams using drawing tools (of the controls 306—see FIG. 3) provided by the visualization tool 12 to create custom diagrams and annotations within the spatial domain 400.

Event Representation and Interactions

Referring to FIGS. 4 and 8, events are represented by a glyph, or icon as the visual element 410, placed along the timeline 422 at the point in time that the event occurred. The glyph can be actually a group of graphical objects, or layers, each of which expresses the content of the event data object 20 (see FIG. 1) in a different way. Each layer can be toggled and adjusted by the user on a per event basis, in groups or across all event instances. The graphical objects or layers for event visual elements 410 are such as but not limited to:

1. Text Label
The Text label is a text graphic meant to contain a short description of the event content. This text always faces the viewer 423 no matter how the reference surface 404 is oriented. The text label incorporates a de-cluttering function that separates it from other labels if they overlap. When two events are connected with a line (see connections 412 below) the label will be positioned at the midpoint of the connection line between the events. The label will be positioned at the end of a connection line that is clipped at the edge of the display area.

2. Indicator—Cylinder, Cube or Sphere
The indicator marks the position in time. The color of the indicator can be manually set by the user in an event properties dialog. Color of event can also be set to match the Entity that is associated with it. The shape of the event can be changed to represent different aspect of information and can be set by the user. Typically it is used to represent a dimension such as type of event or level of importance.

3. Icon
An icon or image can also be displayed at the event location. This icon/image 23 may used to describe some aspect of the content of the event. This icon/image 23 may be user-specified or entered as part of a data file of the tables 122 (see FIG. 2).

4. Connection Elements 412
Connection elements 412 can be lines, or other geometrical curves, which are solid or dashed lines that show connections from an event to another event, place or target. A connection element 412 may have a pointer or arrowhead at one end to indicate a direction of movement, polarity, sequence or other vector-like property. If the connected object is outside of the display area, the connection element 412 can be coupled at the edge of the reference surface 404 and the event label will be positioned at the clipped end of the connection element 412.

5. Time Range Indicator
A Time Range Indicator (not shown) appears if an event occurs over a range of time. The time range can be shown as a line parallel to the timeline 422 with ticks at the end points. The event Indicator (see above) preferably always appears at the start time of the event.

The Event visual element 410 can also be sensitive to interaction. The following user events 109 via the user interface 108 (see FIG. 2) are possible, such as but not limited to:

Mouse-Left-Click:

Selects the visual element 410 of the visualization representation 18 on the VI 202 (see FIG. 2) and highlights it, as well as simultaneously deselecting any previously selected visual element 410, as desired.
   Ctrl-Mouse-Left-Click and Shift-Mouse-Left-Click
Adds the visual element 410 to an existing selection set.
   Mouse-Left-Double-Click:
Opens a file specified in an event data parameter if it exists. The file will be opened in a system-specified default application window on the interface 202 based on its file type.
   Mouse-Right-Click:
Displays an in-context popup menu with options to hide, delete and set properties.
   Mouse over Drilldown:
When the mouse pointer (not shown) is placed over the indicator, a text window is displayed next to the pointer, showing information about the visual element 410. When the mouse pointer is moved away from the indicator, the text window disappears.
   Location Representation

Locations are visual elements 410 represented by a glyph, or icon, placed on the reference surface 404 at the position specified by the coordinates in the corresponding location data object 22 (see FIG. 1). The glyph can be a group of graphical objects, or layers, each of which expresses the content of the location data object 22 in a different way. Each layer can be toggled and adjusted by the user on a per Location basis, in groups or across all instances. The visual elements 410 (e.g. graphical objects or layers) for Locations are such as but not limited to:

1. Text Label
The Text label is a graphic object for displaying the name of the location. This text always faces the viewer 422 no matter how the reference surface 404 is oriented. The text label incorporates a de-cluttering function that separates it from other labels if they overlap.

2. Indicator
The indicator is an outlined shape that marks the position or approximate position of the Location data object 22 on the reference surface 404. There are, such as but not limited to, 7 shapes that can be selected for the locations visual elements 410 (marker) and the shape can be filled or empty. The outline thickness can also be adjusted. The default setting can be a circle and can indicate spatial precision with size. For example, more precise locations, such as addresses, are smaller and have thicker line width, whereas a less precise location is larger in diameter, but uses a thin line width.
The Location visual elements 410 are also sensitive to interaction. The following interactions are possible:
   Mouse-Left-Click:
Selects the location visual element 410 and highlights it, while deselecting any previously selected location visual elements 410.
   Ctrl-Mouse-Left-Click and Shift-Mouse-Left-Click
Adds the location visual element 410 to an existing selection set.
   Mouse-Left-Double-Click:
Opens a file specified in a Location data parameter if it exists. The file will be opened in a system-specified default application window based on its file type.
   Mouse-Right-Click:
Displays an in-context popup menu with options to hide, delete and set properties of the location visual element 410.
   Mouseover Drilldown:
When the Mouse pointer is placed over the location indicator, a text window showing information about the location visual element 410 is displayed next to the pointer. When the mouse pointer is moved away from the indicator, the text window disappears.
   Mouse-Left-Click-Hold-and-Drag:
Interactively repositions the location visual element 410 by dragging it across the reference surface 404.
   Non-Spatial Locations

Locations 22 have the ability to represent indeterminate position. These are referred to as non-spatial locations 22. Locations 22 tagged as non-spatial can be displayed at the edge of the reference surface 404 just outside of the spatial context of the spatial domain 400. These non-spatial or virtual locations 22 can be always visible no matter where the user is currently zoomed in on the reference surface 404. Events and Timelines 422 that are associated with non-spatial Locations 22 can be rendered the same way as Events with spatial Locations 22.

Further, it is recognized that spatial locations 22 can represent actual, physical places, such that if the latitude/longitude is known the location 22 appears at that position on the map or if the latitude/longitude is unknown the location 22 appears on the bottom corner of the map (for example). Further, it is recognized that non-spatial locations 22 can represent places with no real physical location and can always appear off the right side of map (for example). For events 20, if the location 22 of the event 20 is known, the location 22 appears at that position on the map. However, if the location 22 is unknown, the location 22 can appear halfway (for example) between the geographical positions of the adjacent event locations 22 (e.g. part of target tracking).

Entity Representation

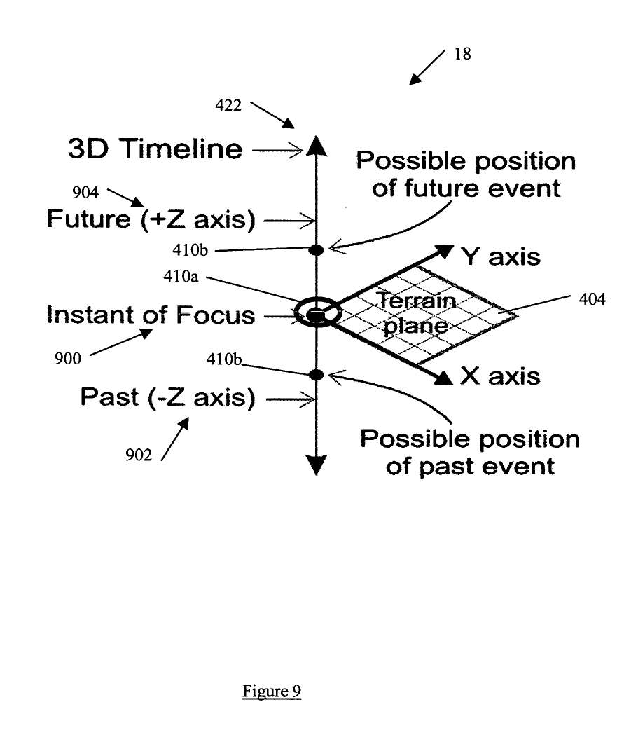

Entity visual elements 410 are represented by a glyph, or icon, and can be positioned on the reference surface 404 or other area of the spatial domain 400, based on associated Event data that specifies its position at the current Moment of Interest 900 (see FIG. 9) (i.e. specific point on the timeline 422 that intersects the reference surface 404). If the current Moment of Interest 900 lies between 2 events in time that specify different positions, the Entity position will be interpolated between the 2 positions. Alternatively, the Entity could be positioned at the most recent known location on the reference surface 404. The Entity glyph is actually a group of the entity visual elements 410 (e.g. graphical objects, or layers) each of which expresses the content of the event data object 20 in a different way. Each layer can be toggled and adjusted by the user on a per event basis, in groups or across all event instances. The entity visual elements 410 are such as but not limited to:

1. Text Label
The Text label is a graphic object for displaying the name of the Entity. This text always faces the viewer no matter how the reference surface 404 is oriented. The text label incorporates a de-cluttering function that separates it from other labels if they overlap.

2. Indicator
The indicator is a point showing the interpolated or real position of the Entity in the spatial context of the reference surface 404. The indicator assumes the color specified as an Entity color in the Entity data model.

3. Image Icon
An icon or image is displayed at the Entity location. This icon may used to represent the identity of the Entity. The displayed image can be user-specified or entered as part of a data file. The Image Icon can have an outline border that assumes the color specified as the Entity color in the Entity data model. The Image Icon incorporates a de-cluttering function that separates it from other Entity Image Icons if they overlap.

4. Past Trail
The Past Trail is the connection visual element 412, as a series of connected lines that trace previous known positions of the Entity over time, starting from the current Moment of Interest 900 and working backwards into past time of the timeline 422. Previous positions are defined as Events where the Entity was known to be located. The Past Trail can mark the path of the Entity over time and space simultaneously.

5. Future Trail
The Future Trail is the connection visual element 412, as a series of connected lines that trace future known positions of the Entity over time, starting from the current Moment of Interest 900 and working forwards into future time. Future positions are defined as Events where the Entity is known to be located. The Future Trail can mark the future path of the Entity over time and space simultaneously.

The Entity representation is also sensitive to interaction. The following interactions are possible, such as but not limited to:

Mouse-Left-Click:

Selects the entity visual element 410 and highlights it and deselects any previously selected entity visual element 410.
   Ctrl-Mouse-Left-Click and Shift-Mouse-Left-Click
Adds the entity visual element 410 to an existing selection set
   Mouse-Left-Double-Click:
Opens the file specified in an Entity data parameter if it exists. The file will be opened in a system-specified default application window based on its file type.
   Mouse-Right-Click:
Displays an in-context popup menu with options to hide, delete and set properties of the entity visual element 410.
   Mouseover Drilldown:
When the Mouse pointer is placed over the indicator, a text window showing information about the entity visual element 410 is displayed next to the pointer. When the mouse pointer is moved away from the indicator, the text window disappears.
   Temporal Domain Including Timelines

Referring to FIGS. 8 and 9, the temporal domain provides a common temporal reference frame for the spatial domain 400, whereby the domains 400, 402 are operatively coupled to one another to simultaneously reflect changes in interconnected spatial and temporal properties of the data elements 14 and associations 16. Timelines 422 (otherwise known as time tracks) represent a distribution of the temporal domain 402 over the spatial domain 400, and are a primary organizing element of information in the visualization representation 18 that make it possible to display events across time within the single spatial display on the VI 202 (see FIG. 1). Timelines 422 represent a stream of time through a particular Location visual element 410a positioned on the reference surface 404 and can be represented as a literal line in space. Other options for representing the timelines/time tracks 422 are such as but not limited to curved geometrical shapes (e.g. spirals) including 2D and 3D curves when combining two or more parameters in conduction with the temporal dimension. Each unique Location of interest (represented by the location visual element 410a) has one Timeline 422 that passes through it. Events (represented by event visual elements 410b) that occur at that Location are arranged along this timeline 422 according to the exact time or range of time at which the event occurred. In this way multiple events (represented by respective event visual elements 410b) can be arranged along the timeline 422 and the sequence made visually apparent. A single spatial view will have as many timelines 422 as necessary to show every Event at every location within the current spatial and temporal scope, as defined in the spatial 400 and temporal 402 domains (see FIG. 4) selected by the user. In order to make comparisons between events and sequences of event between locations, the time range represented by multiple timelines 422 projecting through the reference surface 404 at different spatial locations is synchronized. In other words the time scale is the same across all timelines 422 in the time domain 402 of the visual representation 18. Therefore, it is recognised that the timelines 422 are used in the visual representation 18 to visually depict a graphical visualization of the data objects 14 over time with respect to their spatial properties/attributes.

For example, in order to make comparisons between events 20 and sequences of events 20 between locations 410 of interest (see FIG. 4), the time range represented by the timelines 422 can be synchronized. In other words, the time scale can be selected as the same for every timeline 422 of the selected time range of the temporal domain 402 of the representation 18.

Representing Current, Past and Future

Three distinct strata of time are displayed by the timelines 422, namely;

1. The “moment of interest” 900 or browse time, as selected by the user,

2. a range 902 of past time preceding the browse time called “past”, and

3. a range 904 of time after the moment of interest 900, called “future”

On a 3D Timeline 422, the moment of focus 900 is the point at which the timeline intersects the reference surface 404. An event that occurs at the moment of focus 900 will appear to be placed on the reference surface 404 (event representation is described above). Past and future time ranges 902, 904 extend on either side (above or below) of the moment of interest 900 along the timeline 422. Amount of time into the past or future is proportional to the distance from the moment of focus 900. The scale of time may be linear or logarithmic in either direction. The user may select to have the direction of future to be down and past to be up or vice versa.

There are three basic variations of Spatial Timelines 422 that emphasize spatial and temporal qualities to varying extents. Each variation has a specific orientation and implementation in terms of its visual construction and behavior in the visualization representation 18 (see FIG. 1). The user may choose to enable any of the variations at any time during application runtime, as further described below.

3D Z-Axis Timelines

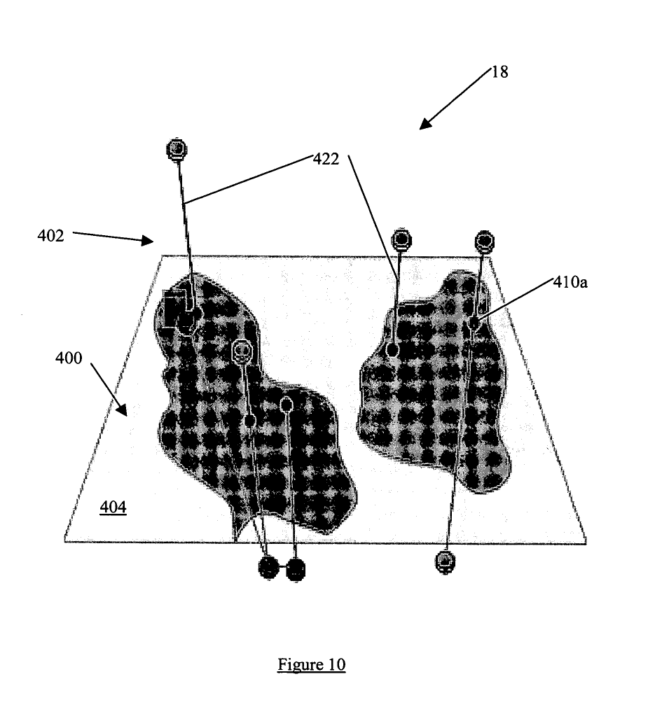

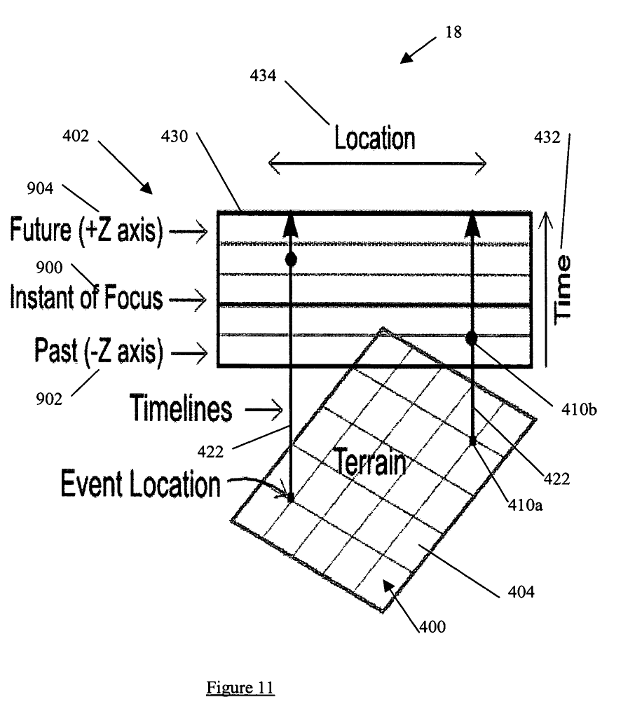

FIG. 10 shows how 3D Timelines 422 pass through reference surface 404 locations 410a. 3D timelines 422 are locked in orientation (angle) with respect to the orientation of the reference surface 404 and are affected by changes in perspective of the reference surface 404 about the viewpoint 420 (see FIG. 8). For example, the 3D Timelines 422 can be oriented normal to the reference surface 404 and exist within its coordinate space. Within the 3D spatial domain 400, the reference surface 404 is rendered in the X-Y plane and the timelines 422 run parallel to the Z-axis through locations 410a on the reference surface 404. Accordingly, the 3D Timelines 422 move with the reference surface 404 as it changes in response to user navigation commands and viewpoint changes about the viewpoint 420, much like flag posts are attached to the ground in real life. The 3D timelines 422 are subject to the same perspective effects as other objects in the 3D graphical window of the VI 202 (see FIG. 1) displaying the visual representation 18. The 3D Timelines 422 can be rendered as thin cylindrical volumes and are rendered only between events 410a with which it shares a location and the location 410a on the reference surface 404. The timeline 422 may extend above the reference surface 404, below the reference surface 404, or both. If no events 410b for its location 410a are in view the timeline 422 is not shown on the visualization representation 18.

3D Viewer Facing Timelines

Referring to FIG. 8, 3D Viewer-facing Timelines 422 are similar to 3D Timelines 422 except that they rotate about a moment of focus 425 (point at which the viewing ray of the viewpoint 420 intersects the reference surface 404) so that the 3D Viewer-facing Timeline 422 always remain perpendicular to viewer 423 from which the scene is rendered. 3D Viewer-facing Timelines 422 are similar to 3D Timelines 422 except that they rotate about the moment of focus 425 so that they are always parallel to a plane 424 normal to the viewing ray between the viewer 423 and the moment of focus 425. The effect achieved is that the timelines 422 are always rendered to face the viewer 423, so that the length of the timeline 422 is always maximized and consistent. This technique allows the temporal dimension of the temporal domain 402 to be read by the viewer 423 indifferent to how the reference surface 404 many be oriented to the viewer 423. This technique is also generally referred to as “billboarding” because the information is always oriented towards the viewer 423. Using this technique the reference surface 404 can be viewed from any direction (including directly above) and the temporal information of the timeline 422 remains readable.

Linked TimeChart Timelines

Referring to FIG. 11, showing how an overlay time chart 430 is connected to the reference surface 404 locations 410a by timelines 422. The timelines 422 of the Linked TimeChart 430 are timelines 422 that connect the 2D chart 430 (e.g. grid) in the temporal domain 402 to locations 410a marked in the 3D spatial domain 400. The timeline grid 430 is rendered in the visual representation 18 as an overlay in front of the 2D or 3D reference surface 404. The timeline chart 430 can be a rectangular region containing a regular or logarithmic time scale upon which event representations 410b are laid out. The chart 430 is arranged so that one dimension 432 is time and the other is location 434 based on the position of the locations 410a on the reference surface 404. As the reference surface 404 is navigated or manipulated the timelines 422 in the chart 430 move to follow the new relative location 410a positions. This linked location and temporal scrolling has the advantage that it is easy to make temporal comparisons between events since time is represented in a flat chart 430 space. The position 410b of the event can always be traced by following the timeline 422 down to the reference surface 404 to the location 410a.

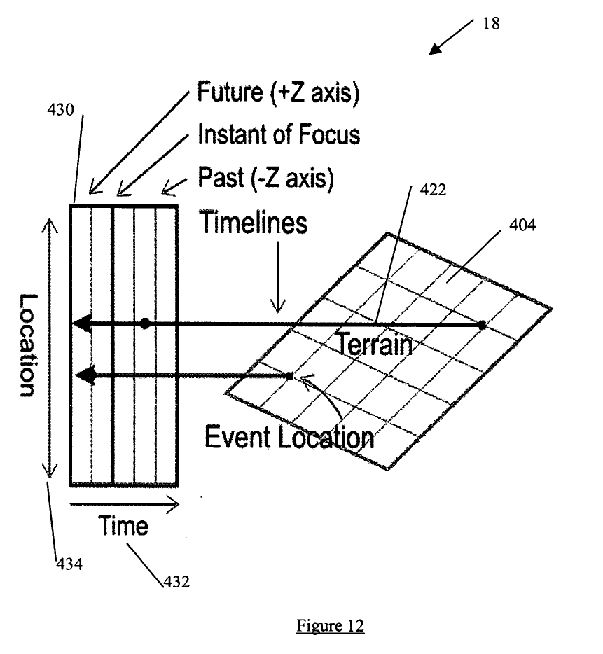

Referring to FIGS. 11 and 12, the TimeChart 430 can be rendered in 2 orientations, one vertical and one horizontal. In the vertical mode of FIG. 11, the TimeChart 430 has the location dimension 434 shown horizontally, the time dimension 432 vertically, and the timelines 422 connect vertically to the reference surface 404. In the horizontal mode of FIG. 12, the TimeChart 430 has the location dimension 434 shown vertically, the time dimension 432 shown horizontally and the timelines 422 connect to the reference surface 404 horizontally. In both cases the TimeChart 430 position in the visualization representation 18 can be moved anywhere on the screen of the VI 202 (see FIG. 1), so that the chart 430 may be on either side of the reference surface 404 or in front of the reference surface 404. In addition, the temporal directions of past 902 and future 904 can be swapped on either side of the focus 900.

Interaction Interface Descriptions

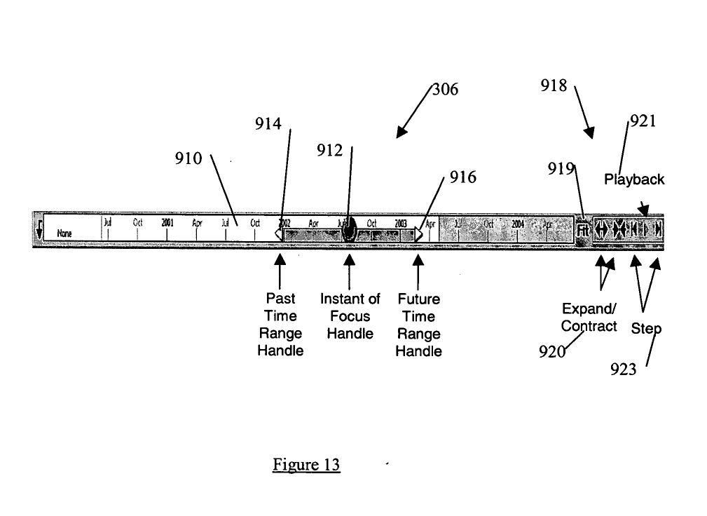

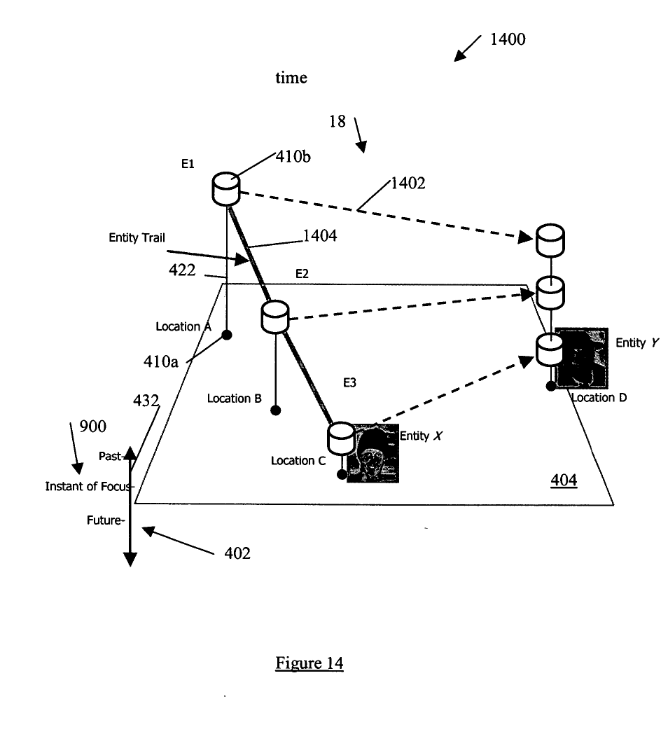

Referring to FIGS. 3 and 13, several interactive controls 306 support navigation and analysis of information within the visualization representation 12, as monitored by the visualization manger 300 in connection with user events 109. Examples of the controls 306 are such as but not limited to a time slider 910, an instant of focus selector 912, a past time range selector 914, and a future time selector 916. It is recognized that these controls 306 can be represented on the VI 202 (see FIG. 1) as visual based controls, text controls, and/or a combination thereof.

Time and Range Slider 901

The timeline slider 910 is a linear time scale that is visible underneath the visualization representation 18 (including the temporal 402 and spatial 400 domains). The control 910 contains sub controls/selectors that allow control of three independent temporal parameters: the Instant of Focus, the Past Range of Time and the Future Range of Time.

Continuous animation of events 20 over time and geography can be provided as the time slider 910 is moved forward and backwards in time. Example, if a vehicle moves from location A at t1 to location B at t2, the vehicle (object 23,24) is shown moving continuously across the spatial domain 400 (e.g. map). The timelines 422 can animate up and down at a selected frame rate in association with movement of the slider 910.

Instant of Focus

The instant of focus selector 912 is the primary temporal control. It is adjusted by dragging it left or right with the mouse pointer across the time slider 910 to the desired position. As it is dragged, the Past and Future ranges move with it. The instant of focus 900 (see FIG. 12) (also known as the browse time) is the moment in time represented at the reference surface 404 in the spatial-temporal visualization representation 18. As the instant of focus selector 912 is moved by the user forward or back in time along the slider 910, the visualization representation 18 displayed on the interface 202 (see FIG. 1) updates the various associated visual elements of the temporal 402 and spatial 400 domains to reflect the new time settings. For example, placement of Event visual elements 410 animate along the timelines 422 and Entity visual elements 410 move along the reference surface 404 interpolating between known locations visual elements 410 (see FIGS. 6 and 7). Examples of movement are given with reference to FIGS. 14, 15, and 16 below.

Past Time Range

The Past Time Range selector 914 sets the range of time before the moment of interest 900 (see FIG. 11) for which events will be shown. The Past Time range is adjusted by dragging the selector 914 left and right with the mouse pointer. The range between the moment of interest 900 and the Past time limit can be highlighted in red (or other colour codings) on the time slider 910. As the Past Time Range is adjusted, viewing parameters of the spatial-temporal visualization representation 18 update to reflect the change in the time settings.

Future Time Range

The Future Time Range selector 914 sets the range of time after the moment of interest 900 for which events will be shown. The Future Time range is adjusted by dragging the selector 916 left and right with the mouse pointer. The range between the moment of interest 900 and the Future time limit is highlighted in blue (or other colour codings) on the time slider 910. As the Future Time Range is adjusted, viewing parameters of the spatial-temporal visualization representation 18 update to reflect the change in the time settings.

The time range visible in the time scale of the time slider 910 can be expanded or contracted to show a time span from centuries to seconds. Clicking and dragging on the time slider 910 anywhere except the three selectors 912, 914, 916 will allow the entire time scale to slide to translate in time to a point further in the future or past. Other controls 918 associated with the time slider 910 can be such as a “Fit” button 919 for automatically adjusting the time scale to fit the range of time covered by the currently active data set displayed in the visualization representation 18. Controls 918 can include a Fit control 919, a scale-expand-contract controls 920, a step control 923, and a play control 922, which allow the user to expand or contract the time scale. A step control 918 increments the instant of focus 900 forward or back. The “playback” button 920 causes the instant of focus 900 to animate forward by a user-adjustable rate. This “playback” causes the visualization representation 18 as displayed to animate in sync with the time slider 910.

Simultaneous Spatial and Temporal Navigation can be provided by the tool 12 using, for example, interactions such as zoom-box selection and saved views. In addition, simultaneous spatial and temporal zooming can be used to provide the user to quickly move to a context of interest. In any view of the representation 18, the user may select a subset of events 20 and zoom to them in both time 402 and space 400 domains using a Fit Time and a Fit Space functions. These functions can happen simultaneously by dragging a zoom-box on to the time chart 430 itself. The time range and the geographic extents of the selected events 20 can be used to set the bounds of the new view of the representation 18, including selected domain 400,402 view formats.

Referring again to FIGS. 13 and 27, the Fit control 919 of the timer slider and other controls 306 can be further subdivided into separate fit time and fit geography/space functions as performed by a fit module 700. For example, with a single click via the controls 306, for the fit to geography function the fit module 700 can instruct the visualization manager 300 to zoom in to user selected objects 20,21,22,23,24 (i.e. visual elements 410) and/or connection elements 412 (see FIG. 17) in both/either space (FG) and/or time (FT), as displayed in a re-rendered “fit” version of the representation 18. For example, for fit to geography, after the user has selected places, targets and/or events (i.e. elements 410,412) from the representation 18, the fit module 700 instructs the visualization manager 300 to reduce/expand the displayed map of the representation 18 to only the geographic area that includes those selected elements 410,412. If nothing is selected, the map is fitted to the entire data set (i.e. all geographic areas) included in the representation 18. For example, for fit to time, after the user has selected places, targets and/or events (i.e. elements 410,412) from the representation 18, the fit module 700 instructs the visualization manager 300 to reduce/expand the past portion of the timeline(s) 422 to encompass only the period that includes the selected visual elements 410,412. Further, the fit module 700 can instruct the visualization manager 300 to adjust the display of the browse time slider as moved to the end of the period containing the selected visual elements 410,412 and the future portion of the timeline 422 can account for the same proportion of the visible timeline 422 as it did before the timeline(s) 422 were “time fitted”. If nothing is selected, the timeline is fitted to the entire data set (i.e. all temporal areas) included in the representation 18. Further, it is recognized, for both Fit to Geography and Fit to Timeline, if only targets are selected, the fit module 700 coordinates the display of the map/timeline to fit to the targets' entire set of events. Further for example, if a target is selected in addition to events, only those events selected are used in the fit calculation of the fit module 700.

Association Analysis Tools

Referring to FIGS. 1 and 3, an association analysis module 307 has functions that have been developed that take advantage of the association-based connections between Events, Entities and Locations. These functions 307 are used to find groups of connected objects 14 during analysis. The associations 16 connect these basic objects 20, 22, 24 into complex groups 27 (see FIGS. 6 and 7) representing actual occurrences. The functions are used to follow the associations 16 from object 14 to object 14 to reveal connections between objects 14 that are not immediately apparent. Association analysis functions are especially useful in analysis of large data sets where an efficient method to find and/or filter connected groups is desirable. For example, an Entity 24 maybe be involved in events 20 in a dozen places/locations 22, and each of those events 20 may involve other Entities 24. The association analysis function 307 can be used to display only those locations 22 on the visualization representation 18 that the entity 24 has visited or entities 24 that have been contacted.

The analysis functions A,B,C,D provide the user with different types of link analysis that display connections between 14 of interest, such as but limited to:

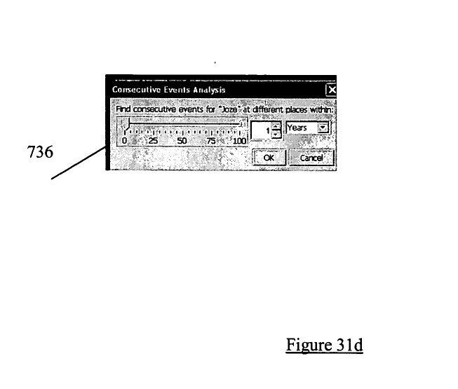

1. Expanding Search A, e.g. a Link Analysis Tool
The expanding search function A of the module 307 allows the user to start with a selected object(s) 14 and then incrementally show objects 14 that are associated with it by increasing degrees of separation. The user selects an object 14 or group of objects 14 of focus and clicks on the Expanding search button 920 this causes everything in the visualization representation 18 to disappear except the selected items. The user then increments the search depth (e.g. via an appropriate depth slider control) and objects 14 connected by the specified depth are made visible the display. In this way, sets of connected objects 14 are revealed as displayed using the visual elements 410 and 412.
Accordingly, the function A of the module 307 displays all objects 14 in the representation 18 that are connected to a selected object 14, within the specified range of separation. The range of separation of the function A can be selected by the user using the I/O interface 108, using a links slider 730 in a dialog window (see FIG. 31a). For example, this link analysis can be performed when a single place 22, target 24 or event 20 is first selected. An example operation of the depth slider is as follows, when the function A is first selected via the I/O interface 108, a dialog opens, and the links slider is initially set to 0 and only the selected object 14 is displayed in the representation 18.
Using the slider (or entry field), when the links slider is moved to 1, any object 14 directly linked (i.e. 1 degree of separation such as all elementary events 20) to the initially selected object 14 appears on the representation 18 in addition to the initially selected object 14. As the links slider is positioned higher up the slider scale, additional connected objects are added at each level to the representation 18, until all objects connected to the initially selected object 14 are displayed.

2. Connection Search B, e.g. a Join Analysis Tool
The Connection Search function B of the module 307 allows the user to connect any pair of objects 14 by their web of associations 26. The user selects any two objects 14 and clicks on the Connection Search function B. The connection search function B works by automatically scanning the extents of the web of associations 26 starting from one of the initially selected objects 14 of the pair. The search will continue until the second object 14 is found as one of the connected objects 14 or until there are no more connected objects 14. If a path of associated objects 14 between the target objects 14 exists, all of the objects 14 along that path are displayed and the depth is automatically displayed showing the minimum number of links between the objects 14.
Accordingly, the Join Analysis function B looks for and displays any specified connection path between two selected objects 14. This join analysis is performed when two objects 14 are selected from the representation 18. It is noted that if the two selected objects 14 are not connected, no events 20 are displayed and the connection level is set to zero on the display 202 (see FIG. 1). If the paired objects 14 are connected, the shortest path between them is automatically displayed, for example. It is noted that the Join Analysis function B can be generalized for three or more selected objects 14 and their connections. An example operation of the Join Analysis function B is a selection of the targets 24 Alan and Rome. When the dialog opens, the number of links 732 (e.g. 4—which is user adjustable—see FIG. 31b) required to make a connection between the two targets 24 is displayed to the user, and only the objects 14 involved in that connection (having 4 links) are visible on the representation 18.

3. A Chain Analysis Tool C
The Chain Analysis Tool C displays direct and/or indirect connections between a selected target 24 and other targets 24. For example, in a direct connection, a single event 20 connects target A and target B (who are both on the terrain 400). In an indirect connection, some number of events 20 (chain) connect A and B, via a target C (who is located off the terrain 400 for example). This analysis C can be performed with a single initial target 24 selected. For example, the tool C can be associated with a chaining slider 736—see FIG. 31c (accessed via the I/O interface 108) with the selections of such as but not limited to direct, indirect, and both. For example, the target TOM is first selected on the representation 18 and then when the target chaining slider is set to Direct, the targets ALAN and PARENTS are displayed, along with the events that cause TOM to be directly connected to them. In the case where TOM does not have any indirect target 24 connections, so moving the slider to Both and to Indirect does not change the view as generated on the representation 18 for the Direct chaining slider setting.

4. A Move Analysis Tool D
This tool D finds, for a single target 24, all sets of consecutive events 20, that are located at different places 22 that happened within the specific time range of the temporal domain 402. For example, this analysis of tool D may be performed with a single target 24 selected from the representation 18. In example operation of the tool D, the initial target 24 is selected, when a slider 736 opens, the time range slider 736 is set to one Year and quite a few connected events 20 may be displayed on the representation 18, which are connected to the initially selected target 24. When the slider 736 selection is changed to the unit type of one Week, the number of events 20 displayed will drop accordingly. Similarly, as the time range slider 736 is positioned higher, the number of events 20 are added to the representation 18 as the time range increases.

It is recognized that the functions of the module 307 can be used to implement filtering via such as but not limited to criteria matching, algorithmic methods and/or manual selection of objects 14 and associations 16 using the analytical properties of the tool 12. This filtering can be used to highlight/hide/show (exclusively) selected objects 14 and associations 16 as represented on the visual representation 18. The functions are used to create a group (subset) of the objects 14 and associations 16 as desired by the user through the specified criteria matching, algorithmic methods and/or manual selection. Further, it is recognized that the selected group of objects 14 and associations 16 could be assigned a specific name which is stored in the table 122.

Operation of Visual Tool to Generate Visualization Representation

Referring to FIG. 14, example operation 1400 shows communications 1402 and movement events 1404 (connection visual elements 412—see FIGS. 6 and 7) between Entities “X” and “Y” over time on the visualization representation 18. This FIG. 14 shows a static view of Entity X making three phone call communications 1402 to Entity Y from 3 different locations 410a at three different times. Further, the movement events 1404 are shown on the visualization representation 18 indicating that the entity X was at three different locations 410a (location A,B,C), which each have associated timelines 422. The timelines 422 indicate by the relative distance (between the elements 410b and 410a) of the events (E1,E2,E3) from the instant of focus 900 of the reference surface 404 that these communications 1404 occurred at different times in the time dimension 432 of the temporal domain 402. Arrows on the communications 1402 indicate the direction of the communications 1402, i.e. from entity X to entity Y. Entity Y is shown as remaining at one location 410a (D) and receiving the communications 1402 at the different times on the same timeline 422.

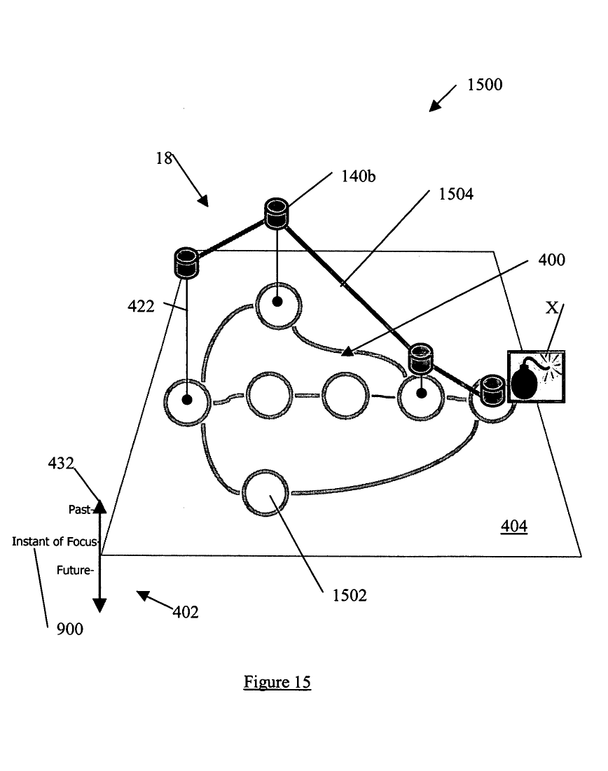

Referring to FIG. 15, example operation 1500 for shows Events 140b occurring within a process diagram space domain 400 over the time dimension 432 on the reference surface 404. The spatial domain 400 represents nodes 1502 of a process. This FIG. 14 shows how a flowchart or other graphic process can be used as a spatial context for analysis. In this case, the object (entity) X has been tracked through the production process to the final stage, such that the movements 1504 represent spatial connection elements 412 (see FIGS. 6 and 7).

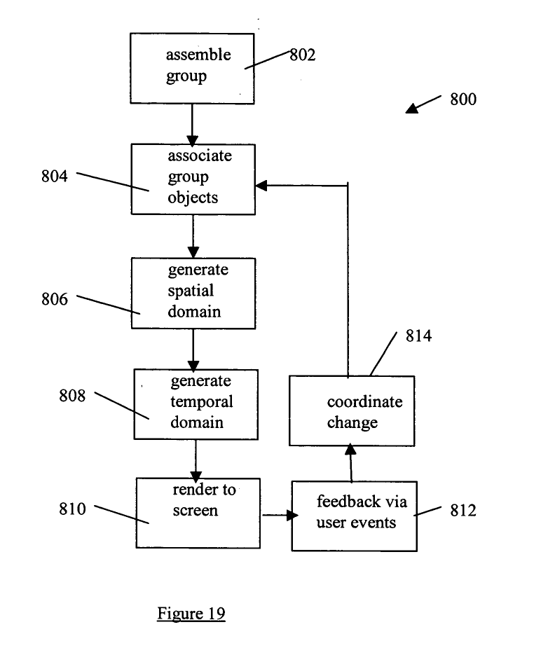

Referring to FIGS. 3 and 19, operation 800 of the tool 12 begins by the manager 300 assembling 802 the group of objects 14 from the tables 122 via the data manager 114. The selected objects 14 are combined 804 via the associations 16, including assigning the connection visual element 412 (see FIGS. 6 and 7) for the visual representation 18 between selected paired visual elements 410 corresponding to the selected correspondingly paired data elements 14 of the group. The connection visual element 412 represents a distributed association 16 in at least one of the domains 400, 402 between the two or more paired visual elements 410. For example, the connection element 412 can represent movement of the entity object 24 between locations 22 of interest on the reference surface 404, communications (money transfer, telephone call, email, etc . . . ) between entities 24 different locations 22 on the reference surface 404 or between entities 24 at the same location 22, or relationships (e.g. personal, organizational) between entities 24 at the same or different locations 22.

Next, the manager 300 uses the visualization components 308 (e.g. sprites) to generate 806 the spatial domain 400 of the visual representation 18 to couple the visual elements 410 and 412 in the spatial reference frame at various respective locations 22 of interest of the reference surface 404. The manager 300 then uses the appropriate visualization components 308 to generate 808 the temporal domain 402 in the visual representation 18 to include various timelines 422 associated with each of the locations 22 of interest, such that the timelines 422 all follow the common temporal reference frame. The manager 112 then takes the input of all visual elements 410, 412 from the components 308 and renders them 810 to the display of the user interface 202. The manager 112 is also responsible for receiving 812 feedback from the user via user events 109 as described above and then coordinating 814 with the manager 300 and components 308 to change existing and/or create (via steps 806, 808) new visual elements 410, 412 to correspond to the user events 109. The modified/new visual elements 410, 412 are then rendered to the display at step 810.

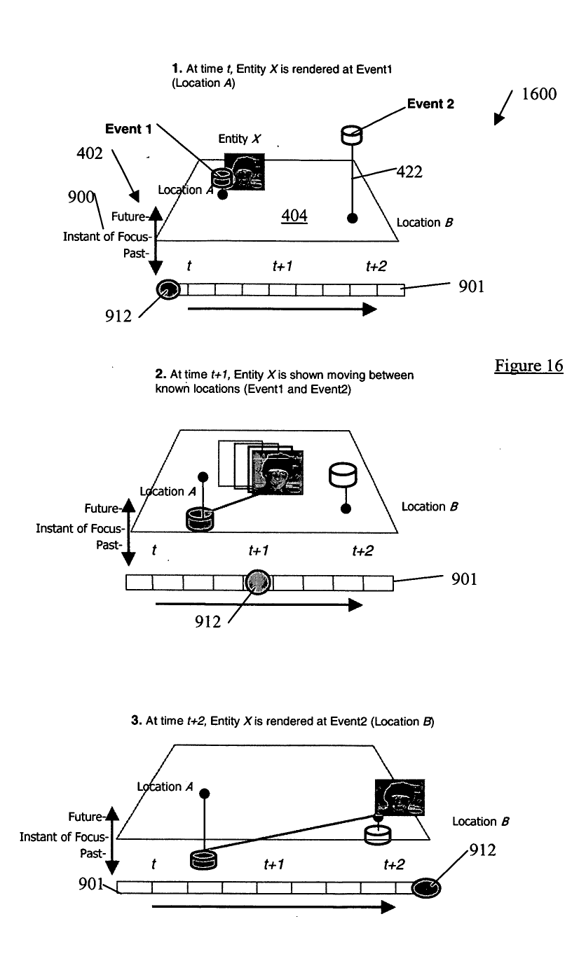

Referring to FIG. 16, an example operation 1600 shows animating entity X movement between events (Event 1 and Event 2) during time slider 901 interactions via the selector 912. First, the Entity X is observed at Location A at time t. As the slider selector 912 is moved to the right, at time t+1 the Entity X is shown moving between known locations (Event1 and Event2). It should be noted that the focus 900 of the reference surface 404 changes such that the events 1 and 2 move along their respective timelines 422, such that Event 1 moves from the future into the past of the temporal domain 402 (from above to below the reference surface 404). The length of the timeline 422 for Event 2 (between the Event 2 and the location B on the reference surface 404 decreases accordingly. As the slider selector 912 is moved further to the right, at time t+2, Entity X is rendered at Event2 (Location B). It should be noted that the Event 1 has moved along its respective timeline 422 further into the past of the temporal domain 402, and event 2 has moved accordingly from the future into the past of the temporal domain 402 (from above to below the reference surface 404), since the representation of the events 1 and 2 are linked in the temporal domain 402. Likewise, the entity X is linked spatially in the spatial domain 400 between event 1 at location A and event 2 at location B. It is also noted that the Time Slider selector 912 could be dragged along the time slider 910 by the user to replay the sequence of events from time t to t+2, or from t+2 to t, as desired.

Referring to FIG. 27, a further feature of the tool 12 is a target tracing module 722, which takes user input from the I/O interface 108 for tracing of a selected target/entity 24 through associated events 20. For example, the user of the tool 12 selects one of the events 20 from the representation 18 associated with one or more entities/target 24, whereby the module 722 provides for a selection icon to be displayed adjacent to the selected event 20 on the representation 18. Using the interface 108 (e.g. up/down arrows), the user can navigate the representation 18 by scrolling back and forward (in terms of time and/or geography) through the events 20 associated with that target 24, i.e. the display of the representation 18 adapts as the user scrolls through the time domain 402, as described already above. For example, the display of the representation 18 moves between consecutive events 20 associated with the target 24. In an example implementation of the I/O interface 08, the Page Up key moves the selection icon upwards (back in time) and the Page Down key moves the selection icon downwards (forward in time), such that after selection of a single event 20 with an associated target 24, the Page Up keyboard key would move the selection icon to the next event 20 (back in time) on the associated target's trail while selecting the Page Down key would return the selection icon to the first event 20 selected. The module 722 coordinates placement of the selection icon at consecutive events 20 connected with the associated target 24 while skipping over those events 20 (while scrolling) not connected with the associated target 24.

Referring to FIG. 17, the visual representation 18 shows connection visual elements 412 between visual elements 410 situated on selected various timelines 422. The timelines 422 are coupled to various locations 22 of interest on the geographical reference frame 404. In his case, the elements 412 represent geographical movement between various locations 22 by entity 24, such that all travel happened at some time in the future with respect to the instant of focus represented by the reference plane 404.

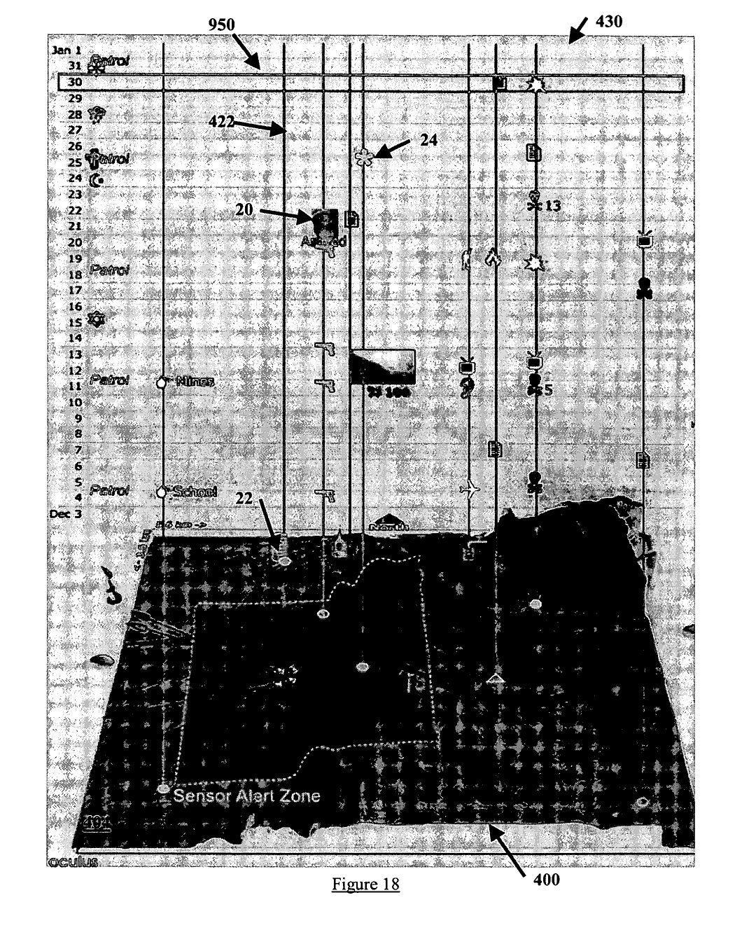

Referring to FIG. 18, the spatial domain 400 is shown as a geographical relief map. The time chart 430 is superimposed over the spatial domain of the visual representation 18, and shows a time period spanning from December 3^{rd} to January 1^{st} for various events 20 and entities 24 situated along various timelines 422 coupled to selected locations 22 of interest. It is noted that in this case the user can use the presented visual representation to coordinate the assignment of various connection elements 412 to the visual elements 410 (see FIG. 6) of the objects 20, 22, 24 via the user interface 202 (see FIG. 1), based on analysis of the displayed visual representation 18 content. A time selection 950 is January 30, such that events 20 and entities 24 within the selection box can be further analysed. It is recognised that the time selection 950 could be used to represent the instant of focus 900 (see FIG. 9).

Aggregation Module 600

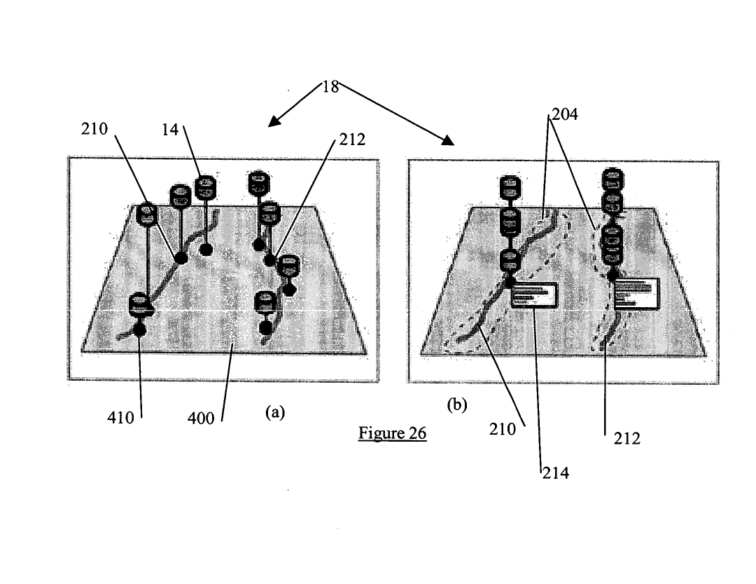

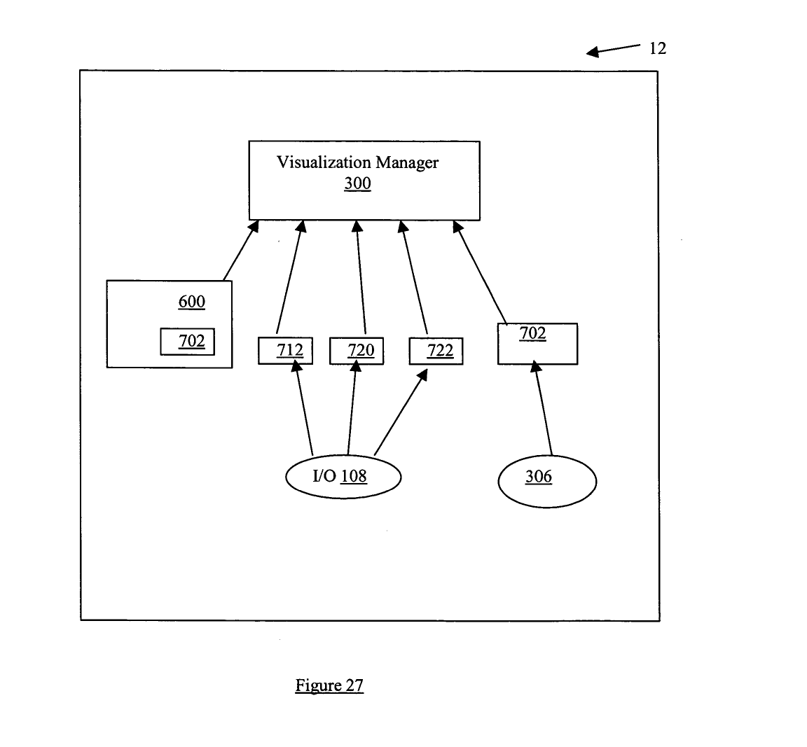

Referring to FIG. 3, an Aggregation Module 600 is for, such as but not limited to, summarizing or aggregating the data objects 14, providing the summarized or aggregated data objects 14 to the Visualization Manager 300 which processes the translation from data objects 14 and group of data elements 27 to the visual representation 18, and providing the creation of summary charts 200 (see FIG. 26) for displaying information related to summarised/aggregated data objects 14 as the visual representation 18 on the display 108.

Referring to FIGS. 3 and 22, the spatial inter-connectedness of information over time and geography within a single, highly interactive 3-D view of the representation 18 is beneficial to data analysis (of the tables 122). However, when the number of data objects 14 increases, techniques for aggregation become more important. Many individual locations 22 and events 20 can be combined into a respective summary or aggregated output 603. Such outputs 603 of a plurality of individual events 20 and locations 22 (for example) can help make trends in time and space domains 400,402 more visible and comparable to the user of the tool 12. Several techniques can be implemented to support aggregation of data objects 14 such as but not limited to techniques of hierarchy of locations, user defined geo-relations, and automatic LOD level selection, as further described below. The tool 12 combines the spatial and temporal domains 400, 402 on the display 108 for analysis of complex past and future events within a selected spatial (e.g. geographic) context.

Referring to FIG. 22, the Aggregation Module 600 has an Aggregation Manager 601 that communicates with the Visualization Manager 300 for receiving aggregation parameters used to formulate the output 603. The parameters can be either automatic (e.g. tool pre-definitions) manual (entered via events 109) or a combination thereof. The manager 601 accesses all possible data objects 14 through the Data Manager 114 (related to the aggregation parameters—e.g. time and/or spatial ranges and/or object 14 types/combinations) from the tables 122, and then applies aggregation tools or filters 602 for generating the output 603. The Visualization Manager 300 receives the output 603 from the Aggregation Manager 601, based on the user events 109 and/or operation of the Time Slider and other Controls 306 by the user for providing the aggregation parameters. As described above, once the output 603 is requested by the Visualization Manager 114, the Aggregation Manager 601 communicates with the Data Manager 114 access all possible data objects 14 for satisfying the most general of the aggregation parameters and then applies the filters 602 to generate the output 603. It is recognised however, that the filters 602 could be used by the manager 601 to access only those data objects 14 from the tables 122 that satisfy the aggregation parameters, and then copy those selected data objects 14 from the tables 122 for storing/mapping as the output 603.

Accordingly, the Aggregation Manager 601 can make available the data elements 14 to the Filters 602. The filters 602 act to organize and aggregate (such as but not limited to selection of data objects 14 from the global set of data in the tables 122 according to rules/selection criteria associated with the aggregation parameters) the data objects 14 according the instructions provided by the Aggregation Manager 601. For example, the Aggregation Manager 601 could request that the Filters 602 summarize all data objects 14 with location data 22 corresponding to Paris. Or, in another example, the Aggregation Manager 601 could request that the Filters 602 summarize all data objects 14 with event data 20 corresponding to Wednesdays. Once the data objects 14 are selected by the Filters 602, the aggregated data is summarised as the output 603. The Aggregation Manager 601 then communicates the output 603 to the Visualization Manager 300, which processes the translation from the selected data objects 14 (of the aggregated output 603) for rendering as the visual representation 18. It is recognised that the content of the representation 18 is modified to display the output 603 to the user of the tool 12, according to the aggregation parameters.

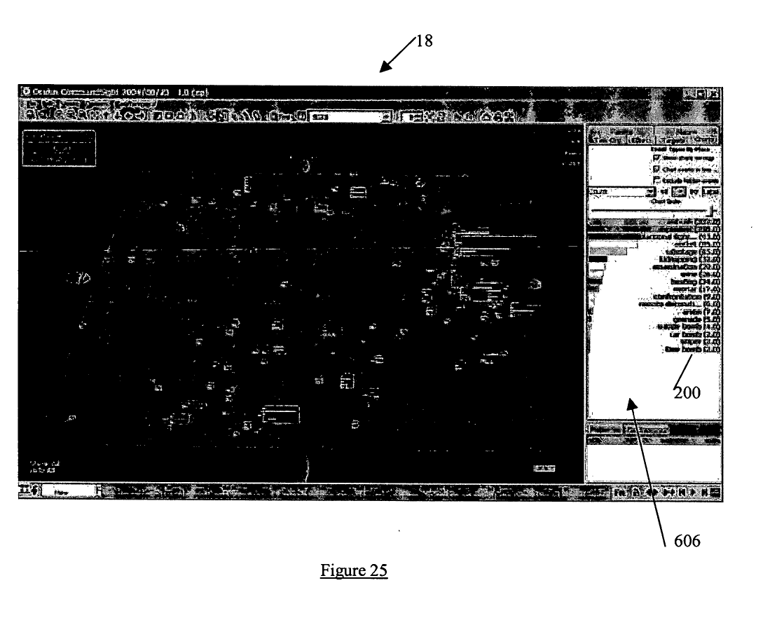

Further, the Aggregation Manager 601 provides the aggregated data objects 14 of the output 603 to a Chart Manager 604. The Chart Manager 604 compiles the data in accordance with the commands it receives from the Aggregation Manager 601 and then provides the formatted data to a Chart Output 605. The Chart Output 605 provides for storage of the aggregated data in a Chart section 606 of the display (see FIG. 25). Data from the Chart Output 605 can then be sent directly to the Visualization Renderer 112 or to the visualisation manager 300 for inclusion in the visual representation 18, as further described below.

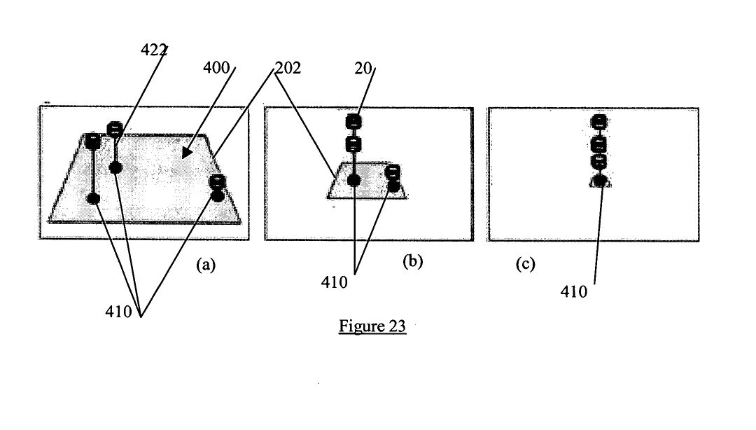

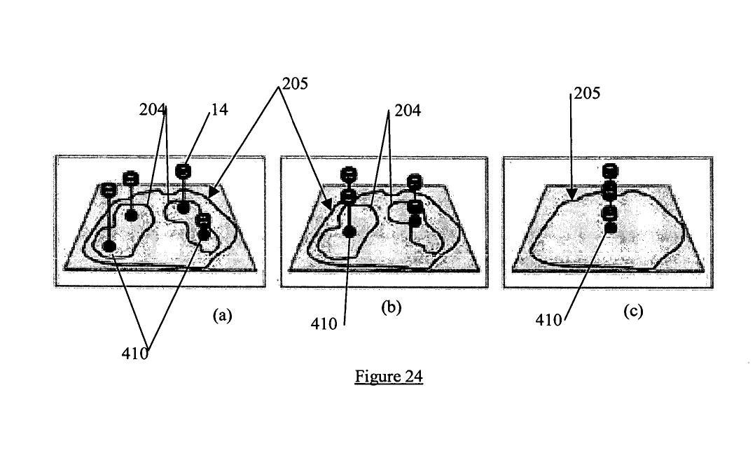

Referring to FIG. 23, an example aggregation of data objects 14 by the Aggregation Module 601 is shown. The event data 20 (for example) is aggregated according to spatial proximity (threshold) of the data objects 14 with respect to a common point (e.g. particular location 410 or other newly specified point of the spatial domain 400), difference threshold between two adjacent locations 410, or other spatial criteria as desired. For example, as depicted in FIG. 23a, the three data objects 20 at three locations 410 are aggregated to two objects 20 at one location 410 and one object at another location 410 (e.g. combination of two locations 410) as a user-defined field 202 of view is reduced in FIG. 23b, and ultimately to one location 410 with all three objects 20 in FIG. 23c. It is recognised in this example of aggregated output 603 that timelines 422 of the locations 410 are combined as dictated by the aggregation of locations 410.

For example, the user may desire to view an aggregate of data objects 14 related within a set distance of a fixed location, e.g., aggregate of events 20 occurring within 50 km of the Golden Gate Bridge. To accomplish this, the user inputs their desire to aggregate the data according to spatial proximity, by use of the controls 306, indicating the specific aggregation parameters. The Visualization Manager 300 communicates these aggregation parameters to the Aggregation Module 600, in order for filtering of the data content of the representation 18 shown on the display 108. The Aggregation Module 600 uses the Filters 602 to filter the selected data from the tables 122 based on the proximity comparison between the locations 410. In another example, a hierarchy of locations can be implemented by reference to the association data 26 which can be used to define parent-child relationships between data objects 14 related to specific locations within the representation 18. The parent-child relationships can be used to define superior and subordinate locations that determine the level of aggregation of the output 603.

Referring to FIG. 24, an example aggregation of data objects 14 by the Aggregation Module 601 is shown. The data 14 is aggregated according to defined spatial boundaries 204. To accomplish this, the user inputs their desire to aggregate the data 14 according to specific spatial boundaries 204, by use of the controls 306, indicating the specific aggregation parameters of the filtering 602. For example, a user may wish to aggregate all event 20 objects located within the city limits of Toronto. The Visualization Manager 300 then requests to the Aggregation Module 600 to filter the data objects 14 of the current representation according to the aggregation parameters. The Aggregation Module 600 provides implements or otherwise applies the filters 602 to filter the data based on a comparison between the location data objects 14 and the city limits of Toronto, for generating the aggregated output 603. In FIG. 24a, within the spatial domain 205 the user has specified two regions of interest 204, each containing two locations 410 with associated data objects 14. In FIG. 24b, once filtering has been applied, the locations 410 of each region 204 have been combined such that now two locations 410 are shown with each having the aggregated result (output 603) of two data objects 14 respectively. In FIG. 24c, the user has defined the region of interest to be the entire domain 205, thereby resulting in the displayed output 603 of one location 410 with three aggregated data objects 14 (as compared to FIG. 24a). It is noted that the positioning of the aggregated location 410 is at the center of the regions of interest 204, however other positioning can be used such as but not limited to spatial averaging of two or more locations 410 or placing aggregated object data 14 at one of the retained original locations 410, or other positioning techniques as desired.

In addition to the examples in illustrated in FIGS. 21 and 22, the aggregation of the data objects can be accomplished automatically based on the geographic view scale provided in the visual representations. Aggregation can be based on level of detail (LOD) used in mapping geographical features at various scales. On a 1:25,000 map, for example, individual buildings may be shown, but a 1:500,000 map may show just a point for an entire city. The aggregation module 600 can support automatic LOD aggregation of objects 14 based on hierarchy, scale and geographic region, which can be supplied as aggregation parameters as predefined operation of the controls 306 and/or specific manual commands/criteria via user input events 109. The module 600 can also interact with the user of the tool 12 (via events 109) to adjust LOD behaviour to suit the particular analytical task at hand.

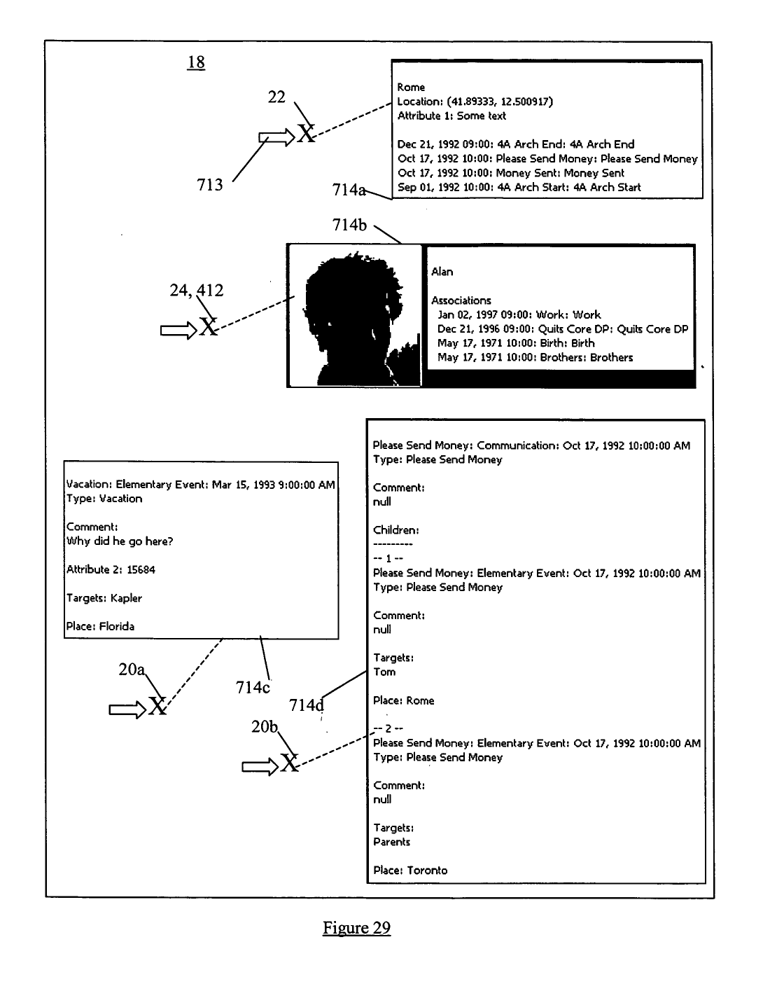

Referring to FIG. 27 and FIG. 28, the aggregation module 600 can also have a place aggregation module 702 for assigning visual elements 410,412 (e.g. events 20) of several places/locations 22 to one common aggregation location 704, for the purpose of analyzing data for an entire area (e.g. a convoy route or a county). It is recognised that the place aggregation function can be turned on and off for each aggregation location 704, so that the user of the tool 12 can analyze data with and without the aggregation(s) active. For example, the user creates the aggregation location 704 in a selected location of the spatial domain 400 of the representation 18. The user then gives the created aggregation location 704 a label 706 (e.g. North America). The user then selects a plurality of locations 22 from the representation, either individually or as a group using a drawing tool 707 to draw around all desired locations 22 within a user defined region 708. Once selected, the user can drag or toggle the selected regions 708 and individual locations 22 to be included in the created aggregation location 704 by the aggregation module 702. The aggregation module 702 could instruct the visualization manager 300 to refresh the display of the representation 18 to display all selected locations 22 and related visual elements 410,412 in the created aggregation location 704. It is recognised that the aggregation module 702 could be used to configure the created aggregation location 704 to display other selected object types (e.g. entities 24) as a displayed group. In the case of selected entities 24, the created aggregation location 704 could be labelled the selected entities' name and all visual elements 410,412 associated with the selected entity (or entities) would be displayed in the created aggregation location 704 by the aggregation module 702. It is recognised that the above-described same aggregation operation could be done for selected event 20 types, as desired.

Referring to FIG. 25, an example of a spatial and temporal visual representation 18 with summary chart 200 depicting event data 20 is shown. For example, a user may wish to see the quantitative information relating to a specific event object. The user would request the creation of the chart 200 using the controls 306, which would submit the request to the Visualization Manager 300. The Visualization Manager 300 would communicate with the Aggregation Module 600 and instruct the creation of the chart 200 depicting all of the quantitative information associated with the data objects 14 associated with the specific event object 20, and represent that on the display 108 (see FIG. 2) as content of the representation 18. The Aggregation Module 600 would communicate with the Chart Manager 604, which would list the relevant data and provide only the relevant information to the Chart Output 605. The Chart Output 605 provides a copy of the relevant data for storage in the Chart Comparison Module, and the data output is communicated from the Chart Output 605 to the Visualization Renderer 112 before being included in the visual representation 18. The output data stored in the Chart Comparison section 606 can be used to compare to newly created charts 200 when requested from the user. The comparison of data occurs by selecting particular charts 200 from the chart section 606 for application as the output 603 to the Visual Representation 18.

The charts 200 rendered by the Chart Manager 604 can be created in a number of ways. For example, all the data objects 14 from the Data Manager 114 can be provided in the chart 200. Or, the Chart Manager 604 can filter the data so that only the data objects 14 related to a specific temporal range will appear in the chart 200 provided to the Visual Representation 18. Or, the Chart Manager 604 can filter the data so that only the data objects 14 related to a specific spatial and temporal range will appear in the chart 200 provided to the Visual Representation 18.

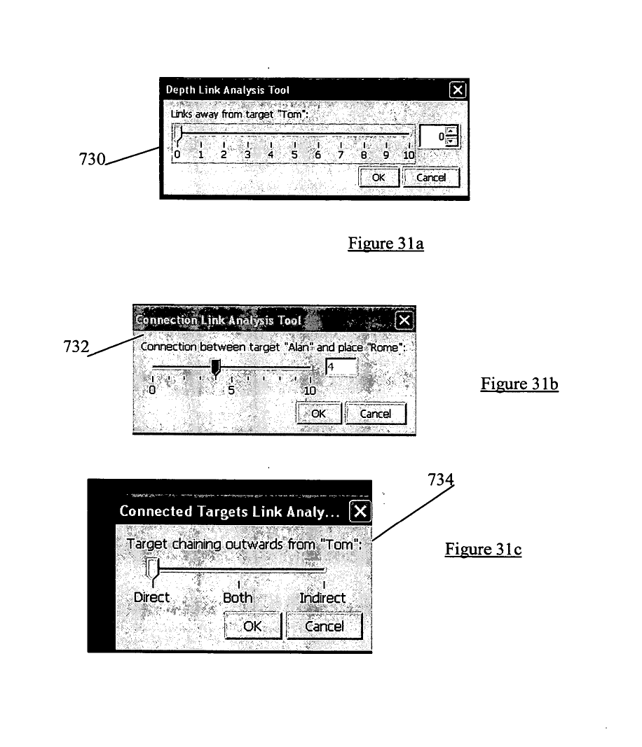

Referring to FIG. 30, a further embodiment of event aggregation charts 200 calculates and displays (both visually and numerically) the count objects by various classifications 726. When charts 200 are displayed on the map (e.g. on-map chart), one chart 200 is created for each place 22 that is associated with relevant events 20. Additional options become available by clicking on the colored chart bars 728 (e.g. Hide selected objects, Hide target). By default, the chart manager 604 (see FIG. 22) can assign colors to chart bars 728 randomly, except for example when they are for targets 24, in which case the chart manager 604 uses existing target 24 colors, for convenience. It is noted that a Chart scale slider 730 can be used to to increase or decrease the scale of on-map charts 200, e.g. slide right or left respectively. The chart manager 604 can generate the charts 200 based on user selected options 724, such as but not limited to:

1) Show Charts on Map—presents a visual display on the map, one chart 200 for each place 22 that has relevant events 20;

2) Chart Events in Time Range Only—includes only events 20 that happened during the currently selected time range;

3) Exclude Hidden Events—excludes events 20 that are not currently visible on the display (occur within current time range, but are hidden);

4) Color by Event—when this option is turned on, event 20 color is used for any bar 728 that contains only events 20 of that one color. When a bar 728 contains events 20 of more than one color, it is displayed gray;

5) Sort by Value—when turned on, results are displayed in the Charts 200 panel, sorted by their value, rather than alphabetically; and

6) Show Advanced Options—gives access to additional statistical calculations.

In a further example of the aggregation module 601, user-defined location boundaries 204 can provide for aggregation of data 14 across an arbitrary region. Referring to FIG. 26, to compare a summary of events along two separate routes 210 and 212, aggregation output 603 of the data 14 associated with each route 210,212 would be created by drawing an outline boundary 204 around each route 210,212 and then assigning the boundaries 204 to the respective locations 410 contained therein, as depicted in FIG. 26a. By the user adjusting the aggregation level in the Filters 602 through specification of the aggregation parameters of the boundaries 204 and associated locations 410, the data 14 is the aggregated as output 603 (see FIG. 26b) within the outline regions into the newly created locations 410, with the optional display of text 214 providing analysis details for those new aggregated locations 410. For example, the text 214 could summarise that the number of bad events 20 (e.g. bombings) is greater for route 210 than route 212 and therefore route 212 would be the route of choice based on the aggregated output 603 displayed on the representation 18.

It will be appreciated that variations of some elements are possible to adapt the invention for specific conditions or functions. The concepts of the present invention can be further extended to a variety of other applications that are clearly within the scope of this invention.

For example, one application of the tool 12 is in criminal analysis by the “information producer”. An investigator, such as a police officer, could use the tool 12 to review an interactive log of events 20 gathered during the course of long-term investigations. Existing reports and query results can be combined with user input data 109, assertions and hypotheses, for example using the annotations 21. The investigator can replay events 20 and understand relationships between multiple suspects, movements and the events 20. Patterns of travel, communications and other types of events 20 can be analysed through viewing of the representation 18 of the data in the tables 122 to reveal such as but not limited to repetition, regularity, and bursts or pauses in activity.

Subjective evaluations and operator trials with four subject matter experts have been conducted using the tool 12. These initial evaluations of the tool 12 were run against databases of simulated battlefield events and analyst training scenarios, with many hundreds of events 20. These informal evaluations show that the following types of information can be revealed and summarised. What significant events happened in this area in the last X days? Who was involved? What is the history of this person? How are they connected with other people? Where are the activity hot spots? Has this type of event occurred here or elsewhere in the last Y period of time?

With respect to potential applications and the utility of the tool 12, encouraging and positive remarks were provided by military subject matter experts in stability and support operations. A number of those remarks are provided here. Preparation for patrolling involved researching issues including who, where and what. The history of local belligerent commanders and incidents. Tracking and being aware of history, for example, a ceasefire was organized around a religious calendar event. The event presented an opportunity and knowing about the event made it possible. In one campaign, the head of civil affairs had been there twenty months and had detailed appreciation of the history and relationships. Keeping track of trends. What happened here? What keeps happening here? There are patterns. Belligerents keep trying the same thing with new rotations [a rotation is typically six to twelve months tour of duty]. When the attack came, it did come from the area where many previous earlier attacks had also originated. The discovery of emergent trends . . . persistent patterns . . . sooner rather than later could be useful. For example, the XXX Colonel that tends to show up in an area the day before something happens. For every rotation a valuable knowledge base can be created, and for every rotation, this knowledge base can be retained using the tool 12 to make the knowledge base a valuable historical record. The historical record can include events, factions, populations, culture, etc.

Referring to FIG. 27, the tool 12 could also have a report generation module 720 that saves a JPG format screenshot (or other picture format), with a title and description (optional—for example entered by the user) included in the screenshot image, of the visual representation 18 displayed on the visual interface 202 (see FIG. 1). For example, the screenshot image could include all displayed visual elements 410,412, including any annotations 21 or other user generated analysis related to the displayed visual representation 18, as selected or otherwise specified by the user. A default mode could be all currently displayed information is captured by the report generation module 720 and saved in the screenshot image, along with the identifying label (e.g. title and/or description as noted above) incorporated as part of the screenshot image (e.g. superimposed on the lower right-hand corner of the image). Otherwise the user could select (e.g. from a menu) which subset of the displayed visual elements 410,412 (on a category/individual basis) is for inclusion by the module 720 in the screenshot image, whereby all non-selected visual elements 410,412 would not be included in the saved screenshot image. The screenshot image would then be given to the data manager 114 (see FIG. 3) for storing in the database 122. For further information detail of the visual representation 18 not captured in the screenshot image, a filename (or other link such as a URL) to the non-displayed information could also be superimposed on the screenshot image, as desired. Accordingly, the saved screenshot image can be subsequently retrieved and used as a quick visual reference for more detailed underlying analysis linked to the screenshot image. Further, the link to the associated detailed analysis could be represented on the subsequently displayed screenshot image as a hyperlink to the associated detailed analysis, as desired.

Diagrammatic Context Spaces/Domains 401

The idea of a “process” is broadly applicable to intelligence analysis as described in “Warning Analysis for the Information Age: Rethinking the Intelligence Process” published in Joint Military Intelligence College by Bodnar in 2003 and in “GeoTime Information Visualization” published in IEEE InfoViz by Wright et al in 2004. People are habitual and many things can be expressed as processes with sequential events and generic timelines. In analysis, a process description or model provides a context and a logical framework for reasoning about the subject. A process model helps to review what is happening, why is it happening, and what can be done about it.

Since geography is only one context in which to see and conceptualize events, connections and flows, it would be beneficial to develop the visual representation 18 of multidimensional data according to abstract diagrammatic reasoning frameworks represented by the Diagrammatic Context domains 401. For example, Diagrammatic Context domains 401 with coupling to the temporal domain 402 could be used to understand problems, such as but not limited to: when there are multiple “spaces”; the organizational space for infrastructure and structure; the project space for sequence of assembly and transportation; the physical space; the decision space that is process, behavioral and issue dependent and can be a network or a hierarchy or a societal way of decision making, and how decisions are made, including fluidity with coalitions forming, and arguments laid out, and with people influencing other people; programs modeled in 6-D: 3D, time, entropy, enthalpy and organizational chart that can form graphical hypotheses; time vs. entropy, i.e. time vs. degree of assembly or disassembly, and see over time the progression from a generic R&D facility to an applied R&D facility to a production plant for product assembly resulting from the initial R&D activities; and assessments of intent built on understanding people and the organizations, nations and cultures they build. It is recognized that locations of interest in diagrammatic space can change in existence as well as in location over time for a particular context (e.g. environment 52) of the diagrammatic domain 401 and that multiple contexts are possible for any particular diagrammatic domain 401.

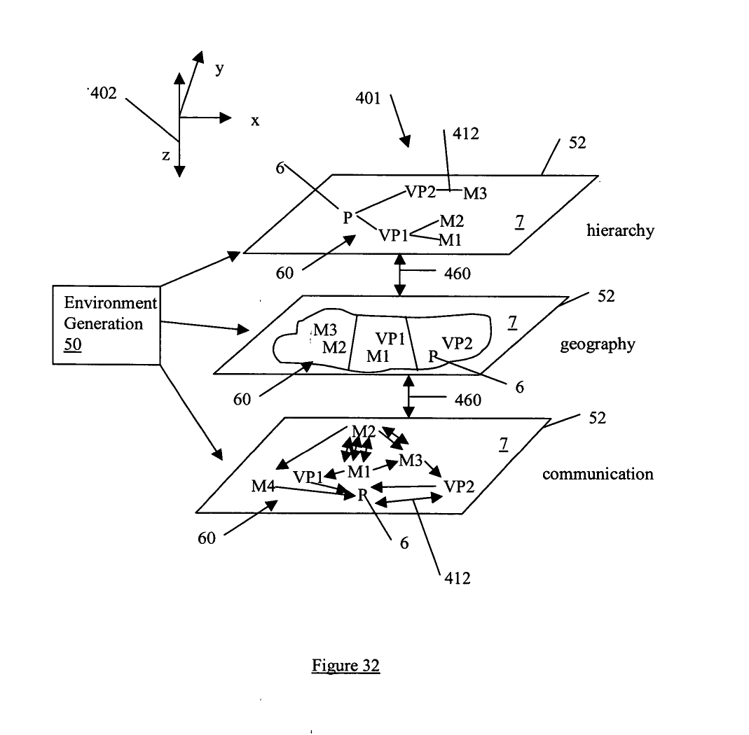

Accordingly, the visualization tool 12 is also configured to facilitate viewing of a problem data set from multiple diagrammatic or configurable context domains 401, through the defining of a set of customizable environments 52, see FIG. 32. Each environment 52 represents a different point of view of the problem using a different diagrammatic context space. The visualization tool 12 preferably provides the ability to switch between different environments 52 or combine two or more environments 52 into a single merged view portrayed by the visualization representation 18.

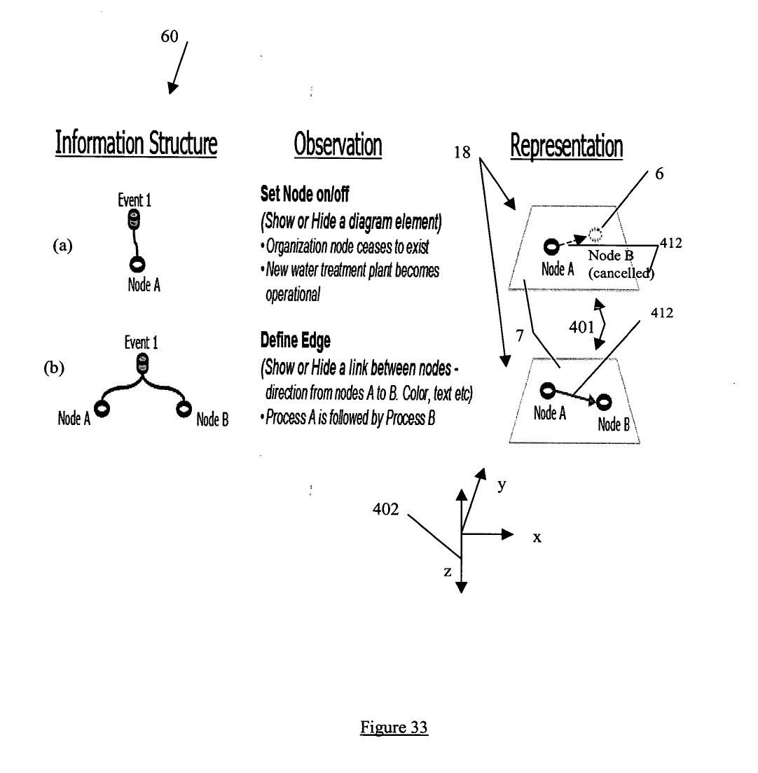

Referring to FIG. 32, the display of any diagram-based context over time is discussed below. Examples of diagram-based information structures 60, of the environments 52, include process views, organization charts, infrastructure diagrams, social network diagrams, etc, which are considered overlapping subsets of the diagrammatic context domain 401 for a particular data set. Diagrammatic nodes 6, which are dynamically positioned on a ground plane/surface 7, represent locations of interest in the diagrammatic context domain 401. The configuration of the links between the nodes 6 is done using a dynamically modified relationship event to represent edges (e.g. connection elements 412—see FIG. 33), which can be dependent upon changes to the configuration/status assigned to the associated nodes 6, as further described below.

This use of the visualization tool 12 for dynamic configuration of nodes 6 and connection elements 412 can support temporal analysis of diagrams in the diagrammatic context domain 401. The visualization tool 12 can display the diagrammatic context domain 401, using one or more defined environments 52, in the x-y plane and show temporal changes to events, communications, tracks and other evidence in the temporal domain 402 (e.g. via time tracks 422—see FIG. 9). To support effective analysis, information structures 60 can be event-driven, that is, their structure (e.g. nodes 6 and/or connection elements 412) change over time based on events, for example. It is recognized that the overall shape of the information structures 60 can be changed through spatial repositioning of the nodes 6; deletion of node(s) 6; insertion of new node(s) 6; modification of existing connection(s) 412 properties based on changes to associated node(s) 6; deletion of existing connection(s) 412; and insertion of new connection(s) 412. This dynamic reconfiguration potential of the node(s) 6 and/or connection elements 412 is one distinctive feature of the diagrammatic domain 401 over that of the geographic domain 400 (i.e. locations of interest in the geographic domain are statically assigned to actual physical locations 22 of the geography of the reference surface 404, see FIG. 8). Geographic locations in the geographic domain 400 cannot cease to exist, nor can the geographic locations be spatially repositioned on the reference surface 404 on the basis of events occurring with respect to the location of interest. This is in contrast to the diagrammatic domain 401, in which the elimination of a position in a company hierarchy could result in the deletion of the representative node 6 from a hierarchy information structure 60.

Referring to Table 1, shown are various types of environments 52 that could be used as a context to provide meaning to a data visualization problem. Each of these environments 52 is a visualization of a particular “operating” space. The geospatial context upon which visualization tool 12 was described previously, will be extended into a flexible visualization tool 12 for temporal analysis of events within diagrammatic context spaces/domains 401 that include dynamic configuration/reconfiguration of the nodes 6 including relative spatial positioning of the nodes 6 on the reference surface 7 and status of the nodes dependent upon temporal considerations.

TABLE 1

Geospatial
Infrastructure
Schematic
Process
Social and/or Behavioural Network
Organization (hierarchy)
Political
Economic
Motivation
Relationships, Aliases
Concept spaces
Toulmin Argumentation Diagrams
Hypotheses
Decision Trees
User-defined layouts
Predefined Layout from external data source
Algorithmic generated

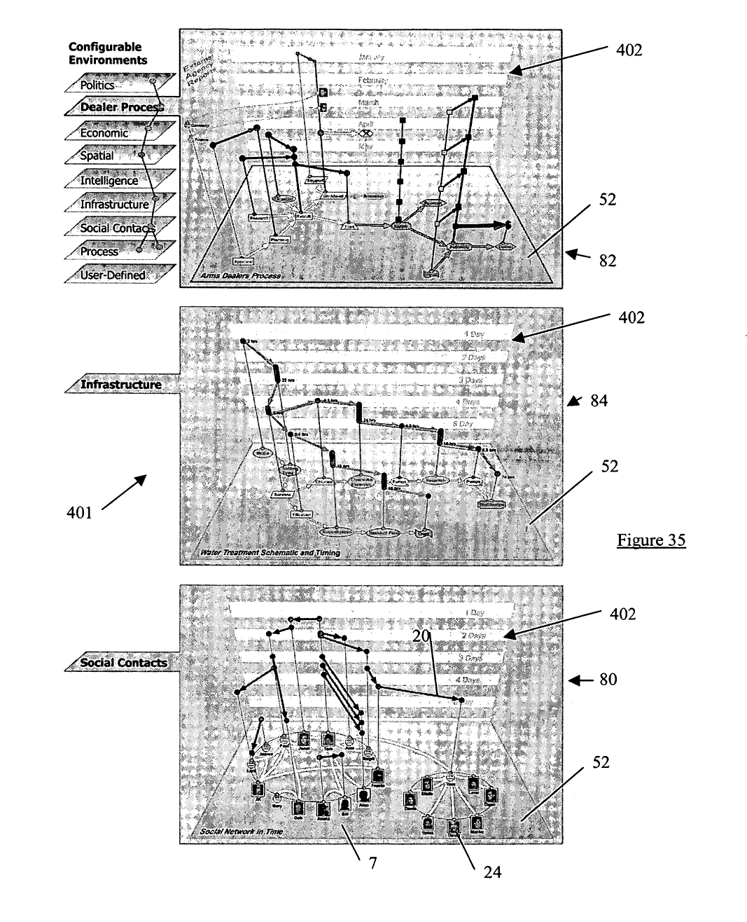

Referring to FIG. 35, shown are various example environments 52 of an overall diagrammatic domain 401.

The data model supporting dynamic information structures 60 is discussed, as well as methods for creating the information structures 60, and visualization methods for animating and representing diagrammatic change over time in the diagrammatic context domain 401. The information structures 60 are represented in the analytical environments 52, defined as a slice or subset of evidence that is best represented in a specific diagrammatic context. The environments 52 can be used to connect varying configurations of the data objects 14 to visualization, and to provide a context for layout logic 54 that controls layout and interaction with the data objects 14. Any number of environments 52 can be specified and layout can be set by the analyst, or driven by 3rd party algorithms and analytics, as further described below. It is recognized that configuration of the information structures 60 can be different in each of the environments 52, including dynamic changes to the relative spatial positioning of nodes 6 to account for different emphases on the data objects 14 as well as to facilitate orderly visualization of the data objects 14 (e.g. minimize visual clutter).

Referring to FIG. 32, shown is a plurality of different environments 52 that were generated by an environment generation module 50, using the data set contents of the memory 102 for selected data objects 14, associations 16 (see FIGS. 1 and 2) as well as any user input via user events 109, for example. Each of the environments 52 are considered a subset of the overall diagrammatic context domain 401 and associated temporal domain 402 for the overall data set of the objects 14 and associations 16 in the memory 102. It is recognized that the environments 52 can share data objects 14 and associations 16 (e.g. one data object 14 can be included with more that one environment 52), as given by example below.

For example, a hierarchy environment 52 of FIG. 32 shows a hierarchy information structure 60 of a Canadian company subsidiary using management data objects 14, namely the president P in charge of two vice presidents VP1 and VP2, who are in charge of managers M1 and M2 and Manager M3 respectively. The hierarchy information structure 60 shows the company hierarchy subset of the diagrammatic domain 401. In this case, the connection elements 410 represent the direct chain of command between the data objects 14. It is recognized that the objects P, VP1, VP2, M1, M2, M3 are positioned on the reference surface 7 as distinct nodes 6 of the hierarchy information structure 60, such that the relative spacing between adjacent nodes is configured so as to represent a traditional hierarchical tree structure (e.g. items of deemed greater importance are located at higher positions in the tree structure and are connected to deemed lower importance items through lines/branches to create a branched structure with an apex). It is also recognized that time tracks 422 (see FIG. 33) can be included with each node(s) 6 to facilitate representation of temporally dependent aspects of the individual nodes 6 and the information structures 60 as a whole, as desired.

Referring again to FIG. 32, a geographic environment 52 of the diagrammatic domain 401 is used to show a geographic distribution subset of the objects P, VP1, VP2, M1, M2, M3 using a geographic information structure 60, namely that P and VP2 are located in one province, M1 and VP1 are located in a second province, and M2 and M3 are located in a third province, for example. It is noted that the majority of the objects 14 are shared between geographic and hierarchy environments 52. It is also noted that the relative spacing between the nodes 6 has been configured (for the geographic environment 52) to represent the objects' 14 actual geographic location on the reference surface 7 (e.g. geographic regions of Canada) for a selected time interval of the temporal domain 402. In this case, no connection elements 410 are shown between the data objects 14.

Referring again to FIG. 32, a communication subset of the objects P, VP1, VP2, M1, M2, M3 is shown using a communication information structure 60. In this case, connection elements 410 represent individual communications between the data objects 14. It should be noted that the layout of the communication information structure 60 shows rearrangement (as compared to the other environments 52) of the relative spatial positioning of the nodes 6 on the reference surface 7, such that the visualization emphasis is on the majority of the communication connection elements 410 (e.g. positioned in the center of the communication information structure 60). Accordingly, configuration for the communication environment 52 may include the parameter that density of communications activity should be clustered in specific regions on the reference surface 7. Further, the connection elements 412 in the communications activity cluster (i.e. associated with M1, M2, M3) can be configured as visually distinguished (e.g. through colour, highlighting, line thickness/type, etc.) in the communication information structure 60, in order to draw the analyst's (e.g. tool 12 user) attention. It is noted that the majority of the objects 14 are shared between geographic and communication environments 52.

Upon review of the three different environments 52, a user of the tool 12 could note (see FIG. 1) in the communication environment 52 that although VP1 is responsible for both M1 and M2, only M1 communicates directly with VP1. Review of the geographic environment 52 shoes that VP1 and M1 live in the same province, which may account for the greater degree of direct communication between VP1 and M1 as compared to none between VP1 and M2. A further observation of the objects P, VP1, VP2, M1, M2, M3 (shown in the communication environment 52) is that M2 communicates with manager M4, who is not part of the hierarchy information structure 60, and that M4 communicates directly with the president P. This information may be of interest to VP1. Based on the initial analysis above, the analyst may choose to reconfigure the layout of the nodes 6 in any of the environments 52, chose to amend the properties of any of the nodes 6 and/or connections 412 (e.g. visual properties and information properties), and/or decide to merge one or more of the environments 52 with each other to create a composite environment 52 (e.g. communications connections 412 superimposed on the nodes of the geographic environment 52), as further described below. It should also be noted that the tool 12 to monitor connections between the environments 52, as further described below, uses commonality information 460.

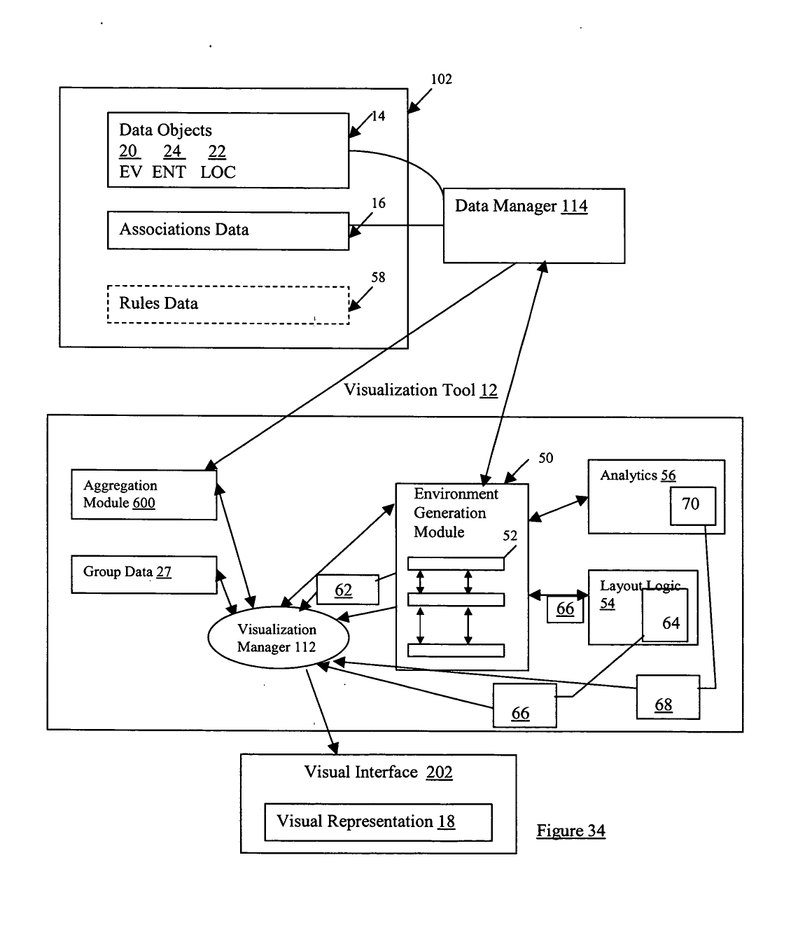

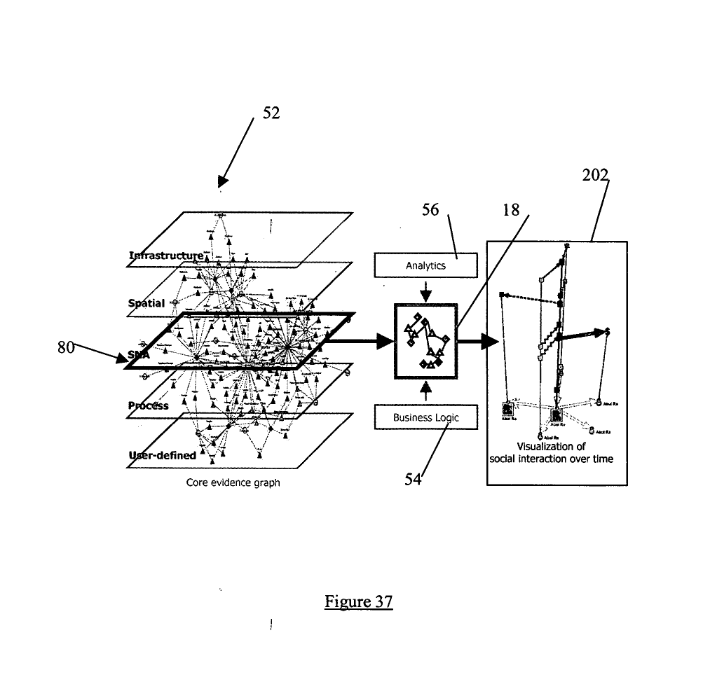

Referring to FIG. 37, shown is a series of generated environments 52 having limited or no temporal domain 402 aspects displayed (i.e. limited to none temporal information shown in the Z axis). One or more of these environments 52 could be generated initially according to respective layout patterns 64 (see FIG. 34) and then displayed on the user interface 202. The user could then decide which of the environments 52 (or composites of two or more environments 52) to investigate further (e.g. using the analytics module 56 and/or updates of the layout using the layout logic module 54) and then proceed to expand the selected environments 52 to include the detailed temporal dimension for all temporal aspects of the data objects 14 and associations 16 shown in the respective information structure(s) 60 on the user interface 202.

Referring again to FIGS. 5, 6 and 7, shown are example visual representations 18 of events over time and space in an x, y, t space, as produced by the visualization tool 12 for the data objects 14 and associations 16 in a temporal-spatial display to show interconnecting stream of events 20 as they change over the range of time associated with the spatial domain 400 and temporal domain 402. Now referring to FIG. 33, visualization representations 18 can also be provided in the diagrammatic domain 401. Diagrammatic domains 401 include contextual information about data objects 14 (e.g. events 20, entities 24, locations 22) that can be represented by diagrams showing informational relationships (e.g. connectivity elements 412) between diagram nodes 6 (e.g. Node A, Node B) in a visual manner. For example, process diagrams, flow charts, as well as customized diagrams (e.g. interrelationships of contact lists for multiple entities 24) are examples information structures 60 of the diagrammatic domain 401, in which the reference surface 7 does not preclude dynamic changes in the relative spatial layout of the nodes 6 in spaces other than geographical space (i.e. domain 400).

Tool 12 Configured for Diagrammatic Space 410 Representations

Accordingly, referring to FIGS. 32 and 34, the visualization tool 12 is used to construct, display, and interact with diagrams including the diagrammatic context domain 401 using basic nodes 6 and edge structures (e.g. connection elements 412), such that changes can occur to the nodes 6 and connections 412 including actions such as but not limited to: overall shape of the information structure 60 through spatial repositioning of the nodes 6; deletion of node(s) 6; insertion of new node(s) 6; amendment of properties of existing node 6 (e.g. size, shape); amendment of connection 412 properties based on changes to associated node(s) 6; deletion of existing connection(s) 412; and insertion of new connection(s) 412. It is recognized that changes to the nodes 6 and/or connections 412 should account for continuity of the information structure 60 in the temporal domain 402, due to the interconnectivity in space and time of the data objects 14 (e.g. removal of a selected node 6 may orphan the events 20 associated with that node 6).

Referring again to FIGS. 32 and 34, the visualization tool 12 has an environment generation module 50 for generating the environments 52 through rules data 58 to assist in the selection of data objects 14 and associations 16 to be included into the respective environment(s) 52, for subsequent display as the visualization representation 18. Layout of the information structures 60 within the environments 52 is facilitated through a layout module 66 using layout patterns 64 to provide the layout of the nodes 6 and connection elements 412 on the ground surface 7 of the respective environments 52. The predefined layout patterns 64 can be part of layout logic 54, which is for use in the generation of the environments 52 and linking of the data objects 14 therein (i.e. to layout the information structures 60). The tool 12 can also include an analytics module 56 that is in communication with the environment generation module 50, and is used to define template environments 70 in which process model templates are defined. A template module 68 facilitates the use of template environments 70 to assist in analysis of the generated environments 52 according to the rules 58 and the layout patters 64. The tool 12 also has a reconfiguration module 62 for tracking/monitoring the status changes of nodes 6 and/or connection elements 412 in the various information structures 60, due to temporal considerations and/or modifications to the data object 14 via user events 109. The reconfiguration module is used to facilitate the updating of the information structure(s) 60 once displayed on the visual interface 202.

Generation Module 50

Referring again to FIG. 34, the environment generation module 50 is configured coordinate the generation of one or more of the environments 52 and for overlaying multiple environments 52 into a single view. The environment generation module 50 can create several environments 52 according to rules data 58 either obtained from the user (or predefined) and also obtains customization and layout parameters 64 from the layout logic module 54. Depending on the context, it may be effective to connect some context data within one environment 52 to another view within another environment 52 (e.g. through commonality information 460). For example, political events associated with an entity 24 could be superimposed on a geospatial view of its movements, hence connecting the geographic information structure 60 with the political information structure 60, with subsequent display of the integrated structures 60 (or a different combined conceptualized view) as one or many visual representations 18. The ability to maintain separate views as environments 52 and then combine them using the layout module 66 raises some potentially interesting collaborative possibilities. For example, analysts with expertise in different areas may be able to work within their specific environments 52 and at any point merge relevant data from another environment 52 into their own to see its impact on the representation 18.

The generation module 52 can be considered a workflow engine for facilitating the generation of the environments 52. The generation module 52 communicates with the data manager 114 to obtain data objects 14 and associations 16 associated with the requested environment(s) 52 (e.g. via user events 109 with the tool 12), coordinates operation of the layout logic module 54 and associated layout module 66 to generate the respective information structures 60 of the environments 52 (using the predefined layout patterns 64), interacts with the reconfiguration module 62 to account for any reconfiguration of the information structures 60 due to user events 109 and/or temporal considerations (e.g. changes in information structure 60 due to change in the instant of focus 900—see FIG. 9), and communicates with the visualization manager 112 to effect presentation of the environment(s) on the user interface 202.

The environments 52 comprise a subset of the full data objects 14 and a diagrammatic layout configuration of the domain 401. The data slice (e.g. subset of the full data objects 14) shown as the visual representation 18 may share data with other environments 52 and may contain data that is exclusive to it. The environment 52 may also specify external functions or algorithms as part of the layout logic module 54 that processes the data with temporal basis considerations.

Accordingly, the environment generation module 50 provides one or more environments 52 according to the data objects 14 and the associations data 16 obtained as either user input 109 or from storage in the memory 102. The associations data 16 defines the link between each of the data objects 14 (thus linking each event 20 to entities 24 to locations). Using the data objects 14, association data 16 and the rules data 58 appropriate to a respective environment 52, the environment generation module 50 can create one or more environments 52 to be displayed as the visual representation 18, where each environment 52 is a representation of a subset of the data objects 14 and their connections 412.

Rules Data 58

The rules data 58 defines the association between each of the data objects 14 and one or more environments 52. The rules data 58 can either be user defined or predetermined (e.g. set up by an administrator). In one embodiment, the rules data 58 can be implicitly included in the definition of the data objects 14 and/or associations 16 though the attributes thereof. One example of this is each data object 14 would have defined attributes specifically assigning the data object 14 to one or more of the environments 52. Accordingly, a request by the generation module 50 to the data manager 114 would specify all data objects 14 including the attribute of a selected environment name, e.g. “communications environment”. In another embodiment, the rules data 58 could be external/explicit to the definitions of the data objects 14 and/or associations 16. For example, each of the environments 52 could have a list of data object 14 and/or association 16 types for inclusion in the environment 52. Another option is for the rules data 58 to specify certain attribute(s) that can be shared by one or more data objects 14 and/or associations 16 (e.g. having a specified time instance in the temporal domain 402). The rules data 58 could also include conditional logic for association of specific data objects 14 and/or associations 16 (or types thereof) to the environment(s) 52. For example, the conditional logic could be: if data objects 14 of type A are selected, then also include associations of type B. Further, it is recognized that the rules data 58 can be a combination of any one or more of implicit, explicit, conditional, or others as desired. The rules can be stored in the memory 102, provided by user events 109, and can be provided to the data manager 114 either from the memory 102, user events 109 and/or the generation module 50, as desired. The rules data 58 may be defined by a user and could be loaded into the memory 102 via the computer readable medium 46 (FIG. 2). In any event, the data manager 114 uses the rules data 58 to select specific data objects 14 and/or associations 16 appropriate for the environment(s) 52 to be generated.

In one example, it may be defined within the rules data 58 that one or more entity objects 24 belong to various environments 52. For example, referring to FIG. 35, the environment shown as “social network” 80 represents the social connection between different people 24 and the events 20 that may connect them, while the “process” environment 82 shows the process objects 14 for arms dealing from approval to delivery of arms over a specified time range of the domain 402, including the people 24. In this case, the rules data 58 specifies events 20 and people 24 as part of the social network 80, while the rules data specifies process objects 14 and the people 24 as part of the process environment 82. Although the two environments 80, 82 show completely different perspectives of a problem, they can share the common people 24. For example, the commonality information 460 would indicate that the people 24 were common between the two environments 80,82. Thus, by viewing the social network 80 of those people 24 within one environment 80 and their role in the arms dealing process 82 within another environment, a more complete visualization of a problem may be obtained.

Alternatively, the environment 84 representing infrastructure process would be specified by the rues data 58 to contain different places and events (as represented by event objects 20, location objects 22 and entity objects 24), rather than the geospatial view of actual water treatment facilities. Thus, events 20 that are being analyzed could be contained and displayed in either one or both environments. Note that the environment generation module 50 may also accept the data objects 14 and the associations data 16 directly without the group data information 27. Referring again to FIG. 35, in either case, the rules data 58 can predefine which data objects 14 are associated with which environments 52. Typically each type of supported environment 52 might require different logic. In this case, the data objects 14 and/or associations 16 for the environment 52 are extracted dynamically from the full data set using the rules data 58.

Layout Logic Module 54

The layout logic module 54 includes predefined layout patterns 64 and the layout module 66 used to generate the information structure 60 of the selected environment(s). Referring again to FIG. 34, the business logic module 54 includes the set of predefined layout patterns 64 (e.g. rules/algorithm) and facilitates integrating new rules and algorithms to control the layout of the selected environment 52. It is recognized that the layout patterns 64 can be used to facilitate the layout of the information structure 60 in an automated, semi-automated, and/or manual manner. For example, the layout patterns 64 could be embodied as a layout wizard for providing instructions and/or example operations to interactively guide a user (e.g. through suggestions and/or selectable layout options) in generating the environment 52, further described below with respect to user generated environment examples. The predefined layout patterns 64 can also be used to provide an initial layout pattern (e.g. template) of the included data objects 14 and associations 16, with selectable options for modifying the initial layout by the user of the tool 12. These modifications can be performed on an object-by-object basis or can include more automated changes to a grouping of objects 14 and/or associations 16.

Specifically, the layout patterns 64 provide formats of the data objects 14 and corresponding visual elements 410 (see FIG. 6), such as nodes 6 and connections 412, that facilitate the adaptation of the visual layout of the information structure 60 to match predefined characteristics of the environment 52, which is subsequently displayed on the visual interface 202. These characteristics can include defined parameters for formatting of the environment 52 such as but not limited to: relative spatial positioning between adjacent nodes 6 (e.g. distance and or angular relationships); node 6 visual characteristics (e.g. size, colour, icon, etc.); information associated with node 6 (actively or passively displayed) such as name, and other node 6 details; connection element 412 visual characteristics (e.g. size, colour, line type/thickness, visibility, etc.); information associated with the connection element 412 (actively or passively displayed) such as name, and other details (see FIGS. 6 and 7 for examples); clutter reduction parameters (e.g. node 6 sizing based on proximity, aggregation operations); definition for use of time tracks 422 and their configuration (e.g. instant of focus 900 and time ranges 914,916—see FIG. 13); conflict resolution when two or more data objects 14 and/or associations 16 occupy/overlap substantially the same location in the information structure 60 (e.g. changes to side by side placement, size differences, transparency differences, colour differences, aggregation possibilities, etc.); format preferences of the above when two or more environments 52 are combined; and optionally scripted/programmed operation to effect the combination of the data objects 14 and/or associations 16 with the predefined parameters. In any event, the defined parameters (or options to provide a definition for the parameter by the user) are used to provide the definition for the layout patterns 64 used to assemble the environment 52, including incorporating selected data objects 14 and/or associations 16 into the respective information structure 60.

The layout logic module 54 also facilitates the user to retrieve specific data objects 14 and facilitate the creation of environments 52 for the retrieved data objects 14 in conjunction with the environment generation module 50. Alternatively, the business logic module 54 may be used to search the data objects 14 for specific entities 24 (or other selected data objects 14). Referring to FIG. 35, in one example, the social network environment 80 is retrieved by the generation module 50 using the layout logic module 54 to facilitate a search of the data objects 14 set for all people within the entities 24, and then construct the social network 80 view as the representation 18 using events 20 between them. As well, the layout logic module 54 is configured to be able to plug-in external functions (e.g. layout modules 66) to layout the diagrams of the environments 52, as desired.

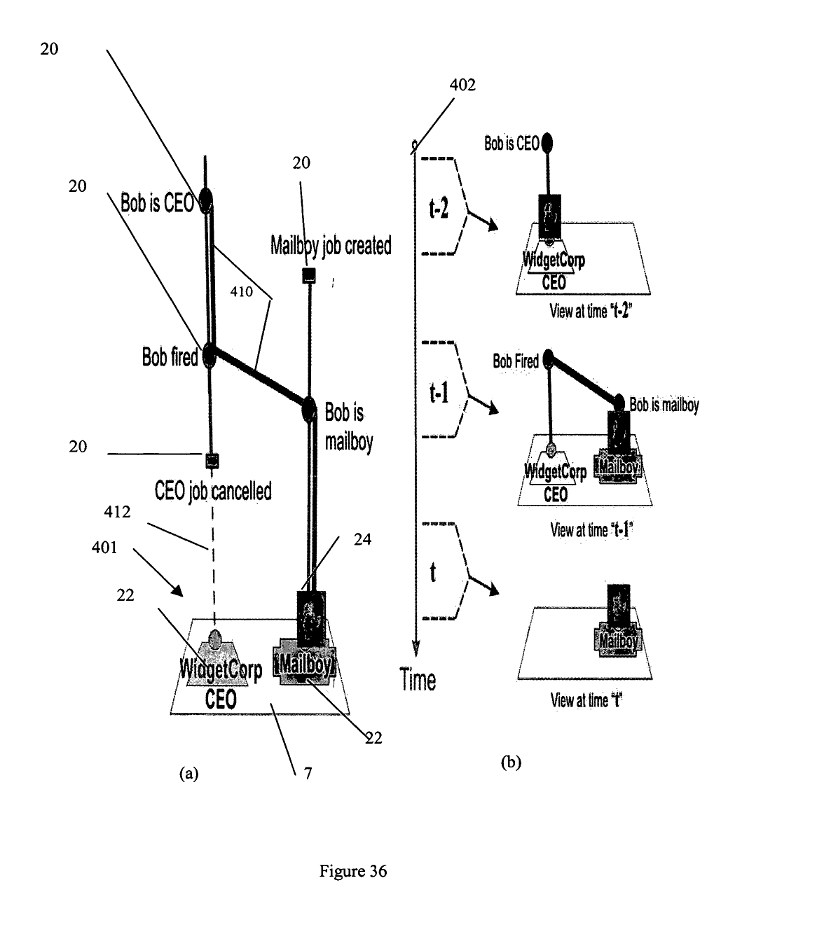

Further, diagrammatic layout patterns 64 can be used by the layout module 66 to enhance the interpretation of the visual representations 18. Some design exercises involving social network interactions show that an effective layout pattern 64 can significantly improve the readability of SNA (social network analysis) information. For this purpose, a third party graphing library plug-in, such as yWorks™, can be integrated into the layout logic module 54 to support smart layout of visual representations 18, such as social networks, processes, hierarchies, etc. For example, the layout module 66 accepts sets of nodes 6 and connection elements 412 and performs the layout for the visualization representation 18, including any reconfiguration data supplied by the reconfiguration module 62 (e.g. line properties), further described below. Given that the configuration of the information structure 60 can change over time, a feedback loop can be possible so that the layout pattern 64 will be applied to subsets of the data scope. For example, a social network environment 52 of the domain 401 is based on interactions between entities 24 over a certain period of time. As we scroll through time we can constrain the set of interactions used to drive the layout of the environment 52 and then recalculate the layout at each time increment (see FIG. 36b), further described below. This can result in optimized layouts for any desired time range of the domain 402, which could be implemented with potential comprehension expenses of causing changes to the layout. It is recognized that the layout module 66 can decide when dynamic layouts are preferable or if a static layout can be achieved that supports dynamic data, as defined by layout logic 54 module (see FIG. 34).

Further, it is recognized that the user of the tool 12 is able to create entirely custom layouts of a problem within a desired diagrammatic space 401. Referring to FIG. 35, the set of layout patterns 64 can integrate new/amended rules and algorithms to create a desired visual analysis environment 52, as customized by the user. Thus, the user can create new nodes 6 or reorganize existing ones to generate novel views of the problem space to emphasize a certain selected aspect of the environment 52. The user may also specify rules/elements/parameters of the layout pattern 64 from a list of preset options or create new custom rules/elements/parameters. For example, the user can interact with the interface 202 to create new environments 52 simply by dragging objects 14 into buckets corresponding to nodes 6, connection 412 and events 20, thus assigning certain objects 14 and or associations 16 (or types thereof), as well as their implicit format to the selected environment 52.

Reconfiguration Module 62

The reconfiguration module 62 monitors the location status change of various nodes 6 in the domain 401 and facilitates interaction with those reconfigured nodes 6 based on their current status. For example, to support visual analysis of an organization over time, the reconfiguration module 62 monitors the organizational hierarchy at any point in time, such that organizational nodes 6 may be added, removed or reassigned to a new location in the ground surface 7 over time. In the case where existence status of one of the nodes 6 has been deemed cancelled, the reconfiguration module 62 could maintain the previously defined connectivity relationships 412 between the cancelled node 6 and adjacent nodes 6, however could also inhibit the assignment of new connectivity relationships 412 to the canceled node 6. It is recognized that various visual properties could be used to portray the connectivity relationships 412 associated with the canceled node 6 in the visual representation 18, including properties such as but not limited to hidden, line type, line thickness, colour, texture, shading, and labels, as desired.

Within the temporal framework of the visualization tool 12, the visual representation 18 that represents the reference surface 7 will be the state of the diagram at the browse time (e.g. at a selected time in the temporal domain 402). Since the visualization tool 12 supports animation, the information structure 60 could hypothetically redraw itself, via the efforts of the reconfiguration module 62, as time is browsed (hence showing the various changes in status over time of the nodes 6 and/or associated connection elements 412). Diagrammatic changes in status over time include, such as but not limited to: adding a node, removing a node, showing connection elements 412 between nodes 6 for a time duration x and setting connection element 412 value(s).

Referring again to FIG. 34, the reconfiguration module 62 monitors updates to the content of the information structures 60 in the event of changes to the nodes 6 and/or connection elements 412. Changes can occur to the nodes 6 and connections 412 including actions such as but not limited to: overall shape of the information structure 60 through spatial repositioning of the nodes 6 (e.g. due to modifications to the amount of information displayed in the visualization representation 18, insertions/deletion of nodes 6 and/or connection elements 412); deletion of node(s) 6; insertion of new node(s) 6; amendment of properties of existing node 6 (e.g. size, shape); amendment of connection 412 properties based on changes to associated node(s) 6; deletion of existing connection(s) 412; and insertion of new connection(s) 412. It is recognized that these changes can be a result of: changes in desired visual characteristics of the nodes 6 (e.g. change in size for selected nodes 6); increased amount of information displayed in conjunction with the nodes 6 and/or connections 412 (e.g. name label of node 6 replaced with name and function label); and changes in density of nodes 6 and/or connections 412 due to changes in instant of focus 900 and time ranges 914,916 displayed (see FIG. 13).

In one embodiment, a selected node 6 could be inserted/deleted from the information structure (see FIG. 36) due to changes in the temporal features of the temporal domain 402, and/or through user initiated changes to the selected node 6 for a particular temporal instance/range of the temporal domain 402. Accordingly, the reconfiguration module 62 could be used to update the displayed information structure 60 to reflect status changes to the nodes 6 as well as to the connections 412 associated with the changes nodes 6. For example, if a position in a company hierarchy were eliminated (either permanently or for the displayed time period), the reconfiguration module 62 would update the visual properties of the respective node 6 to reflect this change (e.g. removal of the position node 6 from the visual representation 18, changing the display of the position node 6 to remain on the visual representation but to be distinct from the other remaining nodes 6—such as highlighted or otherwise in ghosted/semi-transparent view, etc.). Further, any past connection elements 412 associated with this position node 6 (as well as any other interconnected nodes 6) would also have their visual properties updated to reflect this change. Further, the reconfiguration module 62 could also restrict future association of new nodes 6 and or connection elements 412 to the eliminated position node 6, as desired.

Additional functions via the reconfiguration module 62 should be supported to drive temporal analysis of representations 18 of the diagrammatic context domain 401, for example connection element 412 aggregation based on cumulative event activity during:

All time;

Current time range; or

All past time,

for representing events and tracks (e.g. connectivity elements 412) attached to diagram nodes 6 as the nodes 6 move and change over time. It is recognized that the connectivity elements 412 can be attached to one node 6 (e.g. representing a standalone event 20 for that single node 6) or a plurality of nodes (e.g. representing an event 20 that affects/involves multiple nodes 6). In either case, updating of the node 6 could necessitate updating of all the connection elements 412 associated with the updated node 6 or series of nodes 6. Further, it is recognized that updates to two outside nodes 6 on either side of an interposed node 6 (connected to the outside nodes via connection elements 412) may necessitate the updating of the interposed node 6 as well. For example, elimination of a vice president and some of the employees under the vice president may necessitate the elimination or otherwise repositioning of an interposed manager node (having the eliminated role of reporting to the old vice president and overseeing of the old employees) with respect to a company hierarchy information structure 60 and in other information structures 60 of related environments 52.

It is recognized that the reconfiguration module can operate in conjunction with the layout module 66 (e.g. act as a filter for generation of the content of the information structure 60), can be used to update the rules data 58 and/or attributes of the associated with the affected data objects 14 associated with the updated node 6 (e.g. eliminated position node 6), or a combination thereof. For example, the reconfiguration module 62 could always involve the interaction of the layout module 66 for updates to the data objects 14 or can involve the layout module 66 in the event that the updates surpass a change threshold, which would be indicative of a needed revision of the information structure 60. It is recognized that the functionality of the reconfiguration module 62 could be used to update information structures 60 already generated through the generation module 50 and displayed on the user interface 202, could be used as a filter mechanism to update generated information structures prior to their display on the user interface 202, could be incorporated into the generation module 50 as factors to consider during generation of information structures, or a combination thereof.

Analytics Module 56

The analytics module 56 provides template environments 70 depicting different predefined combinations of the data objects 14 within the template environments 70. As will be discussed, the template module 68 can then correlate between the template environment 70 and the generated environments 52 provided by the environment generation module 50, thereby finding a matching environment 52 according to the characteristics of the template environment 70 (e.g. specific data objects 14, associations 16 and connection elements 410 common between the template environment 70 and the selected environment(s) 52). An example of this matching can be where the template environment 70 includes a combination of activities events 20 and specific entity 24 types that are typical of spy actions, i.e. a spy template 70. This spy template 70 could be applied to the generated environment 52 to help identify combinations of the data objects 14 and/or associations 16 therein that match the spy profile provided by the spy template 70.

The template environment 70 can be a portion of an environment 52 or a whole environment depending upon the inherent complexities of the modeling. The template environment 70 can be used to help analyse the environment 52 to review what is happening, why is it happening, and what can be done about it. The template environment 70 can also help describe a pattern against which to compare actual behavior, or act as a template for searches. Referring to FIG. 34, the analytics module 56 that is in communication with the environment generation module 50 could be used to define the template environments 70 in which process model templates are defined. In one example, the template environment 70 within the analytics module 56 could be used by the layout logic module 54 to perform and retrieve specific environments 52, as per operation of the template module 68. The associated layout logic could also then be used to initiate searches to find patterns in the actual evidence provided by the data objects 14 that match the template of the template environment 70. The results would then be shown in the visual representation 18 as passed by the template module 68 to the VI manager 112.

Other Components

Referring again to FIG. 34 for the tool 12, a visualization manager 112 interacts with the provided generated environments 52 for presentation to the visual interface 202 (e.g. rendering). The data manager 114 can receive requests from the generation module 50 for storing, retrieving, amending or creating the data objects 14, the associations data 16, via the rules data 58 in association with the generation of the environments 52 through the generation module 50. Accordingly, the generation module 50 and managers 112, 114 coordinate the processing of data objects 14, association set 16, user events 109 with respect to the content (i.e. environments 52 and associated information structure(s) 60) of the visual representation 18 displayed in the visual interface 202. The visualization manager 112 processes the translation from raw data objects 14 and facilitates generation of the visual representation 18 according to the environments 52 provided by the environment generation module 50.

It should be noted that the aggregation module 600 can further facilitate the retrieval of certain data objects 14 to be used by the visualization manager 112 and the environment generation module 50. As described earlier, the filters 602 (see FIG. 22) within the aggregation module 600 could be used to retrieve selected data objects 14. For example, the user and/or generation module 50 may select to see an aggregate of data objects 14 having a certain physical characteristics and only the selected data objects 14 would then we used by the environment generation module 50 to create the desired environments 52. In turn, this could reduce the computational complexity used by the environment generation module 50 and/or the visual complexity of the generated information structures 60. It is recognized that the aggregation parameters used by the aggregation module may also be included in the rules data 58 and/or in the layout parameters of the layout patterns 64, as desired.

Example Operation of Reconfiguration Module 62

Referring to FIG. 36, an example of such operation showing diagram events mixed with evidence is illustrated. For example, shown is an entity object 24 (Bob) as the CEO of a corporation, WidgetCorp. Note, the XY plane represents the positions within the organization environment 52 (such as CEO and mail boy within WidgetCorp) and the Z plane is the time domain 402. In one embodiment, the most flexible representation for temporal analysis would be the following:
1. “CEO of WidgetCorp” is a “title” represented as a node 6 location in the visualization representation 18; and
2. Bob is an entity that occupies that title for a period of time.
   In the current context, events 20 can exist as follows:
1. Events 20 involving the CEO title/location;
2. Events 20 involving Bob the entity; and
3. Events 20 involving both the CEO and Bob.

For example, consider the following sequence of events regarding Bob (entity data object 24), and the job title (shown as a location data object 22—e.g. an embodiment of node 6 on the ground surface 7, see FIG. 33). The connection visual elements 412 are shown as solid or dotted lines between two events and facilitate the interpretation of the concurrent display of events in the time domain 402 and diagrammatic contextual space 401. First, Bob switches jobs to become the mail-boy as shown by the visual element 412. This event is followed by Bob moving to the mail-boy title (location 22) and a trail shown by a solid edge 412, connects him to his previous job.

Now suppose that WidgetCorp is acquired and the CEO job no longer exists. Removing that node 6 (CEO location object 22) by the reconfiguration module 62 from the diagram would “orphan” the events 20 that occurred in the current view, since the CEO location object 22 no longer exists at the browse time. One example way to deal with this situation is to mark (e.g. update status) the CEO location object 22 as removed instead of actually removing it (e.g. using a label). This solution supports a status/state change of diagrammatic domain 401 within a time range that encompasses more than one state. Thus the visual element 410 is marked as the “CEO job cancelled”. Typically, once the references to a location are out of scope in the time domain 402, the references (e.g. associated location 22, entity 24, event 20 and connection elements 412) could also be temporarily hidden (or otherwise visually differentiated). Further, it is recognized that animation of the updated location object 22 could be done to indicate the updated status, as desired.

It is anticipated that trying to represent a dynamic context while showing events in time within that context will be a challenge in some environments 52, however, the reconfiguration module 62 facilitates the depiction of changes in the visual representation 18 that are balanced with the constraint for a stable context in which to perceive events 20 associated with the domain 401.

Embodiments of the Diagrammatic Domain 401

The following are further examples of application and operation of the tool 12 to produce desired visualization representations 18 involving the diagrammatic domain 401. The user can create the various environments 52 of the diagrammatic domain 401 through the use of selectable (by user and/or toll 12 configuration) diagram generation methodologies described above. It is recognized that further examples of application and operation of the tool 12 employ appropriate respective modules and GUI features commensurate with the above described content and operation of the tool 12.

We introduce event-driven diagrams, or diagrams whose structure and representation may change over time based on events 20. Visualization methods for animating and representing diagrammatic changes over time are also discussed. Generation of diagrams can be user-driven, data-driven, or knowledge-driven using layout patterns 64 logic from a 3^{rd} party application (e.g. layout module 66), which may extract and emphasize properties of a given data set to generate a new perspective (e.g. environments 52). Multiple perspectives (e.g. environments 52) of a scenario (e.g. diagrammatic domain 401) can be generated; methods for organizing these perspectives as part of an analytical workflow are discussed. Examples of user-driven, data-driven, and knowledge-driven diagrammatic perspectives are presented, and lessons learned from these studies are described.

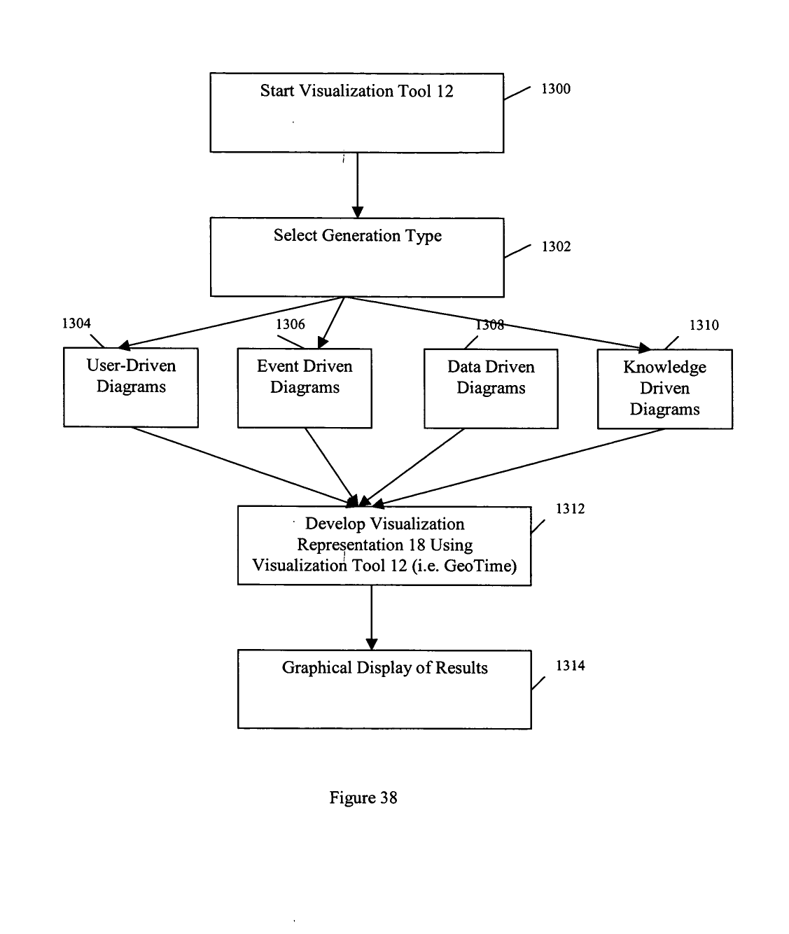

Referring to FIG. 38, shown is an overview of tool 12 operation for the generation and visualization of information for the different environment generation modalities (over time for diagrammatic domains 401), namely user, data, event, and knowledge driven diagrams. At step 1300, the visualization tool 12 is started. The generation module 50 allows a user to generate a diagrammatic perspective from any data set from memory 102. At step 1302, the method used to generate the visualization representation 18 of a sequence of events (event objects 20), entities (entity objects 24) and locations (location objects 26) from raw data objects 14 is selected, for example. The selection of the needed data objects 14 and associations 16 is done at steps 1304, 1306, 1308, 1310 using the rules data 58, as described above by example.

As discussed earlier, the following types of environments 52 can be generated: user-driven diagrams, event-driven diagrams, knowledge driven diagrams, data driven diagrams. At step 1312, the selected diagram type is developed using the visualization tool 12 and the graphical results displayed at step 1314. It is recognized that the generation methodology performed at step 1312 is facilitated through the operation of the generation module 50 and other associated modules (e.g. 54,62,66) via automated or semi-automated processes with varying degrees of active involvement with the user (via appropriate user events 109).

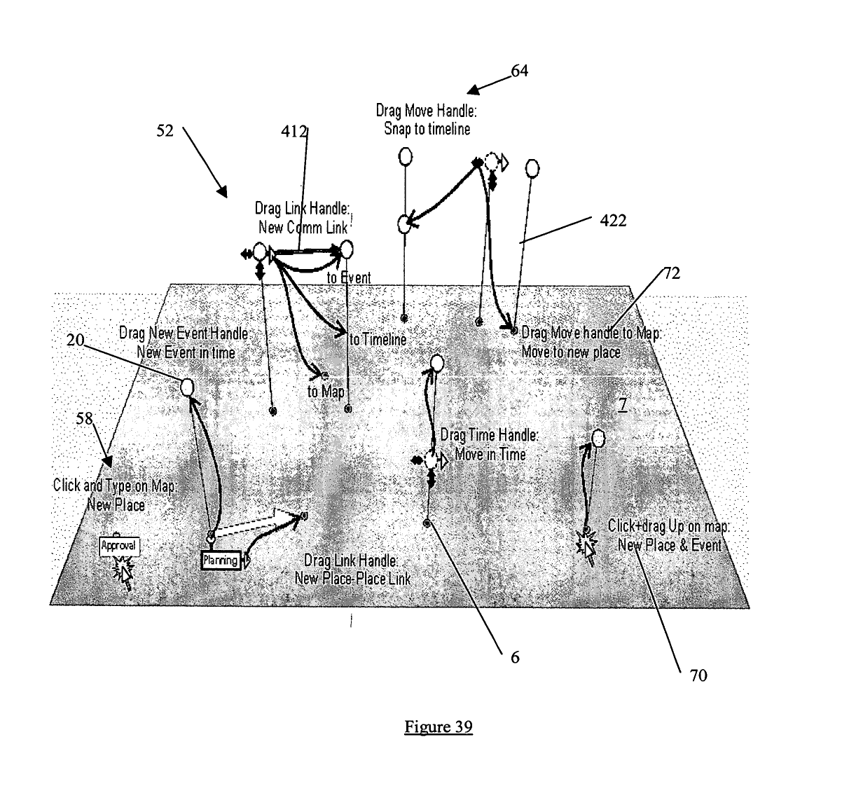

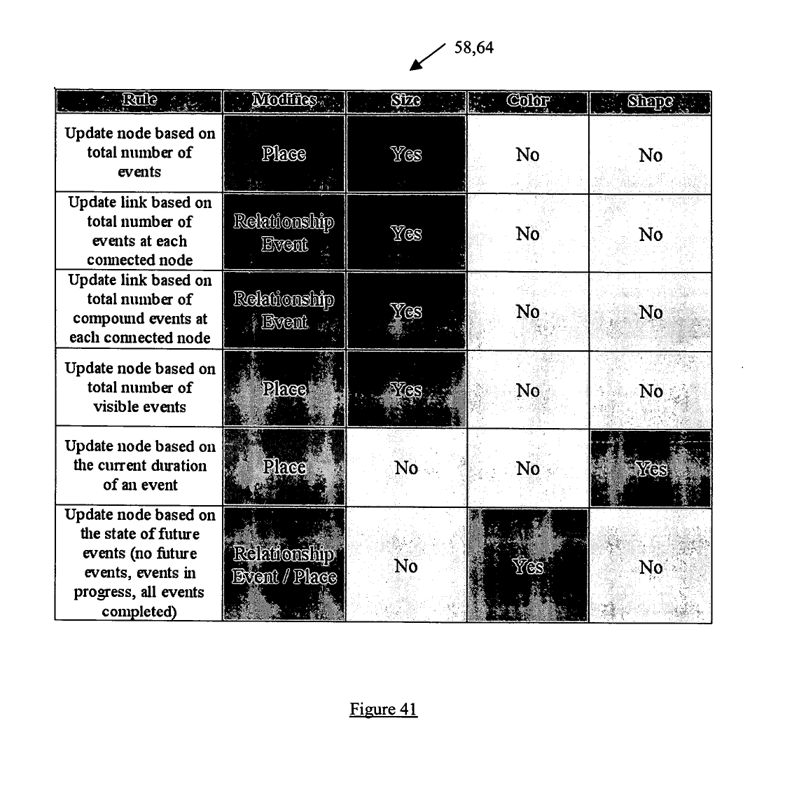

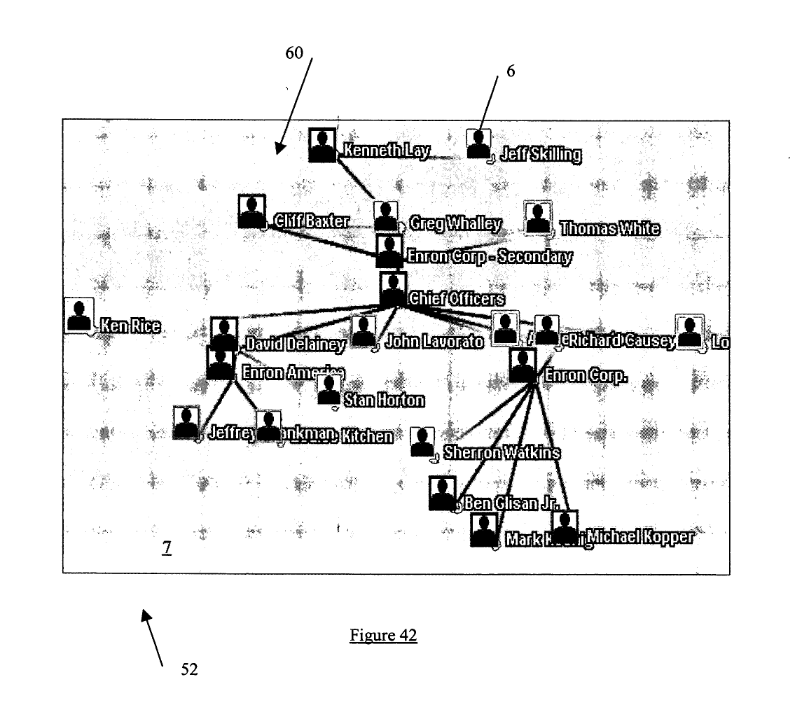

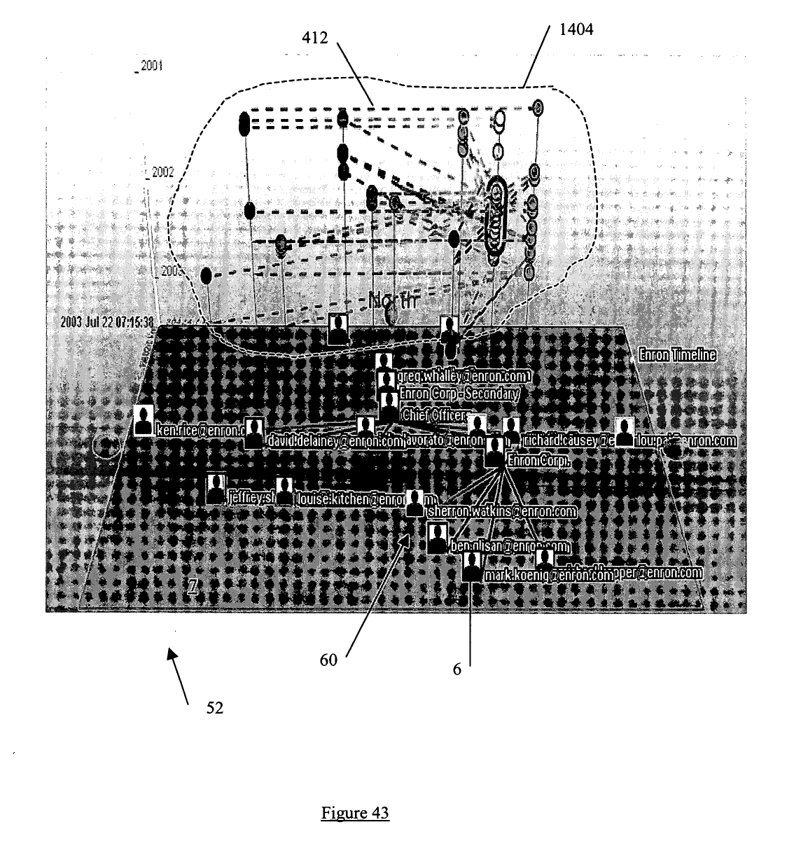

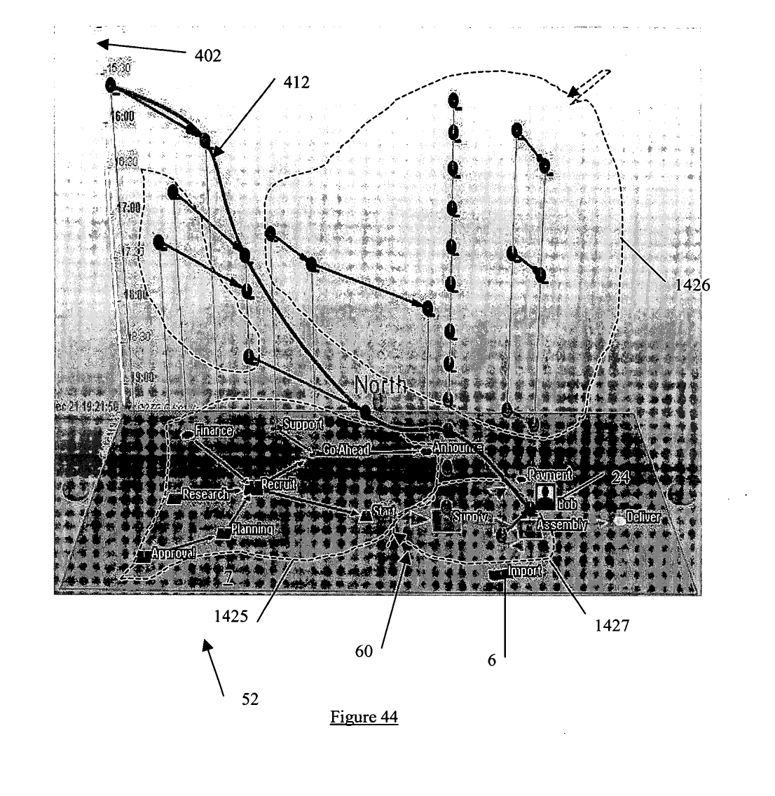

For example, user driven environments 52 generation methodology allows the user to create and edit multidimensional environments 52 depicting a sequence of events over time and the entities they relate to. For example, as shown in FIGS. 39 & 40, a number of characters are connected by the user to show their relationships and interactions (e.g. connection elements 412 as well as the events 20 that that they participate in. The user is further able to create temporal bookmarks that allow browsing over a certain timeframe. The selection of colour or other known graphical characteristics may be varied to distinguish certain aspects of the event 20 or entity 24, for example. At step 1306, event-driven environment 52 generation methodology can be selected. These environments 52 may update themselves through the reconfiguration module 62 according to the events 20 that occur over time or according to certain predefined rules 58 (and layout patterns 64) governing these events 20. An exemplary list of rules 59 that could be used to update the visual representation 18 is shown in FIG. 41. Alternatively, as shown at step 1308, a data-driven environment 52 may be generated. An example of this type of visualization representation is shown in FIG. 42 where a large amount of raw data relating to an organization, their interactions and communications over time was input into the visualization tool 12 to generate the complete scenario. In addition, as shown at step 1310, knowledge-driven environments 52 may be generated. As discussed, they may provide a visualization representation 18 of a behaviour networks, organizations and hierarchies. As shown in FIG. 43, they further allow generation of a summarized 2D graph from a 3D model. The two graphs are linked for subsequent temporal navigation and analysis within each graph. As discussed, a transformation can further be applied to a generated visualization representation 18 to generate another perspective. For example, a filter or rule may be used to generate a network view of a graph as seen in FIG. 44.

User Driven Temporal Diagrams

An important use case that is supported by the tool 12 is that of an analyst building a temporally-expressive picture of a problem from scratch. This means that the content, and layout of the environment 52 and the associations 16 and objects 14 attached to the corresponding information structure 60 are entered interactively directly in concert with the generation module 50. This interactive process through the user interface 202 via user events 109 supports the creation of diagrammatic explanations in time and space. Visual interaction techniques ranging from traditional drag and drop, to hotspot modes with drag actions for nodes and edges were used, as an example of the rules 58 and the layout patterns 64, to enable interactive environment 52 and event 20 manipulation within a 3D spatio-temporal view, as illustrated in FIG. 39. In particular, it should be noted that the generation rules 70,72 relate to the creation of new nodes 6 and the movement of nodes 6 from one location to the next in the reference surface 7, thus providing for dynamic configuration of the nodes 6 and associated connection elements 412 of the environment 52.

Using the user driven environments 52 generation methodology, the user is able to create and edit a complete picture of a sequence of events in time from scratch, including the diagrammatic elements, to generate the desired content and format of the selected environment(s) 52. This capability of user driven environment 52 generation methodology has many important, including support of annotation in time and space, hypothesis creation, collaboration, and advanced navigation techniques. The user driven environment 52 generation methodology also provides the ability to the user to make fine adjustments in high-dimensional displays. Further, visual anchors for locking elements to prevent inadvertently adjustment of important properties of the environment 52 and use of automatic filtering and slicing to de-clutter the display during edits can be implemented as part of the layout patterns 64, as desired.

Test Case 1: Representing the Story of Romeo and Juliet

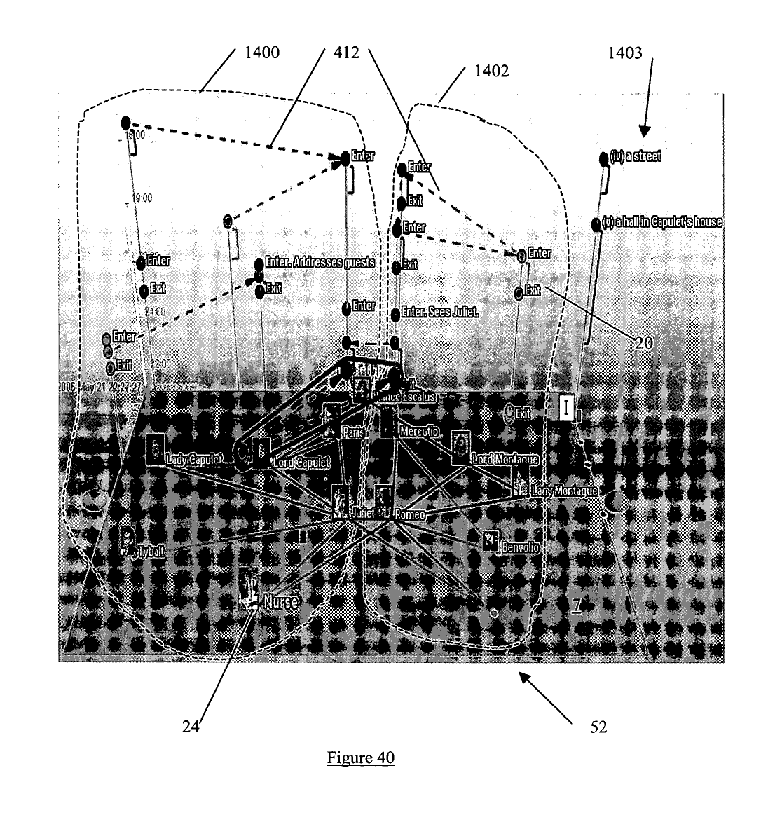

Referring to FIG. 40, the tool 12 for generation of environments 52 for diagrammatic explanations in time and space was tested by creating a representation of a known story, Shakespeare's Romeo and Juliet. This task was given to a test user, who then decided to focus on laying out interactions 412 between characters 24 (e.g. nodes 6) over time, using the user driven environments 52 generation methodology (see examples in FIG. 39). From the diagrammatic perspective, primary characters 24 are arranged based on family relationships and status within each family. Color or other visual distinguishing feature) is used to differentiate members of opposing families, e.g. family 1400 and family 1402. Additionally, temporal bookmarks 1403 can be used to support efficient and rapid browsing by act and scene. For example, the environment 52 shows two information structures 1400 and 1402 in Act 1 of Romeo and Juliet, representing the Capulets family and the Montagues family respectively. Entrances and exit are events 20. The general interactions or speeches between characters are represented as dashed arrow connections 412. In this example environment 52, it is possible to observe characters 24 enter and exit scenes, investigate who 24 they interact with, and potentially how information is passed between family members 24. For example, the nurse 24 connects Romeo 24 and Juliet 24 in Act 1.

Test Case 2: The Final Days of Enron

In order to test diagrammatic interaction and analysis techniques against a fairly large and real problem, the contents of a publicly available external database (not shown) of email traffic 1404 from the final months of Enron was utilized, and coupled to the memory 102 of the tool 12. First, a picture of top-level business units 6 and personnel 6 was developed and significant events in the history of Enron were entered using the modules 50,54,62,66 (see FIG. 42) to create the organizational structure 60 of Enron Executives 6. Next, this organizational structure 60 was overlaid with several thousand email communication events 1404 imported from the database. Upon review of the generated environment 52, the resulting picture shows, among other things, lines of communication between different groups within the organization, frequency and direction of communication, bursts of activity, and one-to-one and one-to-many emails. It is possible to observe certain behaviors, for example a low frequency of email communication originating from and exchanged between the higher echelons at Enron in the final weeks, possibly indicating that alternative routes of communication were utilized, as the temporal domain 402 aspects of the environment 52 are navigates through the tool 12 (in conjunction with the analytics module 56).

Event Driven Diagrams

Referring to FIGS. 1 and 33, the visual representation 18 provided by the visualization tool 12 can facilitate other diagrammatic contexts 401 as defined earlier, in addition to of the geospatial domain 400. Event driven diagrams (information structures 60) can be used to show diagrammatic change over time. The XY plane 7 provides the ground surface of the diagrammatic context domain 401 and the Z-axis represents a time series into the future and past as defined by the temporal domain 402. Further, it is recognised that locations of nodes 6 as linked to the events 20 shown on the domain 401 may move or cease to exist, therefore providing for a dynamic reconfiguration potential of spatial relationships of the nodes 6 on the surface 7 over time, as monitored/performed by a spatial relationship reconfiguration module 62 (see FIG. 34) further described below. Accordingly, the reconfiguration module 62 monitors the location status change of various nodes 6 in the domain 401 and facilitates interaction with those reconfigured nodes 6 based on their current status. For example, to support visual analysis of an organization over time, the reconfiguration module 62 monitors the organizational hierarchy at any point in time, such that organizational nodes 6 may be added, removed or reassigned to a new location in the ground surface 7 over time. In the case where existence status of one of the nodes 6 has been deemed cancelled, the reconfiguration module 62 could maintain the previously defined connectivity relationships 412 between the cancelled node 6 and adjacent nodes 6, however could inhibit the assignment of new connectivity relationships 412 to the canceled node 6. It is recognized that various visual properties could be used to portray the connectivity relationships 412 associated with the canceled node 6 in the visual representation 18, including properties such as but not limited to hidden, line type, line thickness, colour, texture, shading, and labels, as desired.

Referring again to FIG. 33, two examples of event types as information structures 60 and their corresponding representations 18 are shown. The visual representations 18 include the temporal domain 402, diagrammatic domain 401, connection visual elements 412 and the visual elements 410 representing the event/entity/operating space combinations as nodes 6. The connections (e.g. connectivity elements 412) between nodes 6 and changes relating to the nodes 6 can be shown in a solid line between the two nodes 6 to show the current connection status between them, while changed/deleted status between or otherwise associated to the nodes 6 can be shown as dotted lines. For example, in FIG. 33a the behaviour of the entity, node A, which refers to an organizational node (node B) that has ceased to exist, is shown as a dotted line. While in FIG. 33b, the steps of a process relating Nodes A and B is shown by a solid line.

To support the analysis of diagrammatic perspectives in time, the tool 12 is able to visualize the state of a diagram at any point in time. Within the temporal framework of the domain 402, the diagram that is represented on the ground plane 7 will be the state of the diagram at browse time and changes as time is navigated in order to represent conditions at a particular time. Event-driven diagrams are updated for their visual properties based on events 20 and rules 58 (and/or layout patterns 64). The rules determine how the diagram changes in response to certain events 20. Rules can be applied variably to any diagrammatic node 6 or link 412 depending on the situation. One example of a rule may be ‘increase node size based on the total number of events which have occurred’. This would provide the analyst with insight into the total activity at a node 6 during the observed time period. Another rule may cause nodes 6 to appear or move based on events 20 and relationship 412 to other nodes 6. Some of the rules 58, 64 and properties that can currently be attached to nodes 6 are explained by example in FIG. 41, as used by the reconfiguration module 62 to monitor or otherwise effect the updates to the various nodes 6 and/or associated links 412 based on changes to the nodes 6, for example. It will be understood by a person skilled in the art that the rules shown in FIG. 41 are an exemplary embodiment of rules and actions that can be taken, and other types of rules that affect diagrammatic environment 52 may be envisaged.

Using event-driven diagrams and rules, an analyst could create the analytical template 70 (see FIG. 34). For example, if the analyst is interested in financial transactions, the template 70 can be created using a few simple rules to quickly reveal hubs of financial activity as matched patterns from the environment 52 to the template 70 when applied via the template module 68. As described, the visual properties of diagram elements 6, 412 may be modified using event driven diagram generation methodology, including size, color, and shape and other visual distinguishing features. It could however, also be envisaged that events and rules may be used to update diagram layout. This may include using algorithms (e.g. layout patterns 64) to dynamically recalculate the environment 52 layout via the layout module 66. Representing dynamic context while showing events in time may present perceptual challenges. As the perceptual limits of short term memory are tested, is will be important to balance change within the environment 52 with the need for stable context in which to perceive continuity of events between successively updated versions of the environment 52.

Test Case—Process Flow

The tool 12, along with event-driven diagrams generation methodology was used to generate a sample process environment 52, shown in FIG. 44. The process is modeled as a diagram in the X-Y plane 7, the states of process nodes 6 are coded as “completed” 1425 (e.g. blue), “currently active” 1426 (e.g. green), and “require attention” 1427 (e.g. yellow). Events associated with nodes 6 are shown over time and arrows 412 connecting events can indicate an instance of flow between nodes 6. An entity named “Bob” 24 is shown progressing through the process environment 52. Further, it is recognized that the physical visual properties of the nodes 6 and connections 412 (e.g. size, shape, labels, etc) can be dependent upon the total number of nodes 6 and connection elements 412 for inclusion into the information structure 60 for a limited spatial region of the reference surface 7.

Knowledge Driven Diagrams

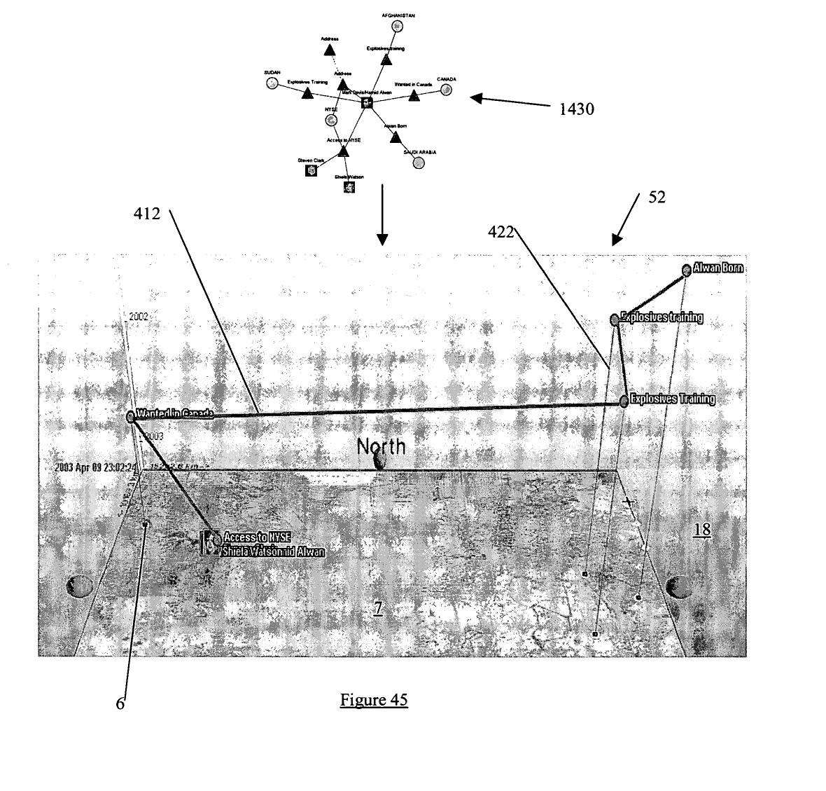

Knowledge driven diagrams (e.g. environments 52) can use 3^{rd} party graph visualization and layout applications (e.g. yWorks) integrated or otherwise coupled to the tool 12 to support knowledge driven layout of diagrams, such as behavior networks, organizations and hierarchies. The generated layouts of the knowledge based environments 52 can improve the readability and interpretation of the contained diagrammatic information. There are a number of example points at which these capabilities can be applied, for example:
1. Generation of new perspectives for display in linked temporal views, such as behavioral networks;
2. Generation of new perspectives for linked interaction and navigation within a temporal view; and
3. Optimized layout of existing diagrams based on user supplied visual representation 18 constraints.
   Linked Interactions
   Referring to FIG. 45, a generated environment 52 can be linked to the tool 12 such that any user interaction with a 2D graph 1430 is reflected in 3D visualization capabilities of the tool 12 (e.g. coupled diagrammatic spatial domain 401 and the temporal domain 402). The graph view 1430 shows a subset of a web of events and this same data is used to dynamically reflect in time and space portrayed in the environment 52. This interaction technique can enable the analyst to explore the diagrammatic 2D graph 1430 summary of the scenario data and by simply clicking, navigate through the geo-temporal environment 52 in the linked visualization 18. Views and data of the environment 52 can be automatically adjusted (e.g. via use of modules 54 and 66) to fit the data selected in the graph 1430. The analyst can even make use of graph analysis tools, including cluster analysis, centrality measures, connectivity, shortest paths, and graph searching as supplied by the tool 12 as described above with respect to FIGS. 31a,b,c,d, for example.
   New Perspective Generation

Referring to FIG. 34, the process of translating the tool 12 event-based data models (e.g. environments 52) into a consumable form for use of the graph layout module 66 has revealed new ways to automatically extract or generate insights from data. Initially it seemed that we were producing social network environments 52 can be produced based on communications events 20, however inspection of actual data reveals that by adjusting the translation parameters of the layout logic module 54 to include other types of connections 412, for example financial transactions and geographical incidents, a more complete diagram of behavior can result. Experimentation in this area has generated new insights into complex multi-dimensional scenarios, (see test case below) indicating the potential for gaining deeper understanding of patterns and behaviors implicit in the information provided by the information structures 60.

Test Case: The Sign of the Crescent

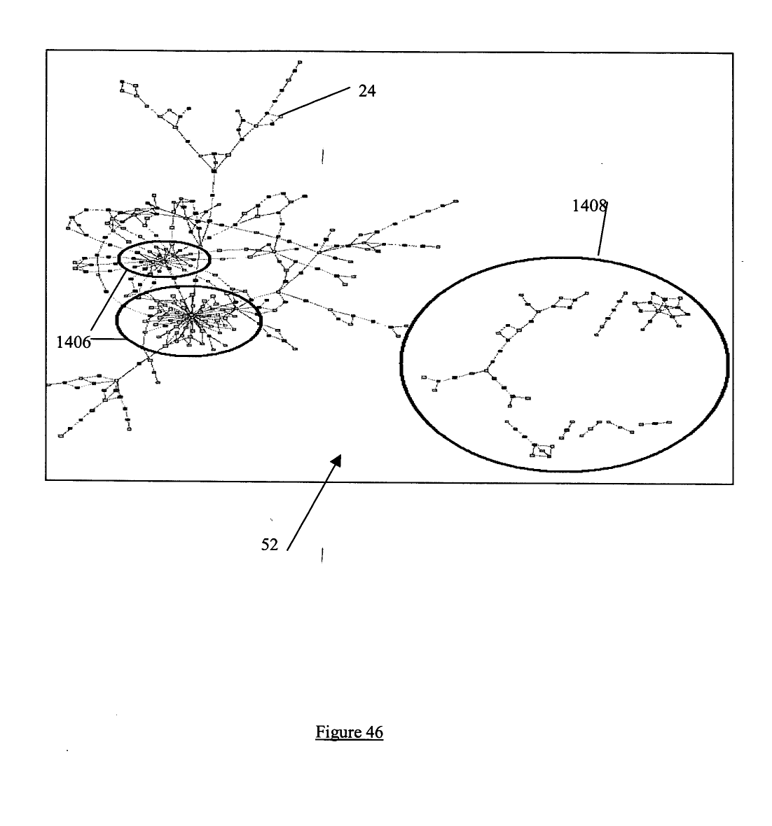

Referring to FIG. 46, generated 2D environments 52 are shown representing a Crescent scenario with relationships of Clusters 1406 and Noise 1408. The Sign of the Crescent is an FBI training scenario used to educate new analysts in the art of intelligence analysis and evidence marshalling. The challenge presented to the analyst is to understand and analyze the data, generate meaningful hypotheses based on core evidence, and present their findings in a report. To add ecological validity to the task, the data contains a large amount of noise 1408, which increases the difficulty of the task. This scenario was previously reconstructed in time domain 401 and geographical domain 400 for display by the tool 12 as the visualization representation 18 (see FIG. 1). The geospatial version of visualization representation 18 of the scenario presented a challenge to the analyst due to its volume of loosely connected events 20 and entities 24 over a wide range of time and space. It can be difficult for an analyst to know where to start, let alone begin generating hypotheses about major players and events. Based on the diagrammatic domain 401 data model of this scenario, including information about communications, financial transfers, relationships and geospatial observations, a transformation was developed to produce a 2D graph environment 52 of the data for testing automatic tools. Various transformation rules resulted in different perspectives of the data, each supporting or emphasizing a different way to reason about the problem.

FIG. 46 shows a direct translation from the base geo-time data model including all events 22, entities 24 and places 20 transposed in to a diagrammatic environment 52. From the generated graph, relationships, clusters 1406, and noise 1408 are distinguishable. This environment 52 has been reviewed with a scenario creator and was well received. The environment 52 is made up of 9 connected components, the largest containing 276 related entities 24. The remaining 8 components indicated by reference numeral 1408 (e.g. marked in blue) show activity that was intentionally meant by the scenario creator to be noise in the data. The removal of these entities from the scenario reduces the total number of data points from 343 to 276, a reduction of 20%.

Within the remaining component, two nodes 1406 of a high degree (e.g. marked in red), represent hubs of activity and connectivity within the scenario. According to the scenario solution, these nodes 1406 also happen to represent key entities within the scenario. It is worth noting that these observations are the result of an automated process applied to what was meant as an objective view of the raw scenario data Although some bias may have occurred, the final result could not have been anticipated.

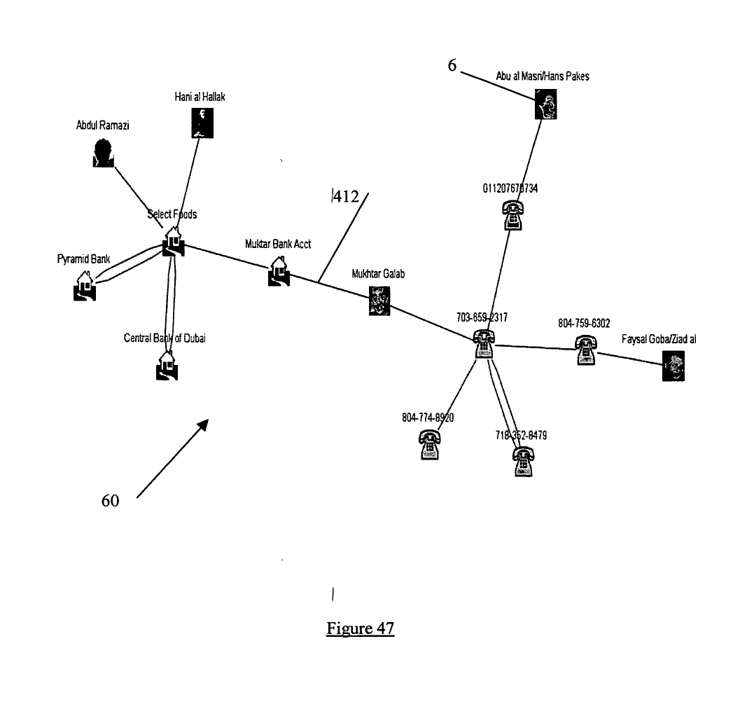

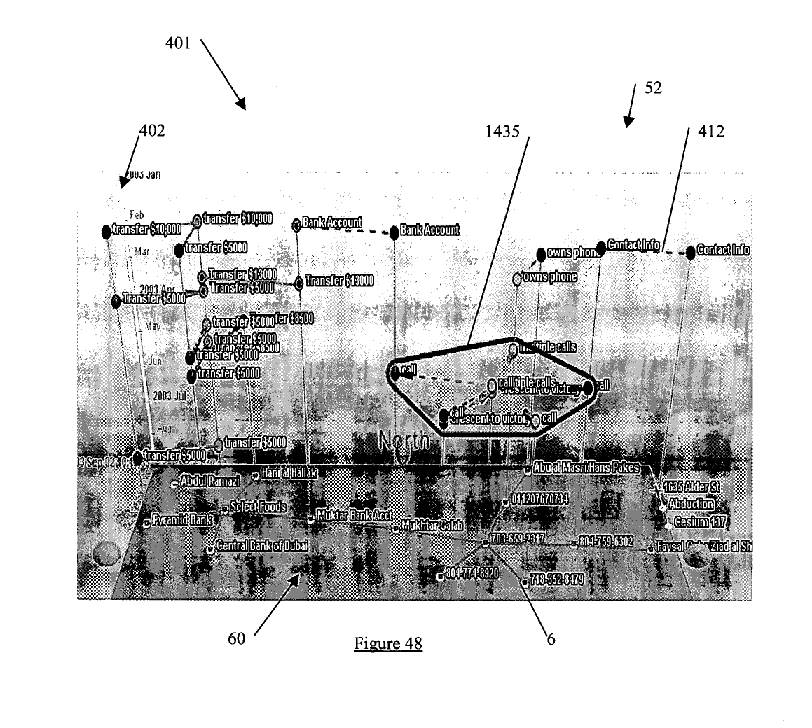

Referring to FIGS. 47 and 48, a different type of transformation reveals another perspective. FIG. 47 shows a derived behavior information structure 60 based on communication and financial transactions 412 between entitles 6. In this environment 52, the information structure 60 is filtered (e.g. using the association analysis module 307 to augment operation of the layout logic module 54—see FIGS. 3 and 34) to generate a view of the data, based only on entities 6 that communicate and/or transfer funds directly between one another. In this case, as shown in FIG. 47, a much smaller, focused 2D information structure 60 is revealed that connects targets to phones, bank accounts and each other. The environment 52 having the 3D information structure 60 is then displayed in as a combined diagrammatic domain 401 and temporal domain 402 aspects, as shown in FIG. 48, to allow for further temporal exploration and analysis of the data content. Using this derived knowledge-driven environment 52, relationships and conditions within the data can be revealed that were not initially apparent, e.g. burst of activity 1435 in the behavior information structure 60. Moreover, the analyst can remove noise in the data through filtering of unwanted selected data objects 14 and associations 16, in an interactive fashion (e.g. via the reconfiguration module 62—see FIG. 34), thereby helping to reduce analysis effort. It is recognized that the process of filtering (e.g. removing or otherwise diminishing the visual presentation of the unwanted objects 14, associations 16) can be used to update the rules data 58 and/or the layout pattern 64 rules in the memory 102, as desired.

Managing Multiple Perspectives

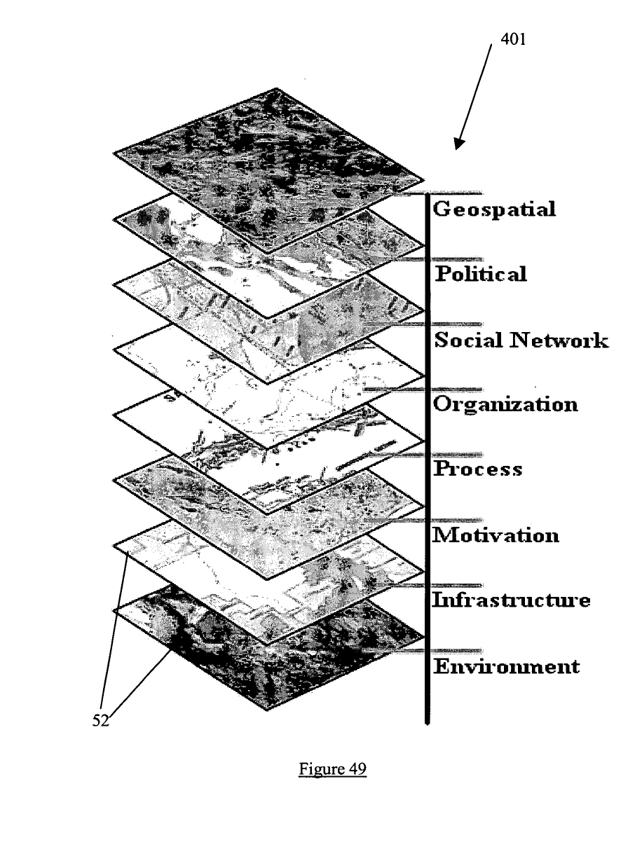

Providing the analyst with multiple perspectives (e.g. environments 52), see FIG. 49, on a problem space (e.g. diagrammatic domain 401) can creates several concerns in terms of management and workflow. Different methods are used in the tool 12 for enabling the user to freely switch between different perspectives, or combine multiple perspectives into a single integrated view, including the use of the modules 50,54,64,66 with interaction with the data objects 14, associations 16, rules 58, and user events 109.

From a data model perspective, each diagrammatic environment 52 consists of a subset of the full data set in memory 102 and a diagrammatic layout configuration provided by the layout logic module 54. For example, an organizational perspective, such as the Enron organization scenario previously described, contains different information than a geospatial perspective. Moreover, events (and other data objects 14) that are being displayed in one perspective, may be contained, linked to, and displayed in other perspectives. In addition, it may further be envisaged to use visible layers to manage different diagrammatic perspectives shown (e.g. overlapped) on the visual interface 202. An environment 52 layer contains any number and type of data elements, and the same data may be contained in multiple layers. This can be used to support multiple perspectives by adding display modes and rules 58,64 to layers. In this way, different perspectives/environments 52 can be quickly created, enabled, disabled, and even combined. For example, events in a political perspective associated with an entity could be turned on, and then combined with a geospatial perspective of its movements, thereby providing the maintaining of context across multiple perspectives, and the handling of events and entities that exist in concurrently visible, perspectives (either superimposed or adjacently displayed).

1. A system for generating a plurality of environments for a diagrammatic domain coupled to a temporal domain, each of the environments having a plurality of nodes and links between the nodes to form a respective information structure, the system comprising;
a storage for storing a plurality of data objects of the diagrammatic domain for use in generating the plurality of nodes and links;
rules data stored in the storage and configured for assigning each of the plurality of data objects to a one or more environments of the plurality of environments;
a layout logic module for providing a first layout pattern for a first environment of the plurality of environments and a second layout pattern for a second environment of the plurality of environments, each of the layout patterns including distinct predefined layout rules for coordinating the visual appearance and spatial distribution of the respective nodes and links with respect to a reference surface for each of the first and second environments to provide the corresponding information structures;
a layout module configured for applying the first layout pattern to a first data object set assigned by the rules data from the plurality of data objects to the first environment for laying out the corresponding nodes and links and configured for applying the second layout pattern to a second data object set assigned by the rules data from the plurality of data objects to the second environment for laying out the corresponding nodes and links, such that some of the data objects from the first data object set are also included in the data objects of the second data object set; and
an environment generation module configured for coordinating presentation of the generated first and second environments on a display for subsequent analysis by a user.

2. The system of claim 1 further comprising the environment generation module configured for combining the contents of the first and second environments as a combined environment suitable for presentation on the display.

3. The system of claim 2, wherein the environment generation module generates the combined environment through interaction with the layout module using an appropriate layout pattern configured for combining the first and second environments.

4. The system of claim 3, wherein the appropriate layout pattern includes layout rules for selecting a first subset of data objects from the first data object set and a second subset of data objects from the second data object set for inclusion in the information structure of the combined environment.

5. The system of claim 4, wherein the layout logic module and the layout module are configured for facilitating the use of a plurality of distinct layout patterns for laying out the plurality of environments, such that the plurality of distinct layout patterns include layout rules to account for changes in the layout of the nodes and links due to the affect of temporal factors of the temporal domain.

6. The system of claim 2 further comprising the environment generation module configured for providing a plurality of environment generation methods selected from the group comprising: user driven; event driven; data driven; and knowledge driven.

7. The system of claim 6, wherein the first layout pattern is configured for use with the user driven method for generating the first environment and the second layout pattern is configured for use with a different one of the plurality of environment generation methods.

8. The system of claim 7, wherein the first layout pattern includes a series of layout rules provided as a series of steps in a layout wizard communicated to the user via the display for providing interactive generation of the first environment between the environment generation module and the user.

9. The system of claim 2 further comprising a reconfiguration module configured for modifying the position of selected nodes in the first environment with respect to the reference surface due to changes in node status of the selected nodes.

10. The system of claim 9, wherein the reconfiguration module operates in conjunction with the layout module for effecting the modification of the selected nodes positions.

11. The system of claim 9, wherein the node status change is selected from the group comprising: a change to a visual property of the selected node for a selected time instance of the temporal domain; and a change to a position property of the selected node between time instances of the temporal domain.

12. The system of claim 9 further comprising the reconfiguration module configured for modifying a visual property of the selected nodes due to the change in node status of the selected nodes.

13. The system of claim 12, wherein the visual property is selected from the group comprising: selected label, visibility level; line type; line thickness; colour; texture; shading; and selected icon.

14. A method for generating a plurality of environments for a diagrammatic domain coupled to a temporal domain, each of the environments having a plurality of nodes and links between the nodes to form a respective information structure, the method comprising the acts of;
accessing a plurality of data objects of the diagrammatic domain for use in generating the plurality of nodes and links;
assigning each of the plurality of data objects to a one or more environments of the plurality of environments;
providing a first layout pattern for a first environment of the plurality of environments and a second layout pattern for a second environment of the plurality of environments, each of the layout patterns including distinct predefined layout rules for coordinating the visual appearance and spatial distribution of the respective nodes and links with respect to a reference surface for each of the first and second environments to provide the corresponding information structures;
applying the first layout pattern to a first data object set assigned by the rules data from the plurality of data objects to the first environment for laying out the corresponding nodes and links and applying the second layout pattern to a second data object set assigned by the rules data from the plurality of data objects to the second environment for laying out the corresponding nodes and links, such that some of the data objects from the first data object set are also included in the data objects of the second data object set; and
displaying the generated first and second environments for subsequent analysis by a user.

15. The method of claim 14 further comprising the act of combining the contents of the first and second environments as a combined environment suitable for presentation on the display.

16. The method of claim 15, wherein an act of generating the combined environment includes interaction with an appropriate layout pattern configured for combining the first and second environments.

17. The method of claim 16, wherein the appropriate layout pattern includes layout rules for selecting a first subset of data objects from the first data object set and a second subset of data objects from the second data object set for inclusion in the information structure of the combined environment.

18. The method of claim 17, wherein a plurality of distinct layout patterns are used for laying out the plurality of environments, such that the plurality of distinct layout patterns include layout rules to account for changes in the layout of the nodes and links due to the affect of temporal factors of the temporal domain.

19. The method of claim 15 further comprising the act of selecting from a plurality of environment generation methods for coordinating the generation of the plurality of environments, the environment generation methods selected from the group comprising: user driven; event driven; data driven; and knowledge driven.

20. The method of claim 19, wherein the first layout pattern is configured for use with the user driven method for generating the first environment and the second layout pattern is configured for use with a different one of the plurality of environment generation methods.

21. The method of claim 20, wherein the first layout pattern includes a series of layout rules provided as a series of steps in a layout wizard communicated to the user via the display for providing interactive generation of the first environment between the environment generation module and the user.

22. The method of claim 15 further comprising the act of modifying the position of selected nodes in the first environment with respect to the reference surface due to changes in node status of the selected nodes.

23. The method of claim 22 further comprising the act of modifying the position of the selected node through interaction with a selected layout pattern for facilitating the modification of the selected nodes positions.

24. The method of claim 22, wherein the node status change is selected from the group comprising: a change to a visual property of the selected node for a selected time instance of the temporal domain; and a change to a position property of the selected node between time instances of the temporal domain.

25. The method of claim 22 further comprising the act of modifying a visual property of the selected nodes due to the change in node status of the selected nodes.

26. The method of claim 25, wherein the visual property is selected from the group comprising: selected label, visibility level; line type; line thickness; colour; texture; shading; and selected icon.

27. The method of claim 22 further comprising the act of modifying at least one of the position or a visual property of one or more links associated with a modified node.
